(19) United States
(12) Patent Application Publication
(10) Pub. No.: US 2017/0059992 A1
(43) Pub. Date: Mar. 2, 2017

(54) RESIST PATTERN-FORMING METHOD AND CHEMICALLY AMPLIFIED RADIATION-SENSITIVE RESIN COMPOSITION

(71) Applicant: JSR CORPORATION, Tokyo (JP)

(72) Inventors: Hisashi NAKAGAWA, Tokyo (JP); Takehiko Naruoka, Tokyo (JP); Tomoki Nagai, Tokyo (JP)

(73) Assignee: JSR CORPORATION, Tokyo (JP)

(21) Appl. No.: 15/239,136

(22) Filed: Aug. 17, 2016

(30) Foreign Application Priority Data
Aug. 26, 2015 (JP) 2015-167294
Aug. 4, 2016 (JP) 2016-154090

(51) Int. Cl. G03F 7/20; G03F 7/16; G03F 7/32; G03F 7/038

(52) U.S. Cl. CPC G03F 7/203; G03F 7/0382; G03F 7/16; G03F 7/325

(57) ABSTRACT

A resist pattern-forming method comprises applying a chemically amplified radiation-sensitive resin composition on a substrate to form a resist film. The chemically amplified radiation-sensitive resin composition comprises a first component solubility in a developer solution of which is capable of being altered by an action of an acid, a second component that is capable of generating an acid by an action of a first exposure light comprising a radioactive ray having a first wavelength, and a sensitizer precursor to be converted into a sensitizer by an action of the first exposure light. A first exposure of the resist film to the first exposure light is conducted. A second exposure of the resist film exposed to the first exposure light, to a second exposure light is conducted. The second exposure light comprises a radioactive ray having a second wavelength longer than the first wavelength.

### CROSS-REFERENCE TO RELATED APPLICATIONS

The present application claims priority to Japanese Patent Application No. 2015-167294, filed Aug. 26, 2015, and to Japanese Patent Application No. 2016-154090, filed Aug. 4, 2016. The contents of these applications are incorporated herein by reference in their entirety.

### BACKGROUND OF THE INVENTION

Field of the Invention

The present invention relates to a resist pattern-forming method, and a chemically amplified radiation-sensitive resin composition.

Discussion of the Background

In exposure processes for semiconductor devices, finer patterns have been demanded along with enhanced integration and increased speed of circuits. In connection with a procedure for pattern microfabrication, shortening of a wavelength of the light source of the exposure is predominantly demanded, and for example, development for extreme ultraviolet rays (EUV; wavelength: 13.5 nm) has been extensively carried out as a promising technique in manufacture of next-generation semiconductor devices. However, it is difficult to develop a light source apparatus having a high power (100 W) needed for applications in mass production, and the power is still at a level as low as 10 W at present; therefore, a long time period is required for exposure in forming a pattern latent image. Furthermore, in a case of a direct electron beam-drawing method in which an electron beam (EB) is used, a fine pattern can be formed with a high dimensional accuracy resulting from a small beam diameter, whereas a longer time period is required for the drawing as the pattern is more complex and has a greater area. Thus, exposure techniques in which EUV or an electron beam is used are accompanied by problems of an inferior throughput even though a fine pattern can be formed.

In order to solve the foregoing problems, sensitivity improvements of resist materials have been advanced for reducing the exposure time period as short as possible. For example, according to the resist composition disclosed in Japanese Unexamined Patent Application, Publication No. 2002-174894, improvements of the sensitivity and resolution are attempted by way of a composition containing a particular resin and compound. Generally speaking, there is trade-off relationships among three important performances of resists, i.e., the sensitivity, resolution and nanoedge roughness (or LER: line edge roughness) property.

### SUMMARY OF THE INVENTION

According one aspect of the present invention, a resist pattern-forming method comprises applying a chemically amplified radiation-sensitive resin composition on a substrate to form a resist film. The chemically amplified radiation-sensitive resin composition comprises a first component solubility in a developer solution of which is capable of being altered by an action of an acid, a second component that is capable of generating an acid by an action of a first exposure light comprising a radioactive ray having a first wavelength, and a sensitizer precursor to be converted into a sensitizer by an action of the first exposure light. A first exposure of the resist film to the first exposure light is conducted. A second exposure of the resist film exposed to the first exposure light, to a second exposure light is conducted. The second exposure light comprises a radioactive ray having a second wavelength longer than the first wavelength. The resist film exposed to the second exposure light is developed with a developer solution comprising an organic solvent as a principal component. A value (I^{PP})/(I^{P}) is no greater than 0.2, wherein (I^{PP}) is an absorbance of the sensitizer precursor at the second wavelength, and (I^{P}) is an absorbance of the sensitizer at the second wavelength.

According another aspect of the present invention, a chemically amplified radiation-sensitive resin composition comprises a first component solubility in a developer solution of which is capable of being altered by an action of an acid, a second component that is capable of generating an acid by an action of a first exposure light including a radioactive ray having a first wavelength, and a sensitizer precursor to be converted into a sensitizer by an action of the first exposure light.

### BRIEF DESCRIPTION OF THE DRAWINGS

FIGS. 1 A to 1E show schematic views illustrating steps of the resist pattern-forming method of the present embodiment;

FIG. 2 shows a view illustrating an energy irradiation dose-percentage of residual film curve in the resist pattern-forming method of the present embodiment;

FIG. 3 shows a view illustrating an energy irradiation dose-time curve in the resist pattern-forming method of the present embodiment;

FIGS. 4A to 4D show explanatory views illustrating steps of the resist pattern-forming method according to a further embodiment of the present invention;

FIGS. 5A to 5C show explanatory views illustrating Specific Example 1 of the resist pattern-forming method of the present invention;

FIGS. 6A to 6D show explanatory views illustrating Specific Example 2 of the resist pattern-forming method of the present invention;

FIG. 7 shows a chemical reaction equation in the present embodiment;

FIG. 8 shows a graph illustrating the absorptivity of DOMeBzH and DOMeBzO;

FIGS. 9A to 9C show schematic views illustrating changes in the concentration of an acid, a sensitizer and a quencher in the present embodiment, in which: FIG. 9A shows the concentrations immediately after the irradiation with the exposure light (I); FIG. 9B shows the concentrations after the acid generated by irradiation with the exposure light (I) was neutralized with the quencher; and FIG. 9C shows the concentrations after the irradiation with the exposure light (II);

FIG. 10 shows a schematic plan view illustrating a line-pattern when seen from above; and

FIG. 11 shows a schematic cross sectional view illustrating a line-pattern configuration.

### DESCRIPTION OF THE EMBODIMENTS

The resist pattern-forming method of an embodiment of the present invention includes:

the step of forming a resist film on a substrate (hereinafter, may be also referred to as “resist film-forming step”) using a chemically amplified radiation-sensitive resin composition (hereinafter, may be also referred to as “radiation-sensitive resin composition (I)”) containing a first component (hereinafter, may be also referred to as “(A) component” or “component (A)”) the solubility in a developer solution of which is capable of being altered by an action of an acid, a second component (hereinafter, may be also referred to as “(B) component” or “component (B)”) that is capable of generating an acid by an action of first exposure light (hereinafter, may be also referred to as “exposure light (I)”) including a radioactive ray having a first wavelength (hereinafter, may be also referred to as “wavelength (I)”), and a sensitizer precursor to be converted into a sensitizer by an action of the exposure light (I) (hereinafter, may be also referred to as “(C) sensitizer precursor” or “sensitizer precursor (C)”);

the first exposure step (hereinafter, may be also referred to as “exposure step (1)”) of exposing the resist film to the exposure light (I);

the second exposure step (hereinafter, may be also referred to as “exposure step (2)”) of exposing to second exposure light including a radioactive ray (hereinafter, may be also referred to as “exposure light (ID”) having a second wavelength longer than the wavelength (I) (hereinafter, may be also referred to as “wavelength (II)”), the resist film exposed to the exposure light (I); and

the step of developing (hereinafter, may be also referred to as “development step”) with a developer solution containing an organic solvent as a principal component (hereinafter, may be also referred to as “developer solution (I)”), the resist film exposed to the exposure light (II),

in which a value (I^{PP})/(I^{P}) is no greater than 0.2, wherein (I^{PP}) is an absorbance of the sensitizer precursor (C) at the wavelength (II), and (I^{P}) is an absorbance of the sensitizer at the wavelength (II).

The chemically amplified radiation-sensitive resin composition of another embodiment of the present invention is a chemically amplified radiation-sensitive resin composition for use in the resist pattern-forming method, and is characterized by containing: (A) a component the solubility in a developer solution of which is capable of being altered by an action of an acid; (B) a component that is capable of generating an acid by an action of the exposure light (I) including a radioactive ray having the wavelength (I), and a sensitizer precursor to be converted into a sensitizer by an action of the exposure light (I).

According to the resist pattern-forming method and the chemically amplified radiation-sensitive resin composition of the embodiments of the present invention, a resist pattern having less nanoedge roughness and a high resolution can be formed with high sensitivity.

Hereinafter, embodiments of the resist pattern-forming method and the radiation-sensitive resin composition (I) according to the present invention will be described with reference to the drawings. However, the present invention is not limited to the following embodiments.

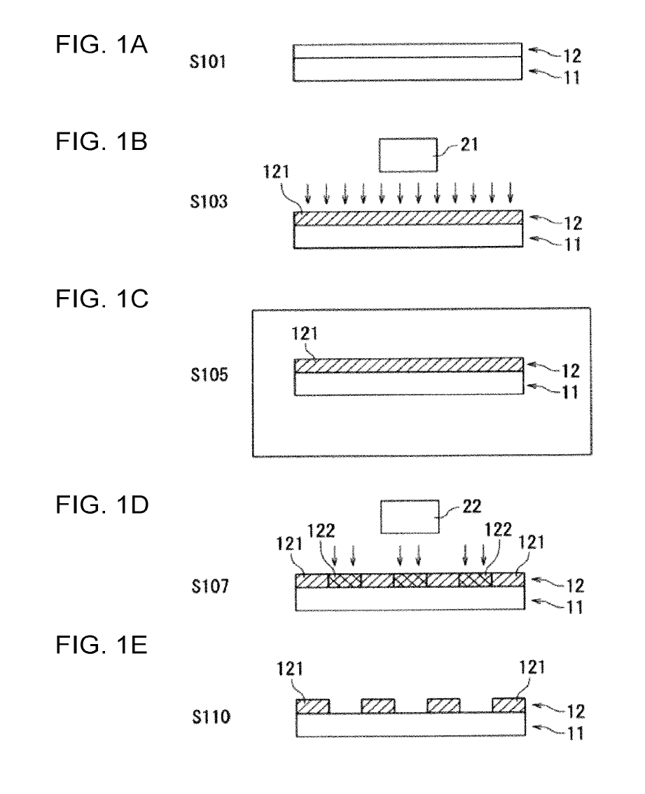

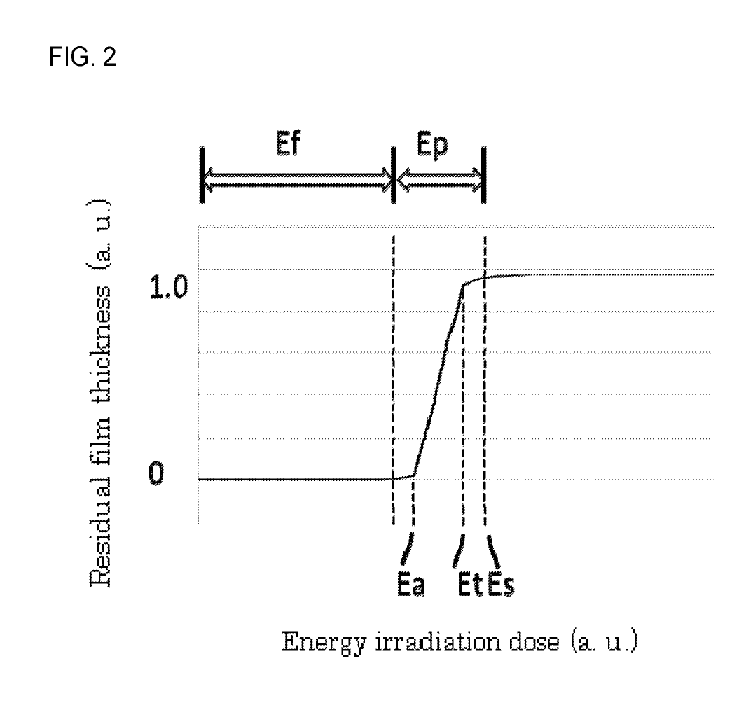

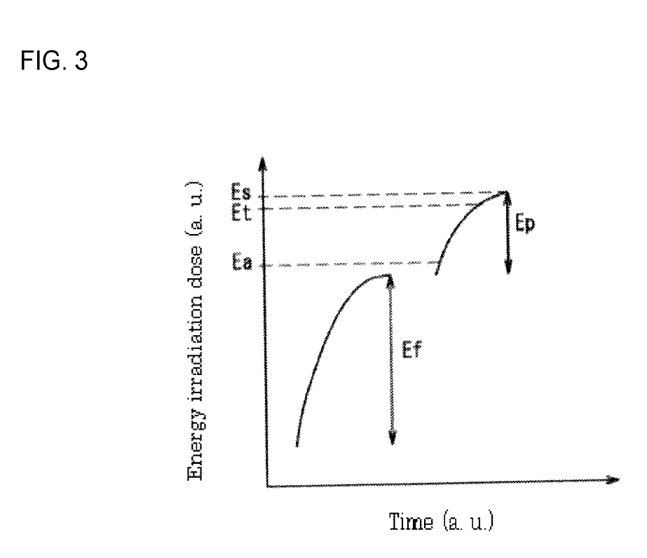

With reference to FIGS. 1 to 3, the resist pattern-forming method according to the embodiment of the present invention is described. FIGS. 1A to 1E show schematic views illustrating the steps of the resist pattern-forming method of the present embodiment. FIG. 2 shows a view illustrating an energy irradiation dose-percentage of residual film curve in the resist pattern-forming method of the present embodiment. FIG. 3 shows a view illustrating an energy irradiation dose-time curve in the resist pattern-forming method of the present embodiment. The resist pattern-forming method of the present embodiment is performed in accordance with step S101 to step S110.

### Resist Film-Forming Step

First, as shown in FIG. 1A, in a resist film-forming step (S101), a resist film 12 is formed on a substrate 11. Specifically, the substrate 11 (for example, wafer) is prepared, and the resist film 12 is formed by applying the chemically amplified radiation-sensitive resin composition (I) on the substrate 11 followed by prebaking. The radiation-sensitive resin composition (I) is as described later. According to the embodiments of the present invention, since a developer solution containing an organic solvent as a principal component is used as the developer solution (I) in the development step as described later, light-exposed regions are turned to be insoluble or hardly soluble in the developer solution (I), whereas the light-unexposed regions are dissolved in the developer solution (I), thereby leading to formation of a negative resist pattern.

With respect to the procedure for forming the resist film, for example, an exemplary process includes: laminating the radiation-sensitive resin composition (I) on, i.e., directly to, the substrate, or applying the same on an organic underlayer film described later or on a silicon-containing film described later to provide a coating film; followed by prebaking the coating film. With respect to the application procedure of the radiation-sensitive resin composition (I), for example, a spin-coating process, a roll coating process, a dip coating process or the like may be employed. The temperature and the time period of the prebaking are not particularly limited, and may be appropriately predetermined such that the solvent contained in the radiation-sensitive resin composition (I) can be removed.

As shown in FIG. 2, when the energy dose irradiated on the resist film is greater than a threshold value Ea (hereinafter, may be also referred to as “latent image-forming energy”), a latent image is formed on the resist film, and the part where the latent image is formed becomes hardly soluble in the developer solution (I). When the energy dose further increases to exceed a threshold value Et (hereinafter, may be also referred to as “necessary energy dose”), the part where the latent image is formed becomes insoluble or hardly soluble in the developer solution (I).

### Organic Underlayer Film-Forming Step

Before the resist film-forming step, the step of forming an organic underlayer film on the side of the face of the substrate to be provided with the resist film may be included.

The organic underlayer film is exemplified by an organic film formed using a composition for a resist underlayer film, a carbon film, etc., formed by a conventionally well-known CVD (Chemical Vapor Deposition) technique.

### Silicon-Containing Film-Forming Step

In addition, after the organic underlayer film-forming step and before the resist film-forming step, the step of forming a silicon-containing film on the side of the face of the organic underlayer film provided with the resist film may be included.

The silicon-containing film if formed by using a polysiloxane composition containing a polysiloxane and a solvent, for example. The polysiloxane is not particularly limited as long as it is a polymer having a siloxane bond.

With respect to the procedure for forming the silicon-containing film, for example, an exemplary process includes: applying the polysiloxane composition on the side of the face of the organic underlayer film to be provided with the resist film to provide a coating film; and subjecting the coating film to a heat treatment and/or an irradiation with ultraviolet light to permit hardening.

### Protective Film-Forming Step

After the resist film-forming step and before the exposure step (1) described in the following, the step of forming a protective film with a composition for protective film formation on the side of the face of the resist film not facing the substrate may be included.

The formation of the protective film enables in the process of a liquid immersion lithography: a direct contact of a liquid immersion liquid to the resist film to be prevented; deterioration of the resist performance to be inhibited, the deterioration being a result of permeation of the liquid immersion liquid into the resist film, and elution of resist film components into the liquid immersion liquid; and staining of the lens of the lithography device with eluted components into the liquid immersion liquid to be prevented. In addition, when exposing to a radioactive ray such as EUV or an electron beam, transpiration of the outgas from the resist film can be reduced, whereby contamination of the lithography device cane prevented.

The composition for protective film formation contains a polymer and a solvent. The polymer preferably has a fluorine atom and/or a silicon atom. The protective film containing such a polymer has more favorable solubility in the developer solution (I) containing an organic solvent as a principal component, and therefore, undissolved matter and the like of the protective film can be prohibited. The polymer having a fluorine atom and/or a silicon atom may be exemplified by similar polymers to those exemplified in connection with (F) a polymer in the radiation-sensitive resin composition (I) described later, and the like.

The solvent contained in the composition for protective film formation preferably does not dissolve the resist film in light of possible formation of a favorable resist pattern, and more preferably differs from the solvent in the developer solution (I) described later. Such a solvent is exemplified by an alcohol solvent, a fluorine solvent, a hydrocarbon solvent and the like. Of these, alcohol solvents not containing a fluorine atom are preferred.

With respect to the procedure for forming the protective film, for example, an exemplary process includes: applying the composition for protective film formation on the resist film to provide a coating film; and prebaking the coating film.

### Exposure Step (1)

Next, as shown in FIG. 1B, a resist film 12 is exposed in the exposure step (1) (S103) by irradiation with the exposure light (I). The irradiation with the exposure light (I) leads to generation of an acid from the component (B) in the resist film 12, whereas the sensitizer is produced from the sensitizer precursor (C). In the resist film 12, both the generation of the acid from the component (B), and the production of the sensitizer from the sensitizer precursor (C) occur. Polarity conversion, crosslinking, degradation reactions and the like are caused by an action of the acid generated from the component (B) in the component (A), and as a result, the solubility of the component (A) in a developer solution is altered. For forming a resist pattern by a development, generation of a certain amount of the acid from the component (B) is required.

The exposure step (1) is carried out in a vacuum or inert atmosphere, for example. The exposure light (I) is emitted from an exposure light source (1) 21 such that the resist film 12 is irradiated from above. In this step, the irradiation with exposure light (I) is a floodwise exposure, an exposure executed on one face of the resist film 12. As shown in FIG. 1B, for example, the entire face of the resist film 12 is irradiated with the exposure light (I). However, not the entirety of the resist film 12, but only a partial region, e.g., patternwise, may be irradiated with the exposure light (I). It is to be noted that the exposure light (I) is, for example, an electromagnetic wave such as visible light, UV (ultraviolet ray), DUV (deep ultraviolet ray), EUV and an X-ray. In addition, the exposure light (I) may be an electron beam or an ion beam. Of these, the exposure light (I) is preferably EUV or an electron beam.

As shown in FIG. 2, an irradiation dose Ef of the exposure light (I) in the exposure step (1) (S103) dose not exceed the latent image-forming energy dose Ea. In other words, the acid is produced from the component (B) in the exposure step (1) (S103) in an amount lower than that needed for forming the resist pattern in the development. Thus, as long as the exposure step (1) (S103) is carried out, the resist film 12 is not made insoluble or hardly soluble in the developer solution, and therefore the resist pattern is not formed.

### Maintaining Step

After the exposure step (1), a maintaining step (S105), the step of maintaining the state of the resist film 12 as shown in FIG. 1C, may be included. Specifically, until an exposure step (2) (S107) described later is carried out, the environment is controlled without carrying out prebaking so as to prevent a decrease in: the amount of the acid generated from the component (B) in the resist film 12 irradiated with the exposure light (I) in the exposure step (1) (S103); and the amount of the sensitizer produced from the sensitizer precursor (C).

For example, the environment surrounding the resist film 12 is an atmosphere capable of controlling a decrease in the amount of the acid and the sensitizer produced in the exposure step (1). The atmosphere capable of controlling the decrease in the amount of the acid and the sensitizer may be an inert gas atmosphere or a vacuum atmosphere not containing a basic substance. Furthermore, a protective film that blocks basic substances and/or oxygen may be also provided. In the case of the inert gas atmosphere, for example, a nitrogen gas, a helium gas, an argon gas or the like may be used as the inert gas, which can be used under vacuum or compression. In the case of the vacuum atmosphere, the environment is acceptable as long as the environment surrounding the resist film 12 is under vacuum, and preferably, the environment surrounding the resist film 12 is regulated to vacuum of no greater than 1 Pa. In the environment of the inert gas atmosphere or vacuum atmosphere, a decrease in the amount of the sensitizer produced in the resist film 12 is prevented.

Furthermore, the environment surrounding the resist film 12 may be an atmosphere or liquid that enables the amount of the acid and/or the sensitizer in the resist film 12 to be increased. As the atmosphere that enables the amount of the acid and/or the sensitizer to be increased, an active gas atmosphere is used. As the active gas atmosphere, for example, a reactive gas for shift of the absorption wavelength is used. As the active liquid that enables the amount of the acid and the sensitizer to be increased, for example, a reactive liquid for shift of the absorption wavelength is used. The sensitizer produced in the resist film 12 reacts with the active gas or the active liquid to be converted into an active substance α or a stable substance α1 in the exposure step (2) (S107) described later. The active substance α or the stable substance α1 can serve as a sensitizer similarly to the sensitizer produced from the sensitizer precursor (C). The active substance α is, for example, an aromatic compound radical or an iodine compound radical, whereas the stable substance α1 is, for example, an aromatic compound or an iodine compound. It is to be noted that in a case in which the active liquid is used, the active liquid may be removed from the resist film 12 before carrying out the exposure step (2) (S107), or the exposure step (2) (S107) may be carried out without removing the active liquid.

In addition, as a procedure for controlling the environment, control of the temperature of the resist film 12 may be adopted. When the temperature of the resist film 12 is higher than a threshold temperature, the amount of the acid and/or sensitizer decreases, and therefore by maintaining the temperature of the resist layer 12 to be no greater than the threshold temperature, a decrease in the amount of the acid and/or the sensitizer in the resist film 12 can be prevented. For example, after the exposure step (1) (S103), the temperature of the resist film 12 is lowered to no greater than the threshold temperature by carrying out a quenching treatment in the maintaining step (S105). The threshold temperature is, for example, 30° C. Also, the exposure step (1) (S103) may be carried out at a certain temperature, and the temperature of the resist film 12 may be maintained at no greater than the threshold temperature in the maintaining step (S105).

Moreover, when the resist film 12 is irradiated with an unexpected radioactive ray until the exposure step (2) (S107) is carried out, the amount of the acid and/or the sensitizer may be decreased. Thus, the resist film 12 is placed in an environment not irradiated with a radioactive ray in the maintaining step (S105).

In addition, since the amount of the acid and/or the sensitizer decreases in a time dependent manner, prevention of a decrease in the amount of the acid and/or the sensitizer in the resist film 12 is also enabled by controlling the time period between the exposure step (1) (S103) and the exposure step (2) (S107) described later. The time period between the exposure step (1) and the exposure step (2) described later is preferably within 60 min. It is to be noted that the control of the temperature, the illuminance or the time period may be executed concomitantly with the control of

the environment surrounding the resist film 12.

### Exposure Step (2)

After the exposure step (1) (S103) or the maintaining step (S105), an exposure step (2) (S107) is carried out as shown in FIG. 1D. In the exposure step (2), the resist film 12 exposed to the exposure light (I) is exposed by irradiating with the exposure light (II). Specifically, the exposure light (II) is a radioactive ray that has the wavelength (II) longer than the wavelength (I), and acts on the sensitizer produced from the sensitizer precursor (C), and an active substance α and/or a stable substance α1, leading to generation of an acid from the component (B). In the region of the resist film 12 irradiated with the exposure light (II), generation of the acid (or an acid having a different structure from that of the aforementioned acid) from the component (B) occurs due to actions of the sensitizer produced from the sensitizer precursor (C), and the active substance α/stable substance α1. Alternatively, in addition to leading to the generation of an acid from the component (B) due to the actions of the sensitizer and the active substance α/stable substance α1, the exposure light (II) may be a radioactive ray that leads to generation of an acid from the component (B) in the resist film 12. In this instance, in the region of the resist film 12 irradiated with the exposure light (II), the acid (or the acid having a different structure from that of the aforementioned acid) is generated from the component (B), the sensitizer is produced from the sensitizer precursor (C) due to the actions of the sensitizer and the active substance α/stable substance α1 and again the acid (or the acid having a different structure from that of the aforementioned acid) is generated from the component (B). As shown in FIG. 2, an irradiation dose Ep of the exposure light (II) in the exposure step (2) (S107) does not exceed the latent image-forming energy dose Ea, and the sum of the irradiation dose Ep of the exposure light (II) and the irradiation dose Ef of the exposure light (I) exceeds the necessary energy dose Et. In other words, in the exposure step (2) (S107), the amount of the acid generated from the component (B) due to the actions of the sensitizer and the active substance α/stable substance α1 is lower than the amount needed for forming the resist pattern in the development except for the case in which the acid is not generated from the component (B) in the exposure step (1) (S103), but the sum of the amount of the acid generated from the component (B) in the exposure step (1) (S103) and the amount of the acid obtained from the component (B) in the exposure step (2) (S107) exceeds the amount needed for forming the resist pattern in the development.

The exposure light (II) is emitted from an exposure light source (2) 22 such that the resist film 12 is irradiated from above. The exposure light source (2) 22 may be identical to an exposure light source (1) 21 that emits the exposure light (I), or may be different from the exposure light source (1) 21. In this procedure, regions of the resist film 12 irradiated with the exposure light (I) are irradiated patternwise with the exposure light (II). It is to be noted that the exposure light (II) may be selected depending on the resolution of the pattern to be formed, and may be, for example, electromagnetic radiations such as UV, DUV, EUV and X-ray, electron beams or ion beams. The exposure step (2) is carried out in, for example, a vacuum atmosphere, an active gas atmosphere or an inert atmosphere. Thus, the resist film 12 includes: light-exposed regions (A) 121 irradiated with only the exposure light (I); and light-exposed regions (B) 122 irradiated with both the exposure light (I) and the exposure light (II) (see FIG. 1D).

### Development Step

After the exposure step (2), a development step (S110) is carried out as shown in FIG. 1E.

In the development step, the resist film 12 is developed. The development of the resist film 12 is conducted by, for example, placing the substrate 11 in a developer solution bath, after conducting post exposure baking (PEB). In the present embodiment, the irradiation dose Ef applied to the light-exposed regions (A) 121 of the resist film 12 does not exceed the latent image-forming energy dose Ea. Since the amount of the acid generated from the component (B) is lower than the amount needed for forming the resist pattern in the light-exposed regions (A) 121, the light-exposed regions (A) 121 are dissolved in the developer solution. On the other hand, the energy dose Es (i.e., Ef+Ep) applied to the light-exposed regions (B) 122 of the resist film 12 exceeds the necessary energy dose Et. In the light-exposed regions (A) 122, since the sum of the amount of the acid generated from the component (B) in exposure step (1), and the amount of the acid generated due to the actions of the sensitizer and the like exceeds the amount needed for forming the resist pattern, the light-exposed regions (B) 122 become insoluble or hardly soluble in the developer solution. Accordingly, a predetermined resist pattern is formed on the substrate 11.

In the development step, the developer solution (I) containing an organic solvent as a principal component is used. The development conducted using the developer solution (I) containing an organic solvent as a principal component enables a pattern with a high resolution to be formed, particularly in a case where a pattern such as a trench pattern or a hole pattern in which an exposure area is smaller is to be formed, as compared with the case in which a positive image is to be formed using an aqueous alkaline developer solution. When the positive image is formed using the aqueous alkaline developer solution, the light-exposed regions are so narrow that the optical contrast becomes inferior, whereby pattern miniaturization is limited. On the other hand, when the development is conducted using the developer solution (I) containing an organic solvent as a principal component, pattern formation with a high resolution is enabled due to the patternwise exposure on the area that results in sufficient optical contrast for the light-exposed regions. The phrase “contain(ing) an organic solvent as a principal component” as referred to means that the amount of the organic solvent contained in the developer solution (I) is typically no less than 50% by mass, preferably no less than 70% by mass, more preferably no less than 90% by mass, and particularly preferably no less than 95% by mass. Components other than the organic solvent in the developer solution (I) include, for example, water, silicon oil and the like.

The organic solvent is exemplified by an alcohol solvent, an ether solvent, a ketone solvent, an amide solvent, an ester solvent, a hydrocarbon solvent, and the like.

Examples of the alcohol solvent include:

monohydric alcohol solvents such as methanol, ethanol, 1-propanol, 2-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethyl cyclohexanol, benzyl alcohol and diacetone alcohol;

polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol and tripropylene glycol;

polyhydric alcohol partial ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether and dipropylene glycol monopropyl ether; and the like.

Examples of the ether solvent include:

diallyl ether solvents such as diethyl ether, dipropyl ether and dibutyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, butanone, methyl-n-propyl ketone, methyl-n-butyl ketone, diethyl ketone, methyl-iso-butyl ketone, methylamyl ketone, ethyl-n-butyl ketone, methyl-n-hexyl ketone, di-iso-butyl ketone and trimethylnonanone:

cyclic ketone solvents such as cyclopentanone, cyclohexanone, cycloheptanone, cyclooctanone and methylcyclohexanone;

2,4-pentanedione, acetonylacetone, acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

ester acetate solvents such as methyl acetate, ethyl acetate, n-propyl acetate, iso-propyl acetate, n-butyl acetate, 3-methylbutyl acetate, 2-butyl acetate, n-pentyl acetate, i-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate and n-nonyl acetate;

polyhydric alcohol partial ether acetate solvents such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate and dipropylene glycol monoethyl ether acetate;

lactone solvents such as γ-butyrolactone and δ-valerolactone;

carbonate solvents such as dimethyl carbonate, diethyl carbonate, ethylene carbonate and propylene carbonate;

hydroxyacid ester solvents such as methyl lactate, ethyl lactate, n-butyl lactate, n-amyl lactate and methyl glycolate;

dicarboxylic acid diester solvents such as diethyl oxalate, di-n-butyl oxalate, diethyl malonate, dimethyl phthalate and diethyl phthalate;

glycol diacetate, methoxytriglycol acetate, ethyl propionate, n-butyl propionate, iso-amyl propionate, methyl acetoacetate, ethyl acetoacetate; and the like.

Examples of the hydrocarbon solvent include:

aliphatic hydrocarbon solvents such as n-pentane, iso-pentane, n-hexane, iso-hexane, n-heptane, iso-heptane, 2,2,4-trimethylpentane, n-octane, iso-octane, cyclohexane and methylcyclohexane;

aromatic hydrocarbon solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene and n-amylnaphthalene; and the like.

Of these, the organic solvent is preferably the alcohol solvent, the ether solvent, the ketone solvent, the amide solvent or the ester solvent, more preferably the monohydric alcohol solvent, the polyhydric alcohol partial ether solvent, the aromatic ring-containing ether solvent, the chain ketone solvent, the cyclic ketone solvent, the chain amide solvent, the ester acetate solvent, the lactone solvent or the hydroxyacid ester solvent, and still more preferably ethanol, 2-propanol, dibutyl ether, anisole, methylamyl ketone, cyclohexanone, N,N-dimethylacetamide, 3-methylbutyl acetate, n-butyl acetate, γ-butyrolactone or ethyl lactate. The developer solution (I) may contain one, or two or more types of the organic solvent.

In addition to the organic solvent, it is preferred that the developer solution (I) further contains a first compound (hereinafter, may be also referred to as “(M) compound” or “compound (M)”) that can give an ionic bond, a hydrogen bond, a covalent bond, a coordinate bond, a dipole-dipole interaction or a combination thereof with a polar group generated in (A) a polymer described later.

The compound (M) is exemplified by a nitrogen-containing compound, an onium salt, a polymer that includes an onium salt, a basic polymer, a phosphorus compound, and the like. In the following, each compound will be described.

Nitrogen-Containing Compound

The nitrogen-containing compound has at least one nitrogen atom. The nitrogen-containing compound can give a hydrogen bond, a covalent bond and/or a dipole-dipole interaction with a polar group such as —COOH generated in the polymer (A).

The nitrogen-containing compound may have one, or two or more nitrogen atoms.

The lower limit of the molecular weight of the nitrogen-containing compound is preferably 50, and more preferably 100. The upper limit of the molecular weight is preferably 900, and more preferably 700.

The nitrogen-containing compound is exemplified by a compound represented by the following formula (A), and the like.

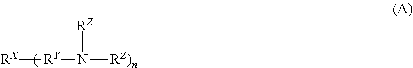

In the above formula (A), R^{X} represents a single bond or an organic group having a valency of n; R^{Y} represents a single bond, a substituted or unsubstituted methylene group, a substituted or unsubstituted alkylene group, a substituted or unsubstituted alkenylene group, a substituted or unsubstituted alkynylene group, a substituted or unsubstituted cycloalkylene group or a substituted or unsubstituted divalent aromatic group; R^{Z}s each independently represent a hydrogen atom or an alkyl group; n is an integer of 1 to 8, wherein in a case where n is no less than 2, a plurality of R^{Y}s may be identical or different, and wherein at least one of R^{X} and R^{Y} does not represent the single bond.

Examples of the organic group having a valency of n which may be represented by represented by R^{X} include a carbon atom, a nitrogen atom, —NH—, —NR—, —O—, —S—, a carbonyl group, an alkylene group, an alkenylene group, an alkynylene group, a cycloalkylene group, an aromatic group, a heterocyclic group, a combination of at least two of these groups, a group obtained from the groups listed above by substituting a part or all of hydrogen atoms included therein with a substituent, and the like, wherein R represents a monovalent organic group, preferably an alkyl group, an alkylcarbonyl group or an alkylsulfonyl group. R^{X} preferably represents the alkyl group, the nitrogen atom, —NH— and —NR—. The substituent which may be included in the groups listed above is exemplified by an alkyl group, an alkoxy group, an alkylcarbonyl group, an alkylcarbonyloxy group, an alkyloxycarbonyl group, an alkenyl group, an alkenyloxy group, an alkenylcarbonyl group, an alkenylcarbonyloxy group, an alkenyloxycarbonyl group, an alkynyl group, an alkynyleneoxy group, an alkynylenecarbonyl group, an alkynylenecarbonyloxy group, an alkynyleneoxycarbonyl group, an aralkyl group, an aralkyloxy group, an aralkylcarbonyl group, an aralkylcarbonyloxy group, an aralkyloxycarbonyl group, a hydroxy group, an amide group, a carboxy group, a cyano group, a fluorine atom, and the like.

The number of carbon atoms of the alkylene group which may be represented by R^{Y} is preferably 2 to 40, more preferably 2 to 20, and still more preferably 2 to 12. The number of carbon atoms of the alkenylene group and the alkynylene group which may be represented by R^{Y} is preferably 2 to 40, more preferably 2 to 20, and still more preferably 2 to 12. The number of carbon atoms of the cycloalkylene group which may be represented by R^{Y} is preferably 3 to 40, more preferably 3 to 20, and still more preferably 5 to 12. The monovalent aromatic group which may be represented by R^{Y} encompasses nonbenzene aromatic groups, and examples thereof include groups obtained by eliminating one hydrogen atom from a hydrocarbon or aromatic heterocyclic compound such as benzene, pyrrole, furan, thiophene, indole, naphthalene, anthracene, tetracene, benzofuran and benzothiophene, and the like.

In the above formula (A), n is preferably 1 to 6, more preferably 1 to 4, and still more preferably 1 to 3.

Examples of the nitrogen-containing compound include: tripentylamine, trioctylamine and the like when n is 1; N,N,N′,N′-tetramethylethylenediamine, N,N,N′,N′-tetramethyltrimethylenediamine and the like when n is 2; and compounds represented by the following formulae when n is no less than 3.

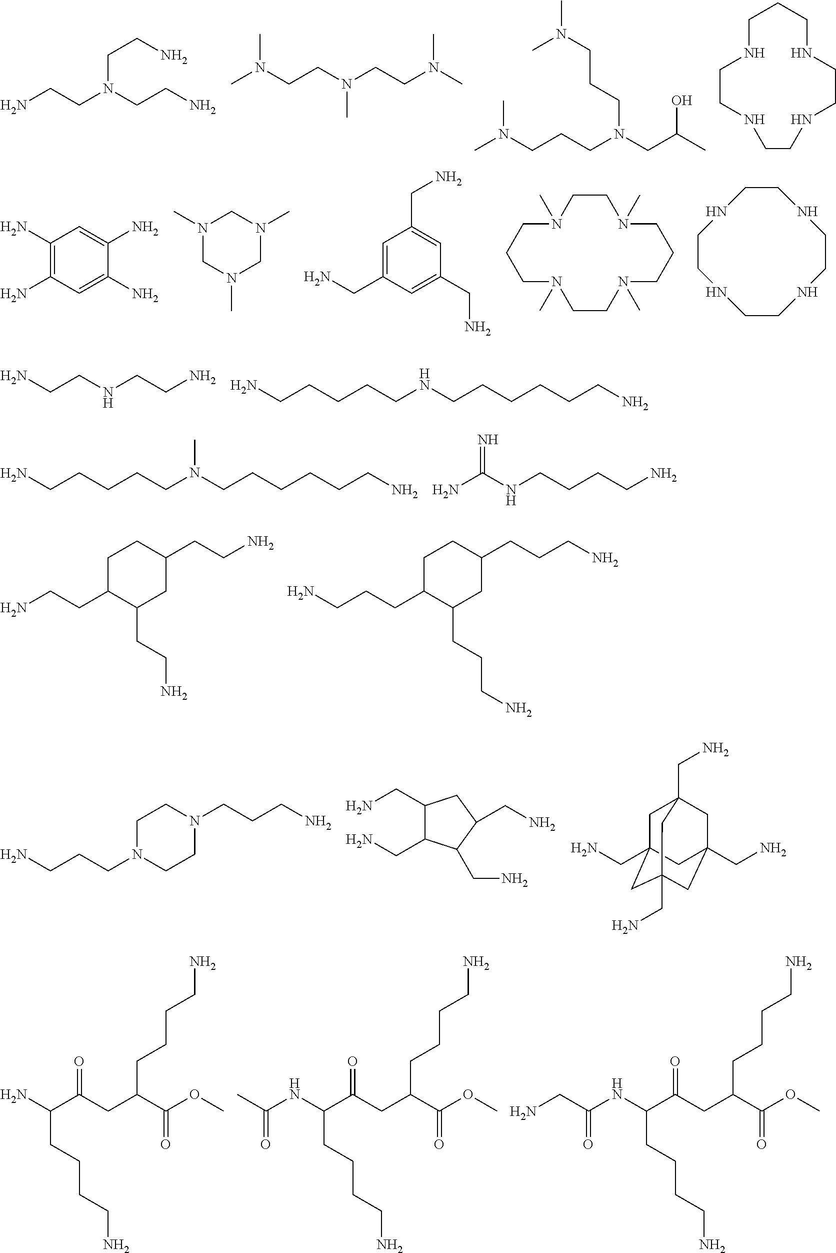

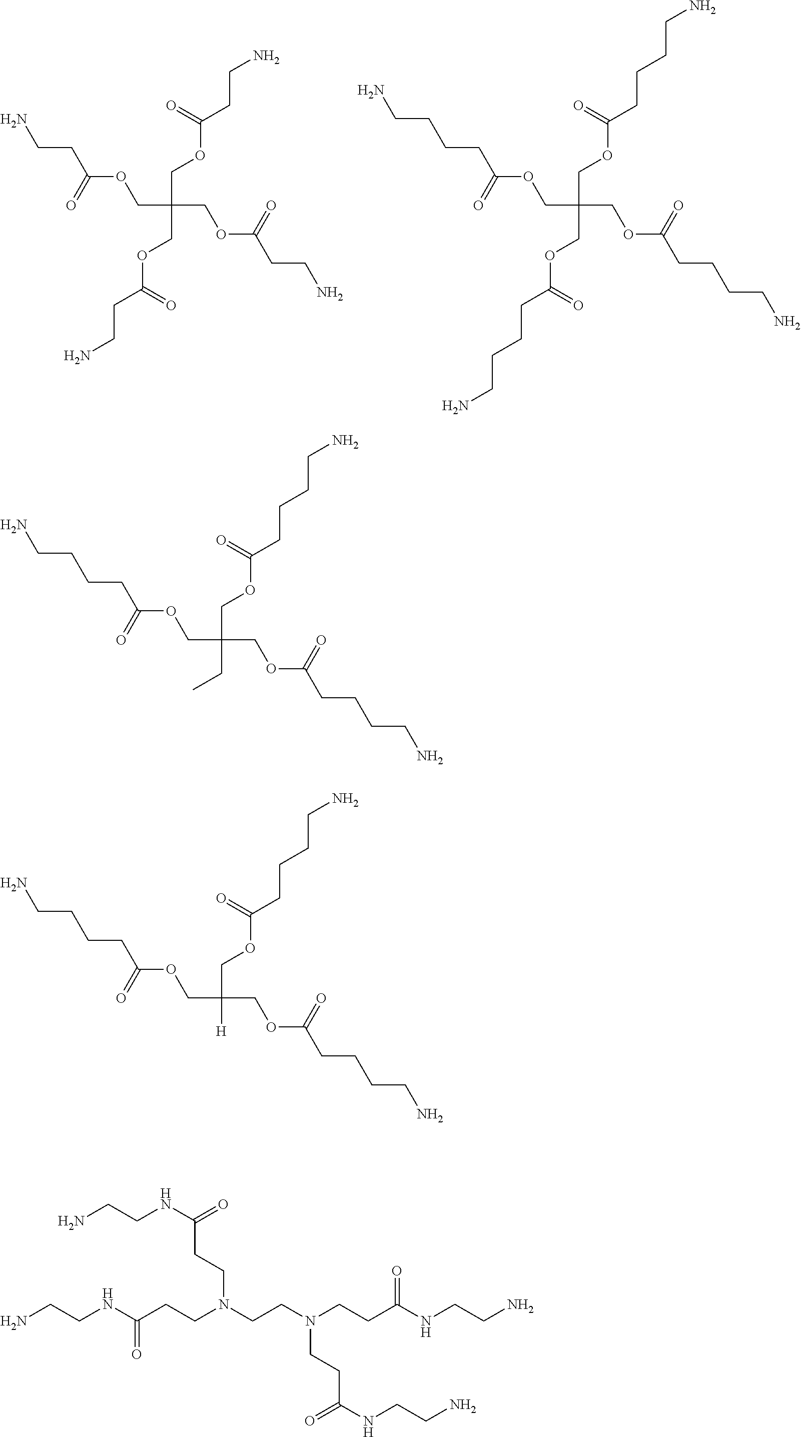 [SMILES: NCCC(=O)OCC(COC(=O)CCN)(COC(=O)CCN)COC(=O)CCN ; NCCCCC(=O)OCC(COC(=O)CCCCN)(COC(=O)CCCCN)COC(=O)CCCCN ; CCC(COC(=O)CCCCN)(COC(=O)CCCCN)COC(=O)CCCCN ; NCCCCC(=O)OCC(COC(=O)CCCCN)COC(=O)CCCCN ; NCCNC(=O)CCN(CCC(=O)NCCN)CCN(CCC(=O)NCCN)CCC(=O)NCCN]

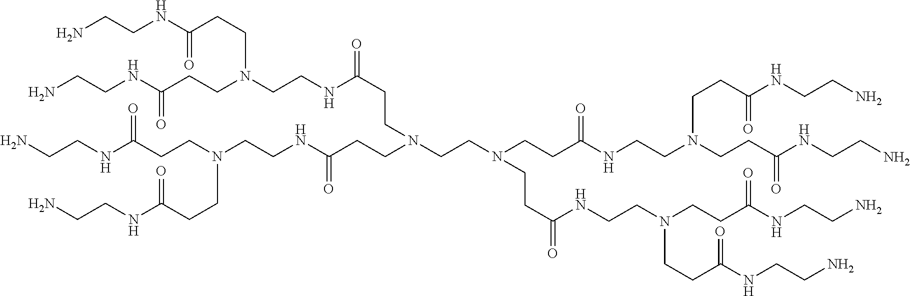 [SMILES: NCCNC(=O)CCN(CCNC(=O)CCN(CCC(=O)NCCN(CCC(=O)NCCN)CCC(=O)NCCN)CCN(CCC(=O)NCCN(CCC(=O)NCCN)CCC(=O)NCCN)CCC(=O)NCCN(CCC(=O)NCCN)CCC(=O)NCCN)CCC(=O)NCCN]

Onium Salt

The onium salt contains an onium cation and an anion. The onium salt can give a hydrogen bond and/or a dipole-dipole interaction with a polar group such as —COOH generated in the polymer (A).

The onium salt is exemplified by an ammonium salt, a phosphonium salt, an oxonium salt, a sulfonium salt, a selenonium salt, a carbonium salt, a diazonium salt, an iodonium salt, and the like. Moreover, examples of the cation contained in the onium salt also include heteroaromatic ring-containing cations in which a hetero atom of the heteroaromatic ring has a positive charge. Such an onium salt is exemplified by a pyridinium salt, an imidazolium salt, and the like.

The onium salt may be a polyvalent onium salt having at least two onium ion atoms in a single molecule. The polyvalent onium salt is preferably a compound in which the at least two cations are linked via a covalent bond. The polyvalent onium salt is exemplified by a diazonium salt, an iodonium salt, a sulfonium salt, an ammonium salt, a phosphonium salt, and the like.

The anion included in the onium salt may be either monovalent or polyvalent. The monovalent anion is exemplified by a sulfonic acid anion, a formic acid anion, a carboxylic acid anion, a sulfinic acid anion, a boron anion, a halide ion, a phenol anion, an alkoxy anion, a hydroxide ion, and the like. The divalent anion is exemplified by an oxalic acid ion, a phthalic acid ion, a maleic acid ion, a fumaric acid ion, a tartaric acid ion, a malic acid ion, a lactic acid ion, a sulfuric acid ion, a diglycolic acid ion, a 2, 5-furandicarboxylic acid ion, and the like.

Examples of the monovalent anion include Cl⁻, Br⁻, AlCl₄⁻, Al₂O₇⁻, BF₄⁻, PF₆⁻, ClO₄⁻, NO₃⁻, CH₃COO⁻, CF₃COO⁻, CH₃SO₃⁻, CF₃SO₃⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, (CF₃SO₂)(CF₃CO)N⁻, C₉H₁₉COO⁻, (CH₃)₂PO₄⁻, (C₂H₅)₂PO₄, C₂H₅OSO₃⁻, C₆H₁₃OSO₃⁻, C₈H₁₇OSO₃⁻, CH₃(OC₂H₄)₂OSO₃⁻, C₆H₄(CH₃)SO₃⁻, (C₂F₅)₃PF₃⁻, CH₃CH(OH)COO⁻, B(C₆F₅)₄⁻, FSO₃⁻, C₆H₅O⁻, (CF₃)₂CHO⁻, (CF₃)₃CHO⁻, C₆H₃(CH₃)₂O⁻, C₂H₅OC₆H₄COO⁻, and the like.

Examples of the onium cation contained in the onium salt include cations represented by the following formulae, and the like.

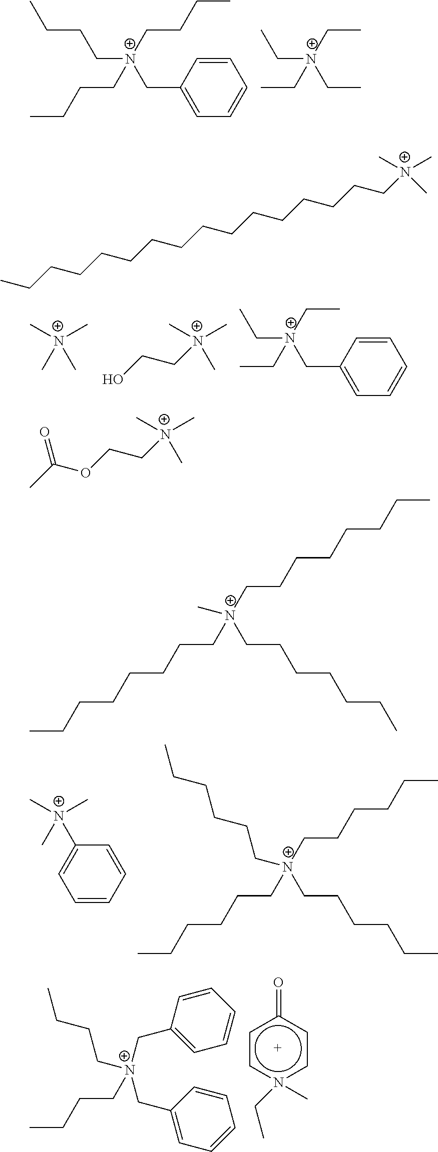

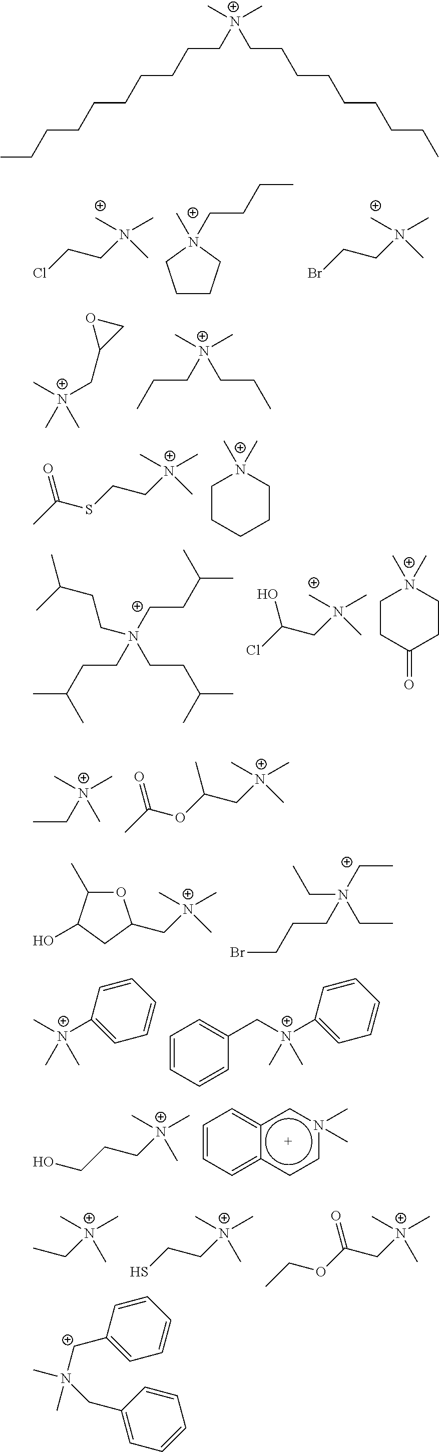

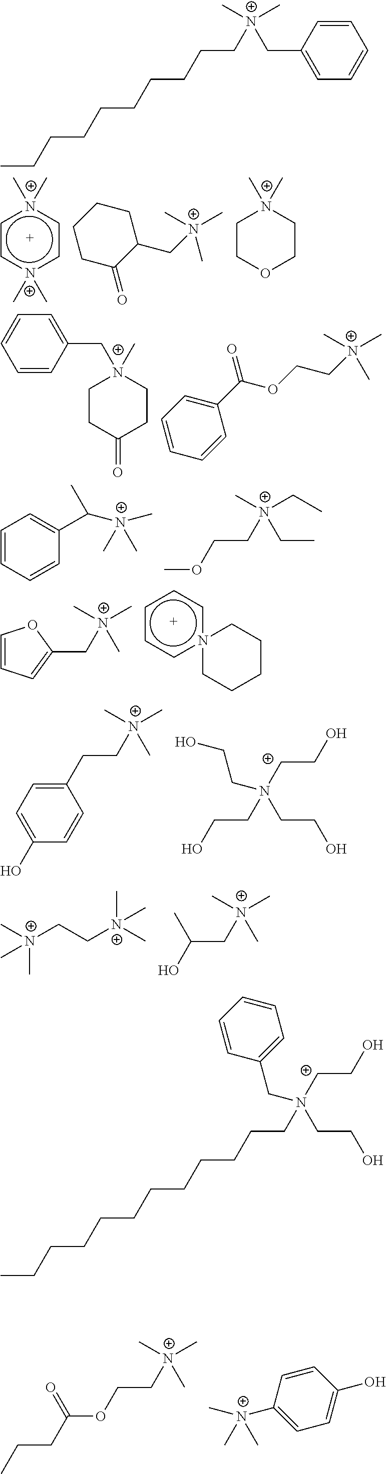

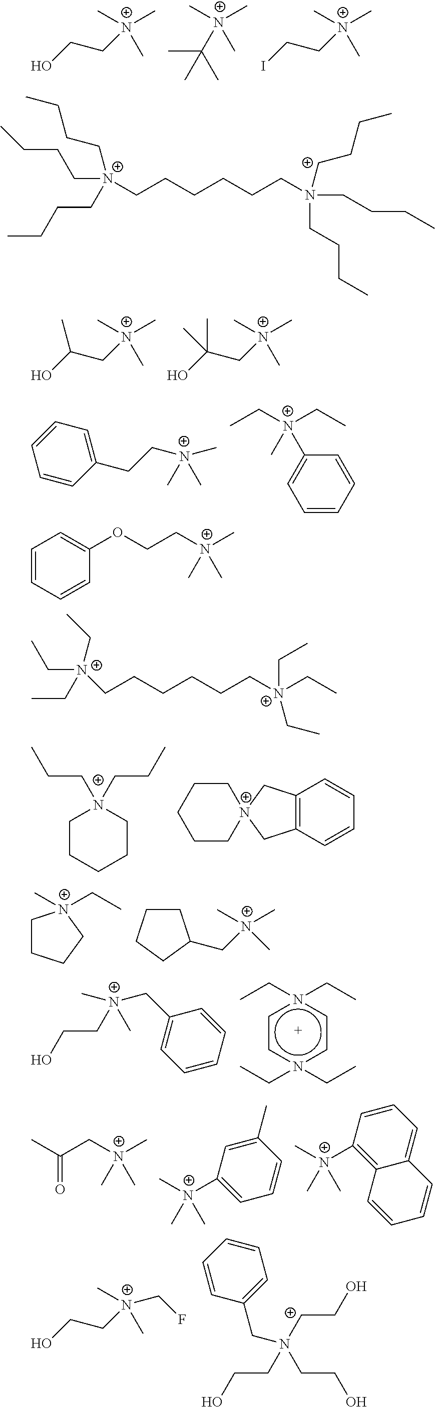

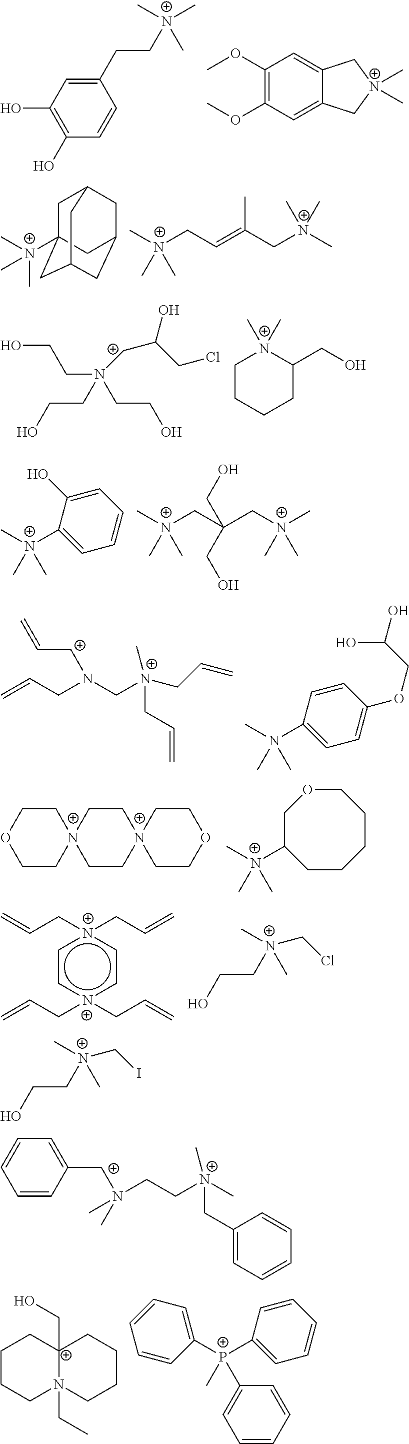

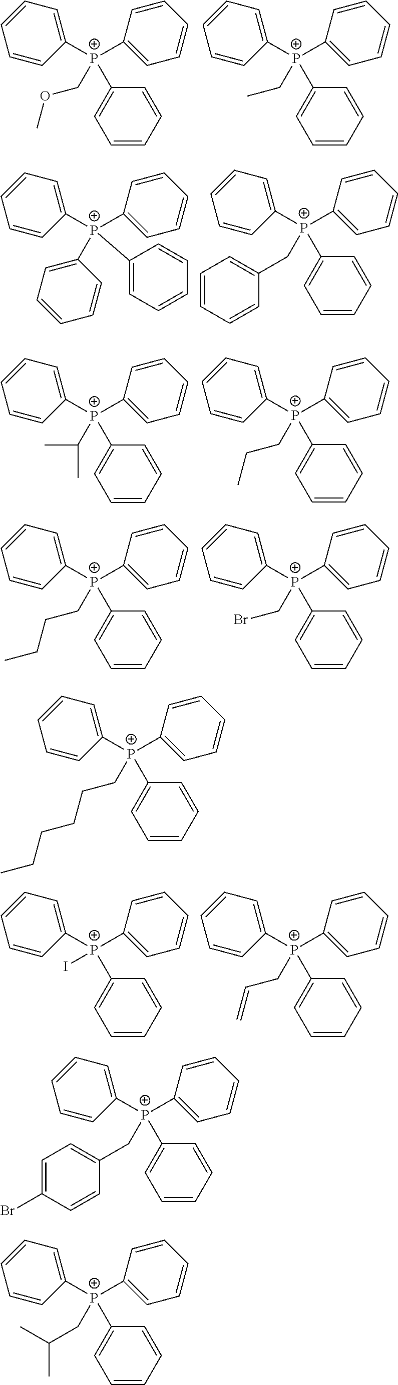

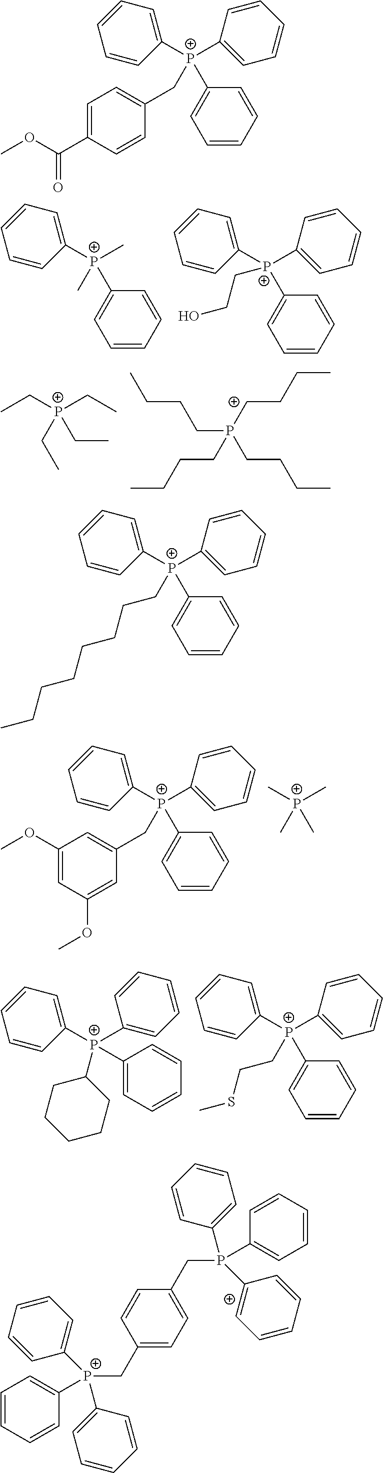

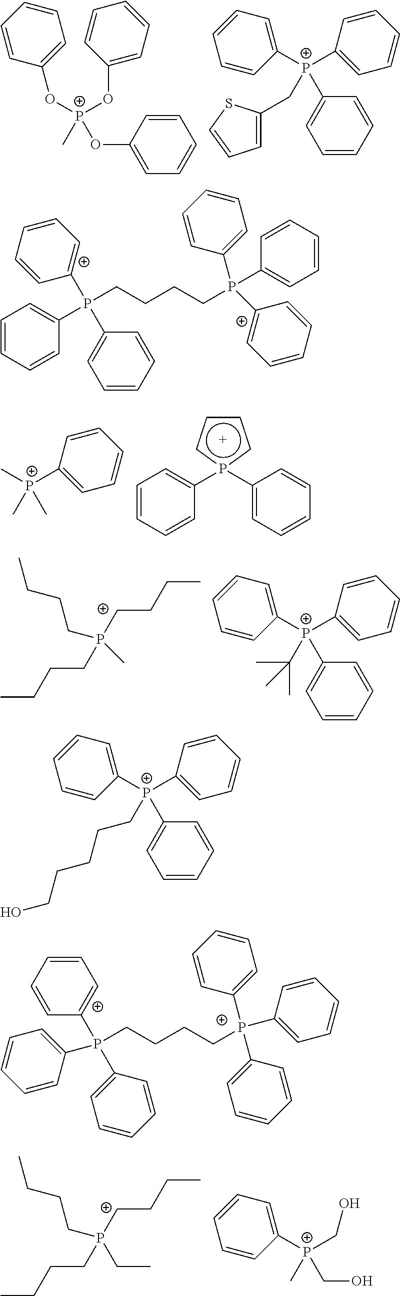

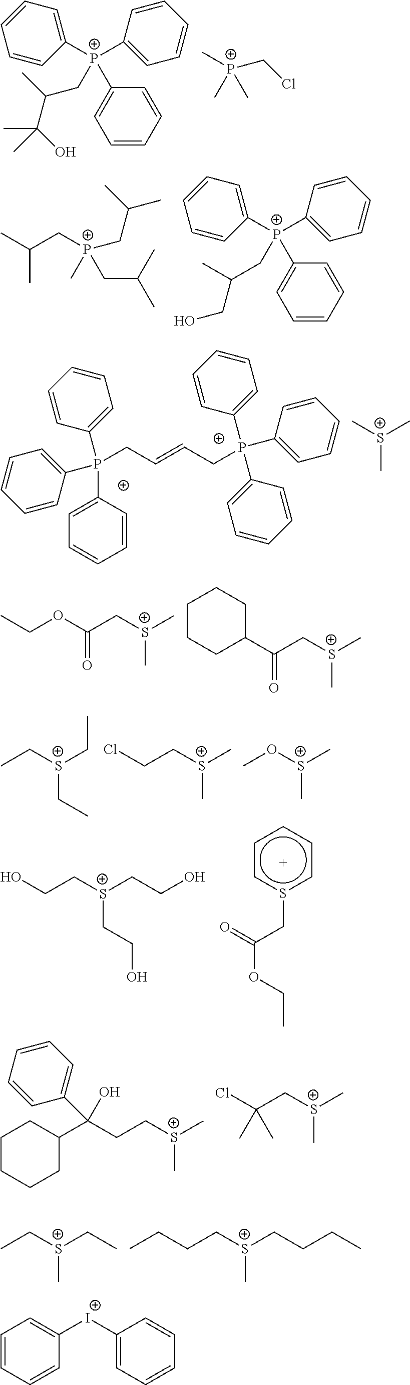

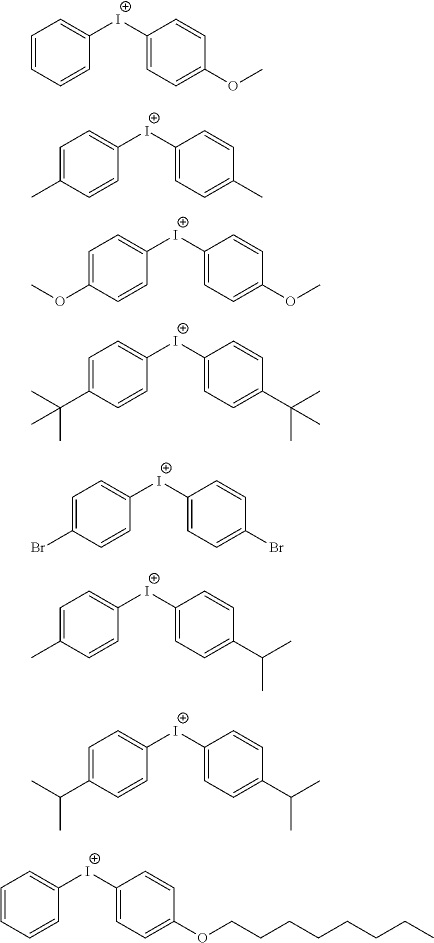

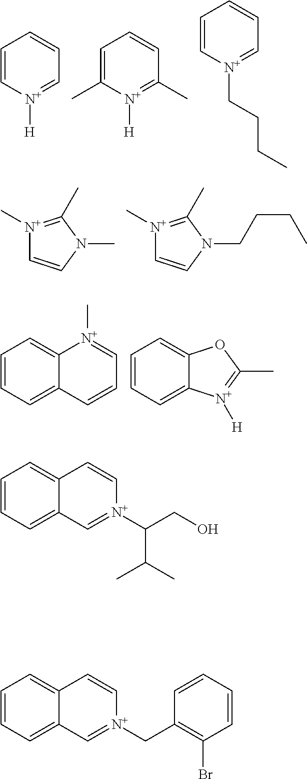

Examples of the anion contained in the onium salt also include anions represented by the following formulae, and the like.

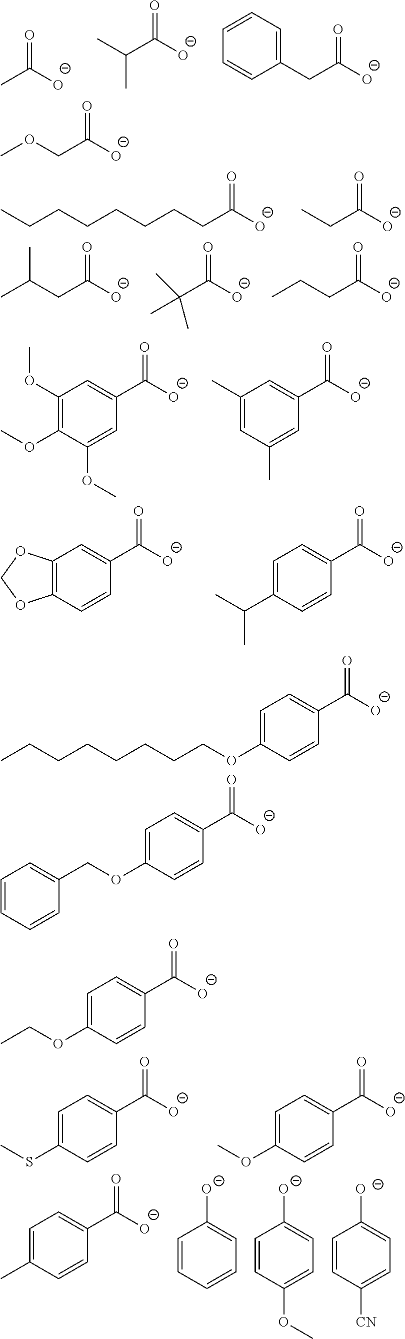

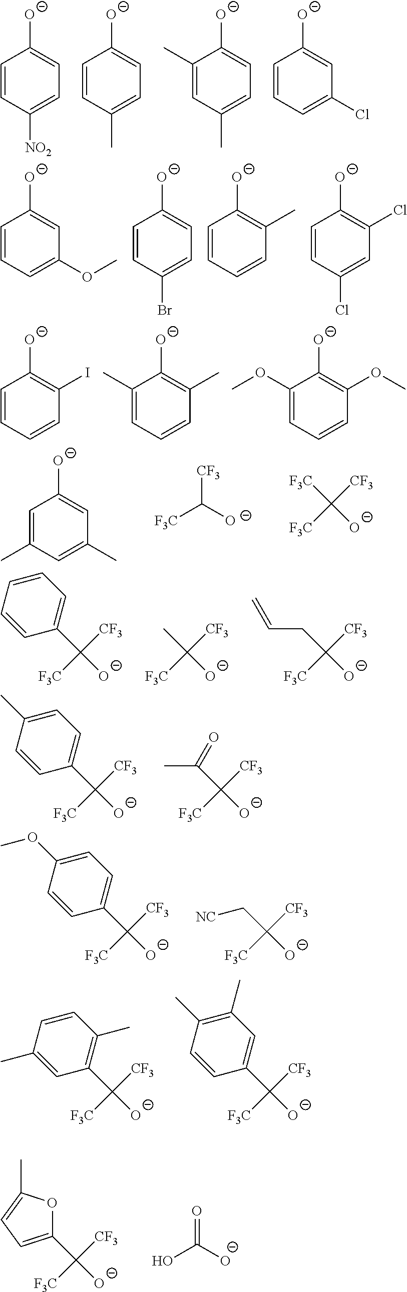

Examples of the onium salt include compounds represented by the following formulae, and the like.

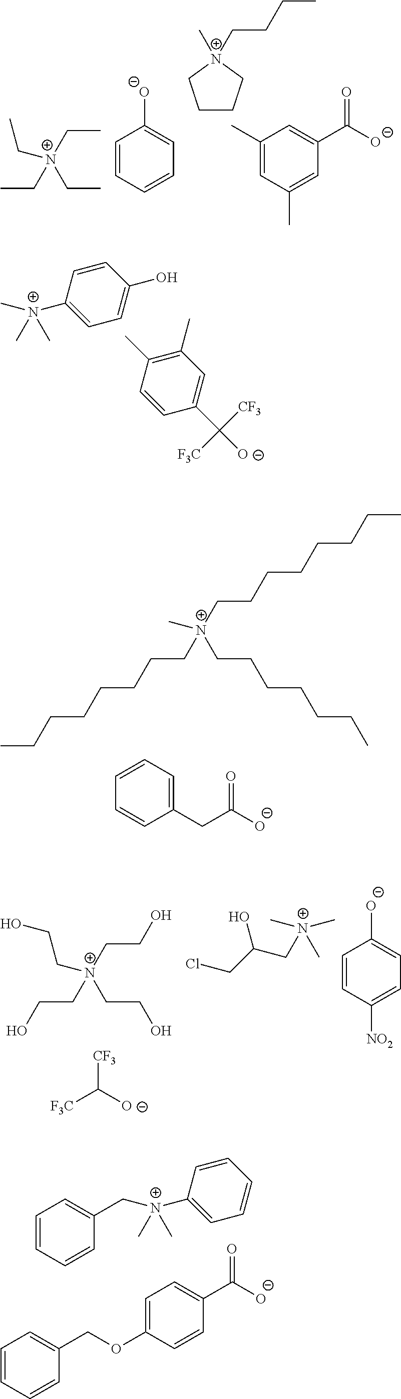

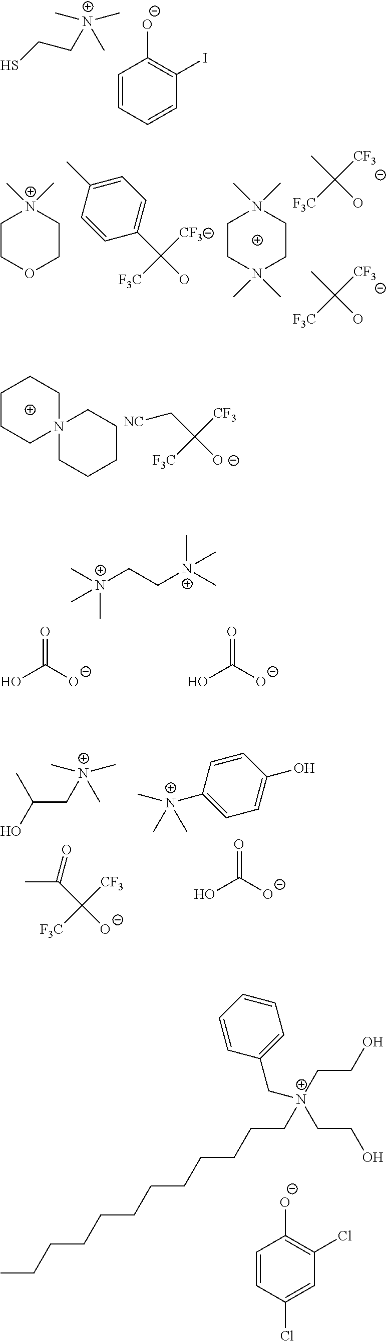

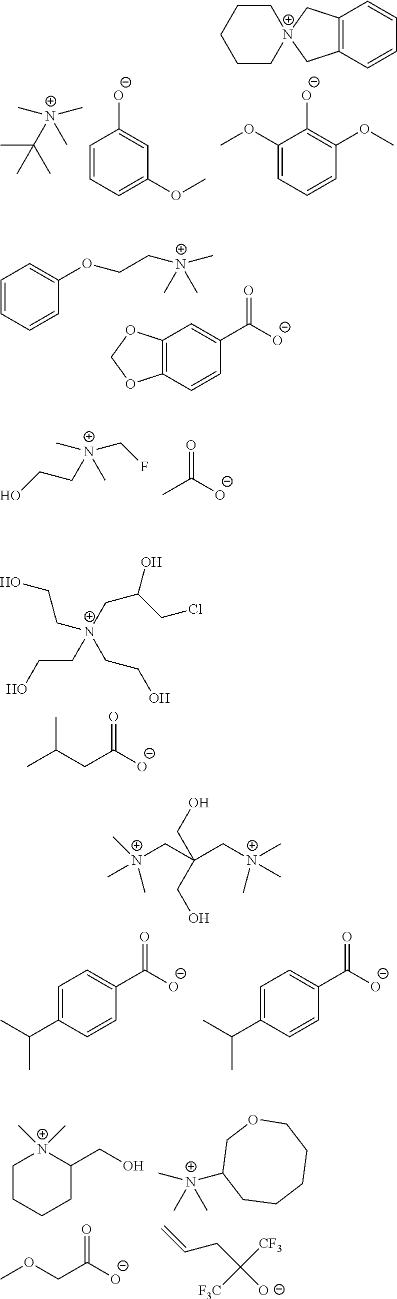

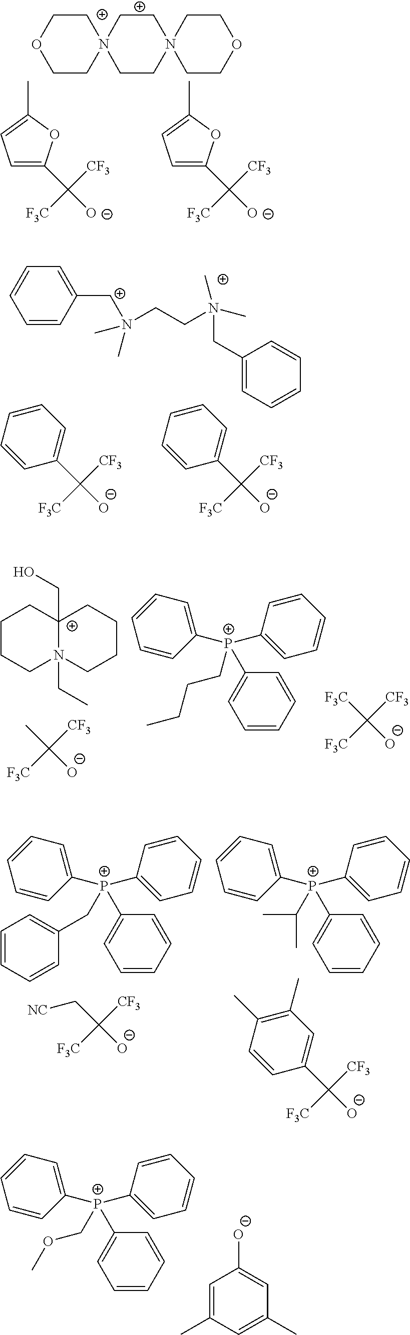

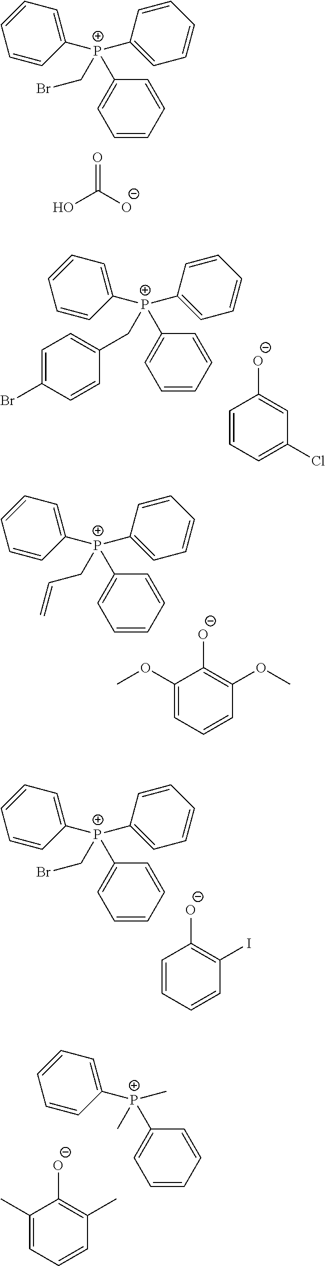

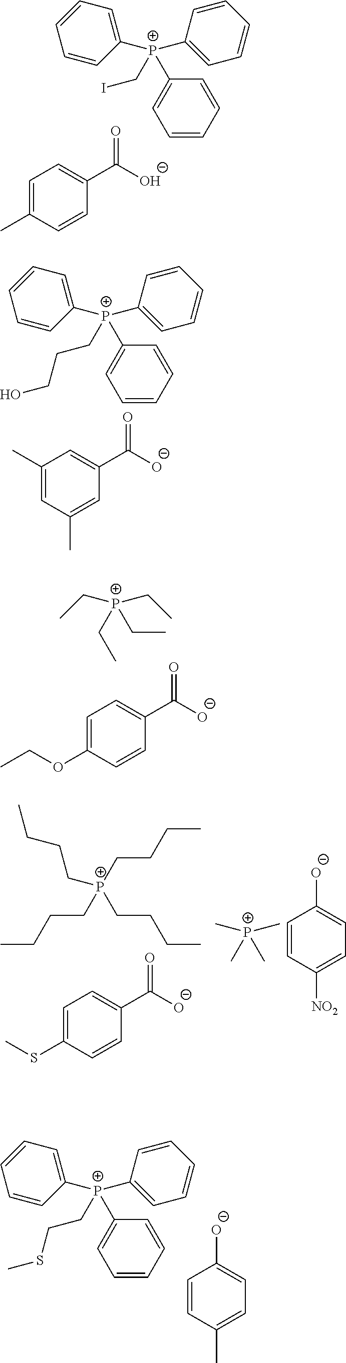

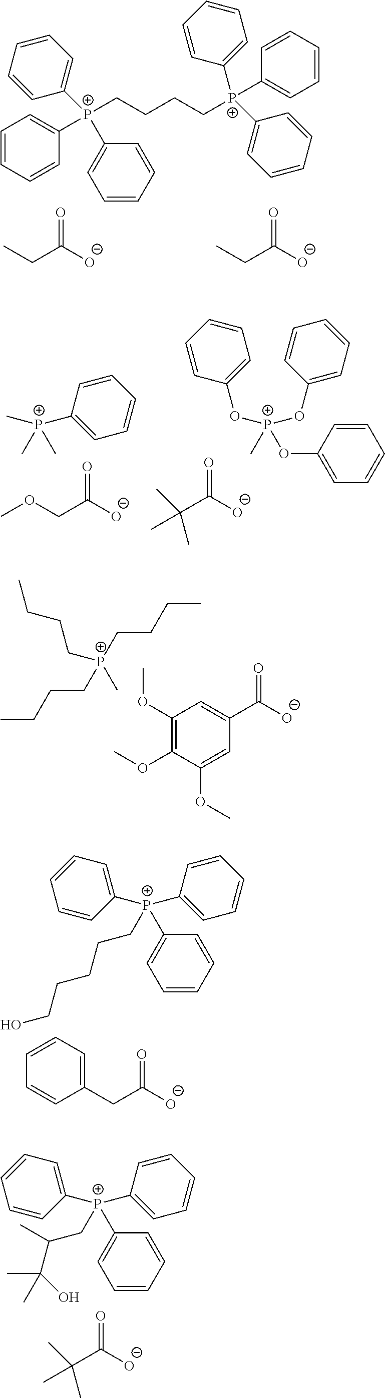

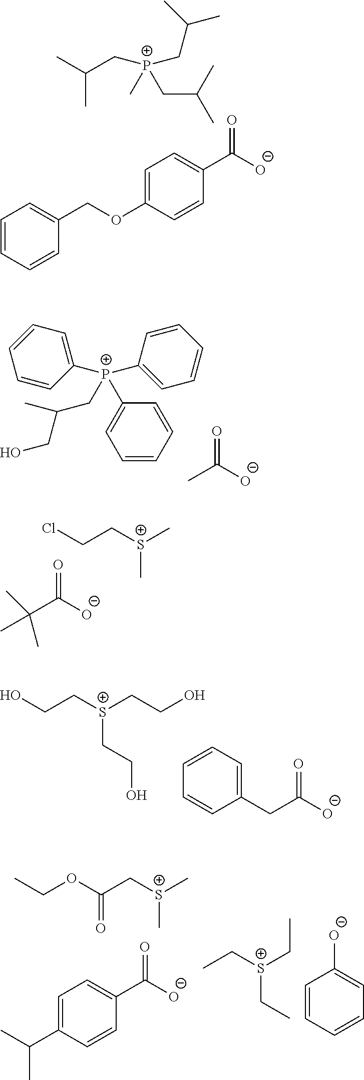

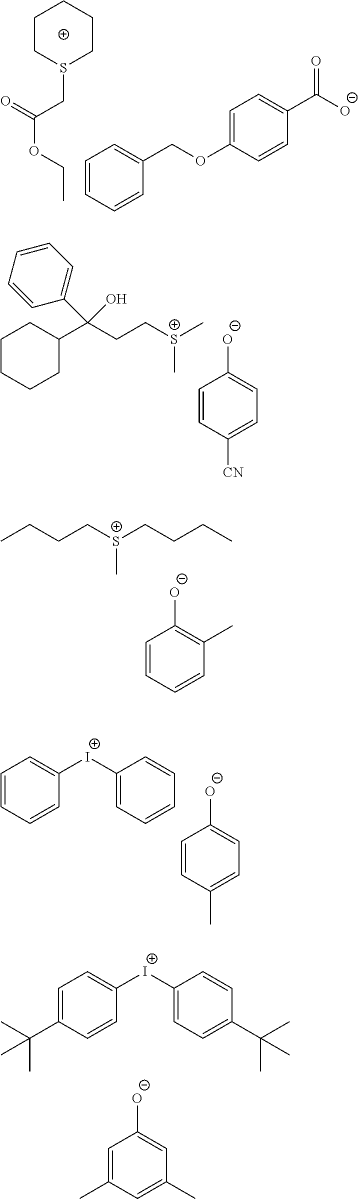

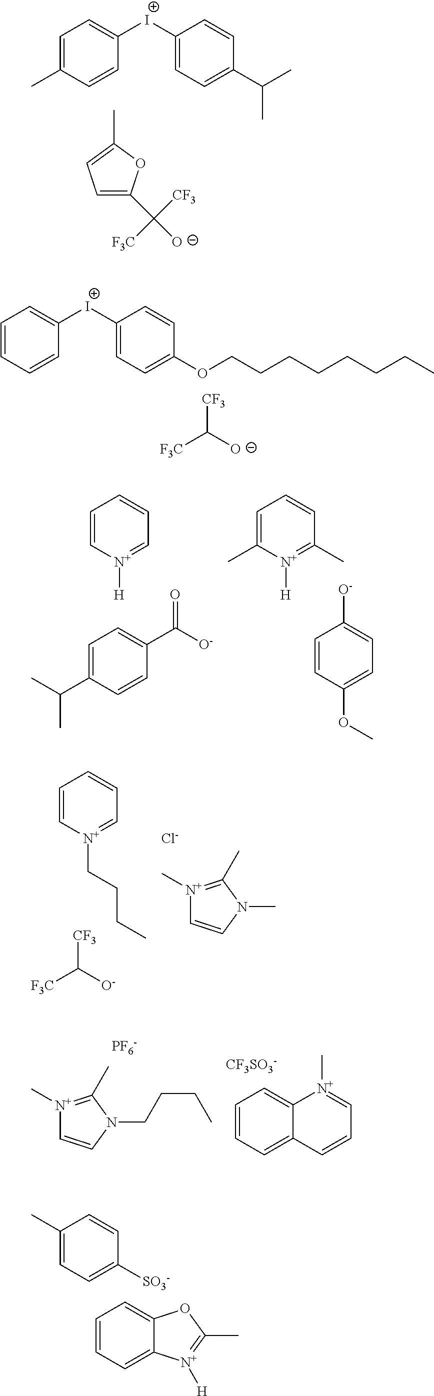

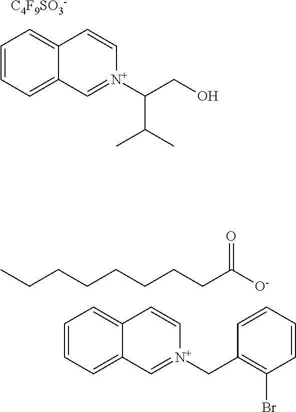 [SMILES: "C4F9SO3-" ; CC(C)C(CO)[n+]1ccc2ccccc2c1 ; CCCCCCCCC(=O)[O-] ; Brc1ccccc1C[n+]1ccc2ccccc2c1]

The lower limit of the pKa of a conjugate acid of the anion contained in the onium salt is preferably 4.0, and more preferably 5.0. The upper limit of the pKa is preferably 11.0, and more preferably 10.5. When the pKa of the conjugate acid of the anion falls within the above range, pattern collapse of the resist pattern can be inhibited more favorably. It is to be noted that the pKa is a value calculated using ACD/ChemSketch (ACD/Labs 8.00 Release Product Version: 8.08).

The pKa values of the conjugate acids of the anions are shown below.

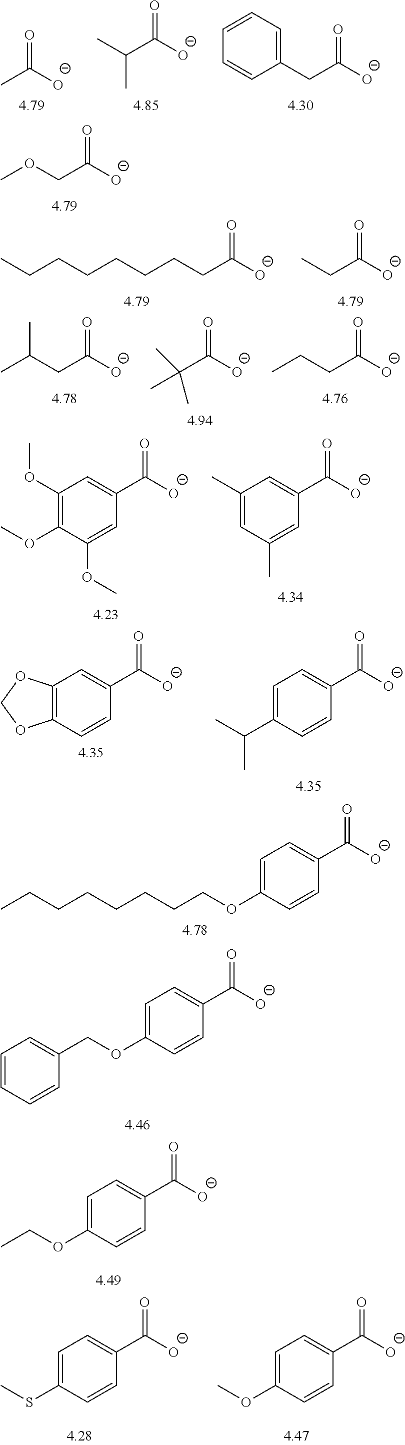

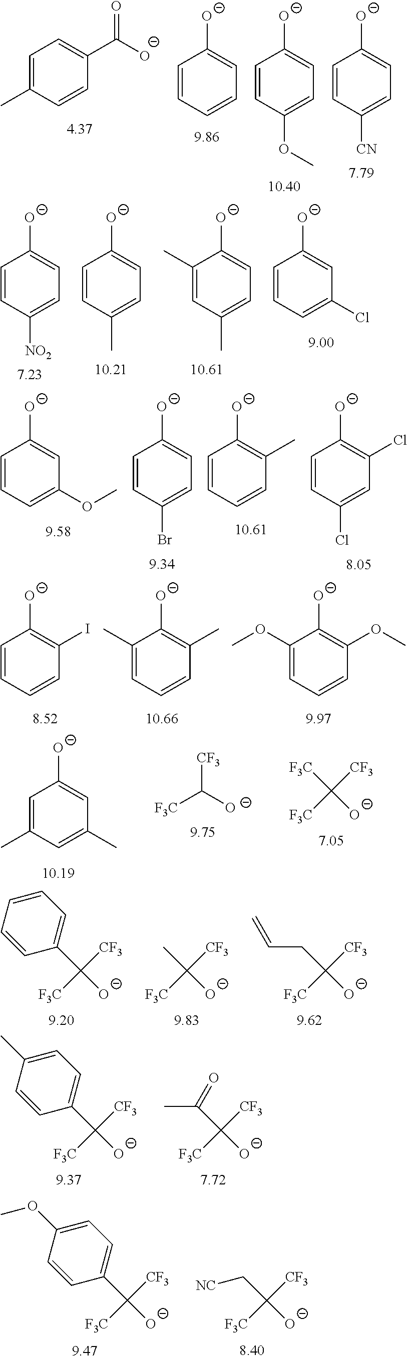

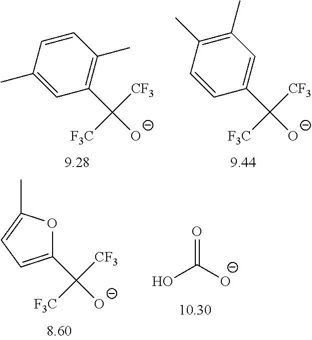

The lower limit of the ratio of the sum of the atomic masses of all the carbon atoms contained in the cation of the onium salt to the sum of the atomic masses of all the atoms constituting the cation of the onium salt ([(the number of carbon atoms)×12]/(the sum of the atomic masses of all the atoms constituting the cation)) is preferably 0.4, and more preferably 0.5. The upper limit of the ratio is preferably 0.75, and more preferably 0.65.

As the onium salt, a compound represented by the following formula (B-1) and a compound represented by the following formula (B-2) are preferred.

M⁺(R^{C})ₘ₁Y⁻ (B-1)

L^{A}M⁺R^{C})ₘ₂]2Y⁻ (B-2)

In the above formulae (B-1) and (B-2), M⁺s each independently represent a nitrogen cation, a phosphorus cation, a sulfur cation or an iodine cation; R^{C}s each independently represent a hydrogen atom or a monovalent organic group; m1 is an integer of 2 to 4; m2 is 3 in a case where M⁺ represents the nitrogen cation or the phosphorus cation, m2 is 2 in a case where M⁺ represents the sulfur cation, and m2 is 1 in a case where M⁺ represents the iodine cation, wherein in a case where R^{C} is present in a plurality of number, a plurality of R^{C}s may be identical or different, and may taken together represent a ring structure together with the M⁺ to which the plurality of R^{C}s bond; L^{A} represents a divalent linking group; and Y⁻s each independently represent a monovalent anion.

M⁺ preferably represents the nitrogen cation.

The monovalent organic group which may be represented by R^{C} is exemplified by a monovalent hydrocarbon group, a group obtained by incorporating a hetero atom-containing group between two adjacent carbon atoms of the hydrocarbon group, a group obtained by substituting with a substituent, a part or all of hydrogen atoms included in the hydrocarbon group or the group obtained by incorporating a hetero atom-containing group between two adjacent carbon atoms of the hydrocarbon group, and the like.

Examples of the hydrocarbon group include: chain hydrocarbon groups such as alkyl groups, alkenyl groups and alkynyl groups; alicyclic hydrocarbon groups such as cycloalkyl groups and cycloalkenyl groups; aromatic hydrocarbon groups such as aryl groups and aralkyl groups; and the like. The number of carbon atoms of the chain hydrocarbon group is preferably 1 to 20, more preferably 1 to 15, and still more preferably 1 to 5. The number of carbon atoms of the alicyclic hydrocarbon group is preferably 3 to 20, and more preferably 5 to 15. The number of carbon atoms of the aromatic hydrocarbon group is preferably 6 to 20, and more preferably 6 to 10.

Examples of the hetero atom of the hetero atom-containing group include halogen atoms, an oxygen atom, a nitrogen atom, a sulfur atom, a selenium atom, a tellurium atom, and the like. Examples of the hetero atom-containing group include —Y₁—, —N(R^{a})—, —C(═Y₂)—, —CON(R^{b})—, —C(═Y₃)Y₄—, —SOₜ—, —SO₂N(R^{c})—, halogen atoms, a combination of at least two of these groups, and the like, wherein Y₁ to Y₄ each independently represent an oxygen atom, a sulfur atom, a selenium atom or a tellurium atom. Of these, Y₁ to Y₄ each independently represent preferably the oxygen atom or the sulfur atom in light of greater ease of handling. R^{a}, R^{b} and R^{c} each independently represent a hydrogen atom or a hydrocarbon group having 1 to 20 carbon atoms, and t is an integer of 1 to 3. In a case where the hetero atom-containing group is included between two adjacent carbon atoms of the aromatic hydrocarbon group, an aromatic heterocyclic group is formed.

R^{C} preferably represents an alkyl group, an alkenyl group, a cycloalkyl group, an aryl group, or a group obtained by incorporating a hetero atom-containing group between two adjacent carbon atoms of these groups.

In a case where the ring structure taken together represented by the plurality of R^{C}s has aromaticity, the cation of the onium salt is exemplified by a pyridinium cation represented by the following formula (C-1), and the like. In addition, in a case where R^{C} has an additional hetero atom, the cation of the onium salt is exemplified by an imidazolium cation represented by the following formula (C-2), and the like.

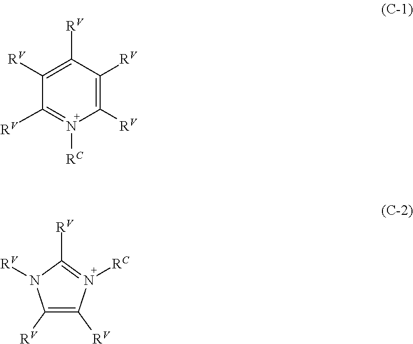

In the above formulae (C-1) and (C-2), R^{V}s each independently represent a hydrogen atom or an alkyl group, wherein the plurality of R^{V}s may taken together represent a ring together with the carbon chain to which the plurality of R^{V}s bond; and R^{C} is as defined in the above formula (B-1).

Examples of the divalent linking group represented by L^{A} include substituted or unsubstituted divalent hydrocarbon groups, —O—, —S—, —SO₂—, —NR—, —CO—, —NH—, —COO—, —CONH—, or a combination of at least two of these groups, and the like, wherein R represents an alkyl group. Of these, the substituted or unsubstituted divalent hydrocarbon groups are preferred, substituted or unsubstituted divalent chain hydrocarbon groups having 1 to 8 carbon atoms, substituted or unsubstituted divalent alicyclic hydrocarbon groups having 3 to 10 carbon atoms and substituted or unsubstituted divalent aromatic hydrocarbon groups having 6 to 12 carbon atoms are more preferred, and a methylene group, an ethylene group, a propylene group and a phenylene group are still more preferred.

Polymer that Includes Onium Salt

The polymer that includes an onium salt has an onium salt structure in a side chain or main chain thereof. The polymer that includes an onium salt can form a hydrogen bond and/or a dipole-dipole interaction with a polar group such as —COOH generated in the polymer (A). The definition of the onium salt in this section is the same as the definition of the aforementioned onium salt. The polymer that includes an onium salt is exemplified by a polymer having a structural unit that includes an onium salt structure, and the like.

Examples of the polymer that includes an onium salt include a polymer that includes a structural unit represented by the following formula (D-1), and the like.

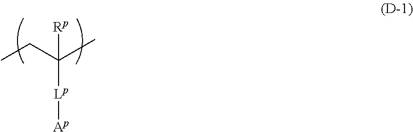

In the above formula (D-1), R^{p} represents a hydrogen atom or an alkyl group; L^{p} represents a divalent linking group; and A^{p} represents a group obtained by eliminating one hydrogen atom from the onium salt represented by either the formula (B-1) or the formula (B-2).

The number of carbon atoms of the alkyl group which may be represented by R^{p} is preferably 1 to 20, and more preferably 1 to 10.

Examples of the divalent linking group represented by L^{p} include divalent linking groups similar to those exemplified in connection with the divalent linking group represented by L^{A}, and the like. Of these, the alkylene groups, the arylene groups, —COO— and a combination of at least two of these groups are preferred, and the alkylene groups are more preferred.

The lower limit of the proportion of the structural unit represented by the above formula (D-1) with respect to the total structural units constituting the polymer having a structural unit that includes an onium salt is preferably 30 mol %, and more preferably 50 mol %. The upper limit of the proportion of the structural unit represented by the above formula (D-1) contained is preferably 100 mol %, and more preferably 90 mol %.

The lower limit of the Mw of the polymer that includes an onium salt is preferably 1,000, and more preferably 2,000. The upper limit of the Mw is preferably 30,000, and more preferably 10,000.

As the structural unit represented by the above formula (D-1), a structural unit represented by the following formula (D-2) is preferred.

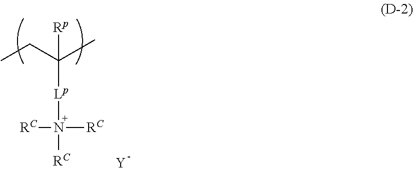

In the above formula (D-2), R^{C}s each independently represent a hydrogen atom or a monovalent organic group; and R^{p}, L^{p} and Y⁻ are as defined in the above formula (D-1).

As the structural unit represented by the above formula (D-2), structural units represented by the following formulae (D-3) to (D-5) are preferred.

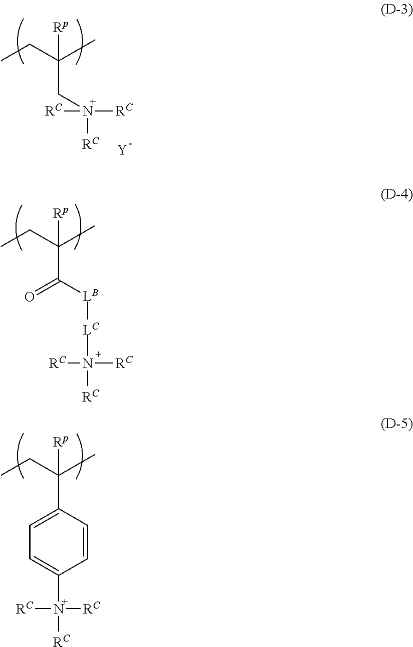

In the above formulae (D-3) to (D-5), R^{C}, R^{p} and Y⁻ are as defined in the above formula (D-2).

In the above formula (D-4), L^{B} represents —O—, —NH— or —NR—; and L^{C} represents an alkylene group.

Basic Polymer

The basic polymer includes a proton-accepting group. The basic polymer can form a hydrogen bond, a covalent bond, a coordinate bond and/or a dipole-dipole interaction by means of the proton-accepting group with a polar group, which will be described later, generated in the polymer (A). The proton-accepting group may be included in any of the main chain and a side chain of the basic polymer.

The basic polymer typically has a structural unit that includes a proton-accepting group, and this basic polymer may further have a structural unit that does not include a proton-accepting group.

Examples of the proton-accepting group include an amino group, a phosphino group, and the like. The “amino group” as referred to encompasses a primary amino group, a secondary amino group and a tertiary amino group. It is to be noted that the secondary amino group also encompasses cyclic secondary amino groups such as a pyrrolidino group, a piperidino group, a piperazino group and a hexahydrotriazino group. The “phosphino group” as referred to encompasses a primary phosphino group, a secondary phosphino group and a tertiary phosphino group. The proton-accepting group is preferably the amino group.

The side chain that includes the amino group is exemplified by structures represented by the following formulae, and the like.

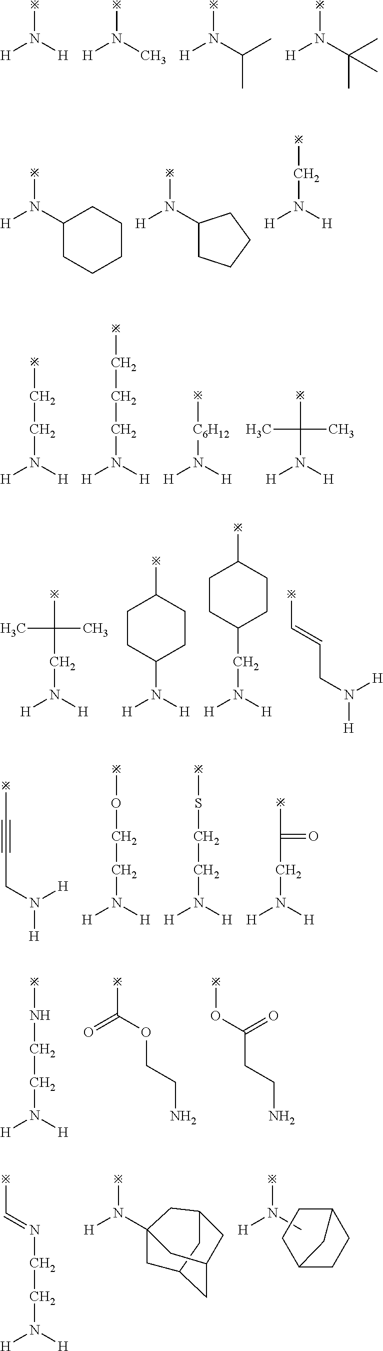

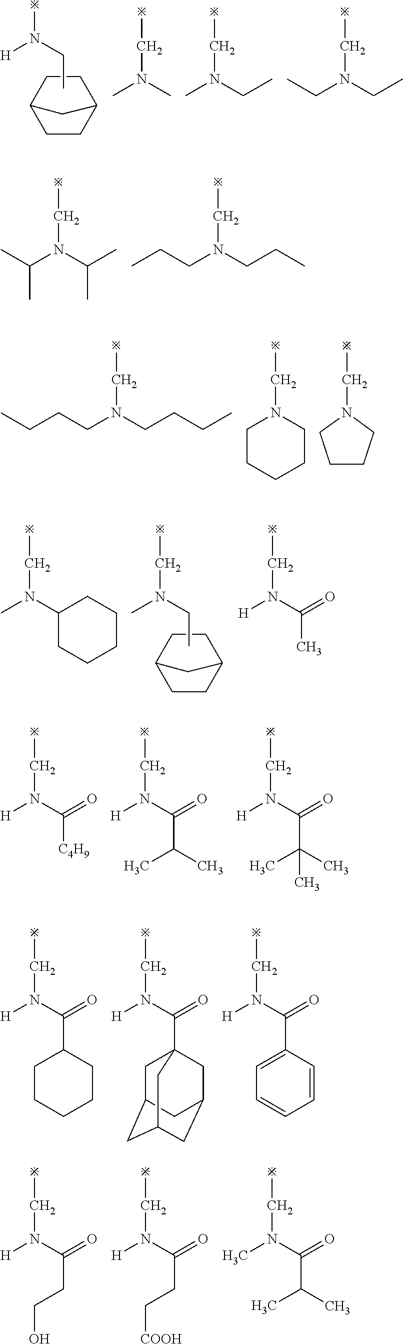

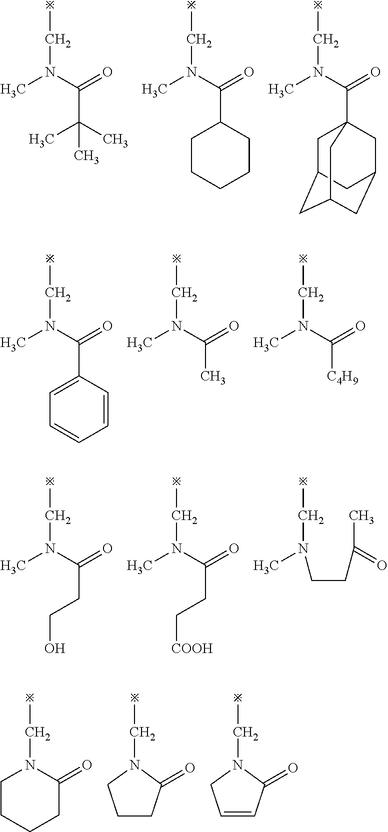

In the above formula, * denotes a binding site to the main chain of the basic polymer.

Examples of the basic polymer that includes the amino group include polyallylamine, polyethyleneimine, polyvinylpyridine, polyvinylimidazole, polypyrimidine, polytriazole, polyquinoline, polyindole, polypurine, polyvinylpyrrolidone, polybenzimidazole, and the like.

The structural unit that includes the proton-accepting group is exemplified by a structural unit represented by the following formula (E), and the like.

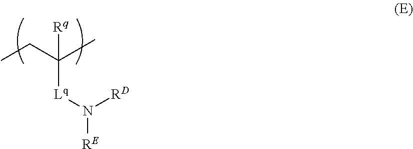

In the above formula (E), R^{q} represents a hydrogen atom or an alkyl group; R^{D} and R^{E} each independently represent a hydrogen atom or a monovalent organic group; and L^{q} represents a divalent linking group.

The number of carbon atoms of the alkyl group which may be represented by R^{q} is preferably no less than 1 and no greater than 4, and more preferably 1 or 2.

Examples of the monovalent organic group which may be represented by R^{D} or R^{E} include organic groups similar to those exemplified in connection with the organic group represented by R^{C}, and the like.

Examples of the divalent linking group represented by L^{q} include divalent linking groups similar to those exemplified in connection with the divalent linking group represented by L^{A}, and the like. Of these, the alkylene groups, the arylene groups, —COO— and a combination of at least two of these groups are preferred, and the alkylene groups are more preferred.

Examples of the structural unit represented by the above formula (E) include structural units represented by the following formulae, and the like.

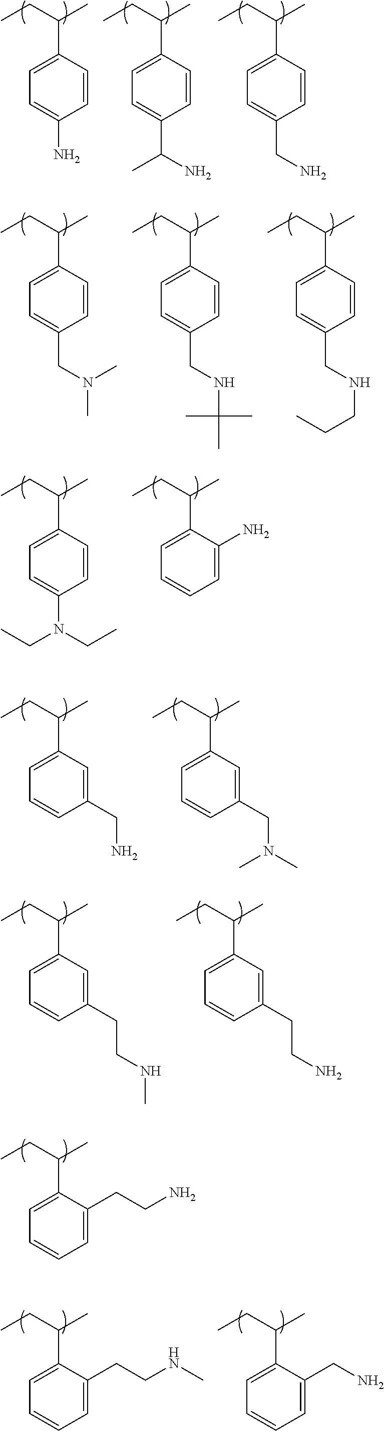

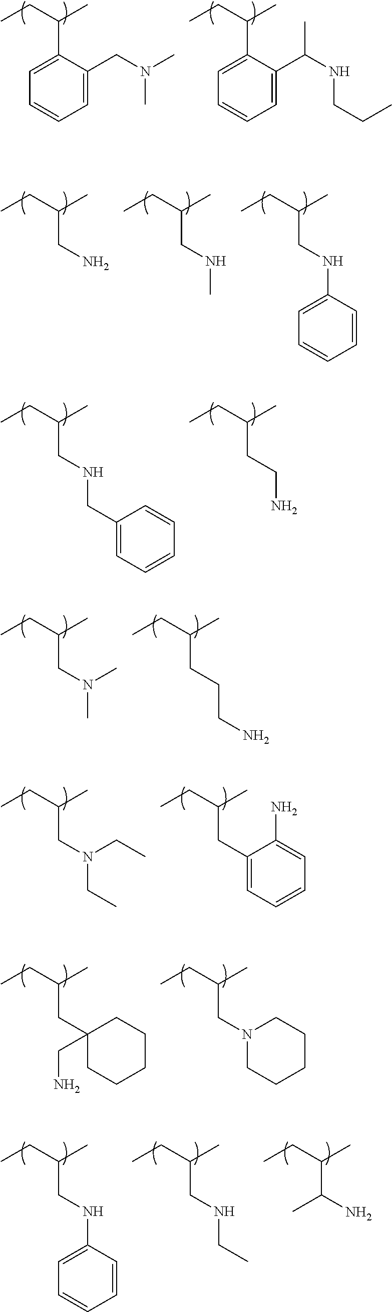

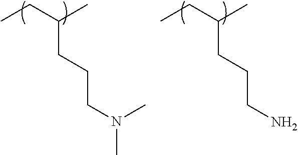

The lower limit of the proportion of the structural unit represented by the above formula (E) with respect to the total structural units constituting the polymer having the structural unit that includes the proton-accepting group is preferably 40 mol %, and more preferably 70 mol %. The upper limit of the proportion of the structural unit represented by the above formula (E) contained is preferably 100 mol %, and more preferably 90 mol %.

The lower limit of the Mw of the basic polymer is preferably 1,000, and more preferably 2,000. The upper limit of the Mw is preferably 30,000, and more preferably 10,000.

Phosphorus Compound

The phosphorus compound contains at least one trivalent phosphorus atom. The lower limit of the molecular weight of the phosphorus compound is preferably 70, and more preferably 100. The upper limit of the molecular weight is preferably 500, and more preferably 300.

The phosphorus compound is preferably a compound represented by the following formula (F-1) or a compound represented by the following formula (F-2).

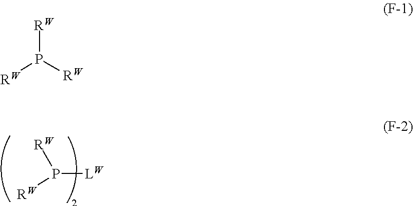

In the above formulae (F-1) and (F-2), R^{W}s each independently represent a monovalent organic group; and L^{W} represents a divalent linking group.

Examples of the monovalent organic group represented by R^{W} include organic groups similar to those exemplified in connection with the organic group represented by R^{C}, and the like.

Examples of the divalent linking group represented by L^{W} include divalent linking groups similar to those exemplified in connection with the divalent linking group represented by L^{A}, and the like. Of these, the divalent hydrocarbon groups are preferred.

Examples of the phosphorus compound include compounds represented by the following formulae, and the like.

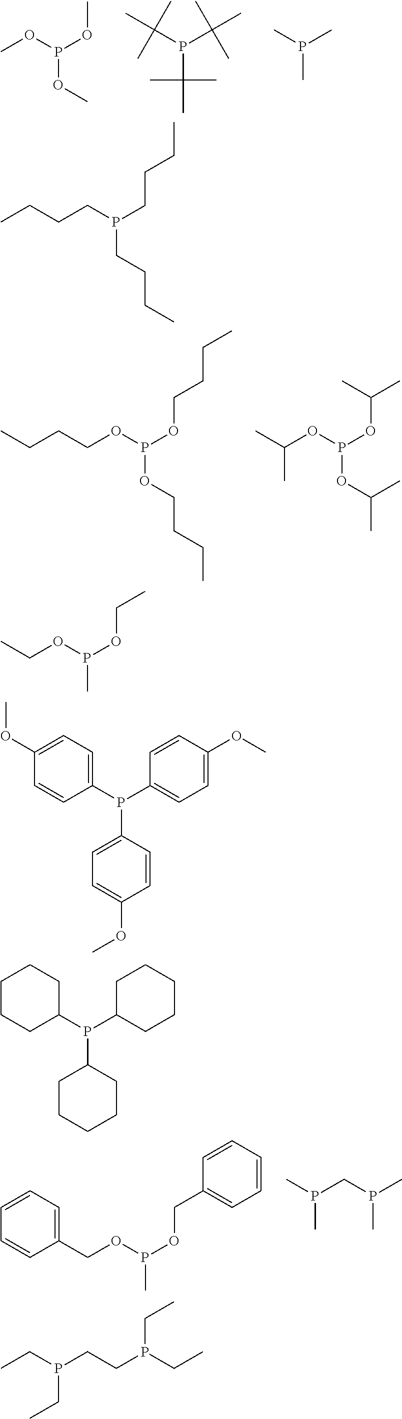

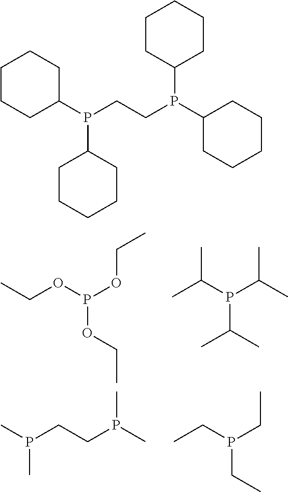

With reference to FIGS. 1 and 2, the resist pattern-forming method of the present embodiment is described. In the present embodiment, before forming a pattern latent image by irradiating with the exposure light (II), the acid is generated from the component (B) in the resist film 12 by irradiating with the exposure light (I). Since the amount of the acid generated from the component (B) in the exposure step (2) can be reduced, the irradiation time period of the exposure light (II) can be shortened, or an light source being inexpensive and having low power can be used as the light source for the exposure light (II). For example, when the pattern latent image is formed by irradiating the resist film 12 patternwise with EUV using EUV as the exposure light (II), the irradiation time period with EUV can be shortened according to the present embodiment, and thus even if a low-power light source is used, high throughput can be attained. In such a manner, problems resulting from a trade-off relation ship can be solved according to the present embodiment, whereby the sensitivity of the resist film 12 can be improved while the pattern resolution is maintained. In addition, an improvement of throughput in the exposure step is realized, and thus a significant reduction in the cost for the exposure system can be achieved. Moreover, since a low-power light source is applicable, lifetime of consumable parts in a light source device and a lithography device is prolonged, whereby costs for maintenance and operation can be significantly reduced.

Furthermore, in the present embodiment, a maintaining step for inhibiting a decrease in the amount of the acid and/or the sensitizer in the resist film 12 may be carried out after the exposure step (1) and before the exposure step (2). In a case where a decrease in the amount of the acid and/or the sensitizer is not inhibited, the amount of the acid and/or the sensitizer in the resist film 12 decreases in a time dependent manner after the exposure step (1). Thus, it is necessary to supply the resist film with the energy again in the exposure step (2) for generating the acid and/or the sensitizer so as to compensating for the decrease. On the other hand, since a decrease in the amount of the acid and/or the sensitizer in the resist film 12 is inhibited in the present embodiment, the amount of the acid and/or the sensitizer in the resist film 12 is maintained, and thus a comparatively small energy dose applied to the resist film 12 in the exposure step (2) may be sufficient. As a result, the sensitivity of the resist film 12 is improved, thereby enabling the shortening of the exposure time period, and a further improvement of the throughput in the exposure step to be achieved.

It is to be noted that in the present embodiment, irradiation with the exposure light (I) over the entire face of the resist film 12 is executed in the exposure step (1), and in the exposure step (2), the resist film 12 is irradiated patternwise with the exposure light (II), but the present invention is not limited thereto. As long as the sum of the irradiation dose Ef of the exposure light (I) and the irradiation dose Ep of the exposure light (II) exceeds the necessary energy dose Et, it is acceptable to irradiate the resist film 12 patternwise with the exposure light (I) in the exposure step (1), followed by the irradiation with the exposure light (II) over the entire face of the resist film 12 in the exposure step (2). It is to be noted that in this instance, the exposure light (I) may be appropriately selected depending on the resolution of the pattern to be formed, and may be for example, electromagnetic radiations such as UV, DUV, EUV and X-ray, or electron beams. The exposure light (II) may be, for example, electromagnetic radiations such as visible light, UV, DUV and EUV, or may be electron beams or ion beams.

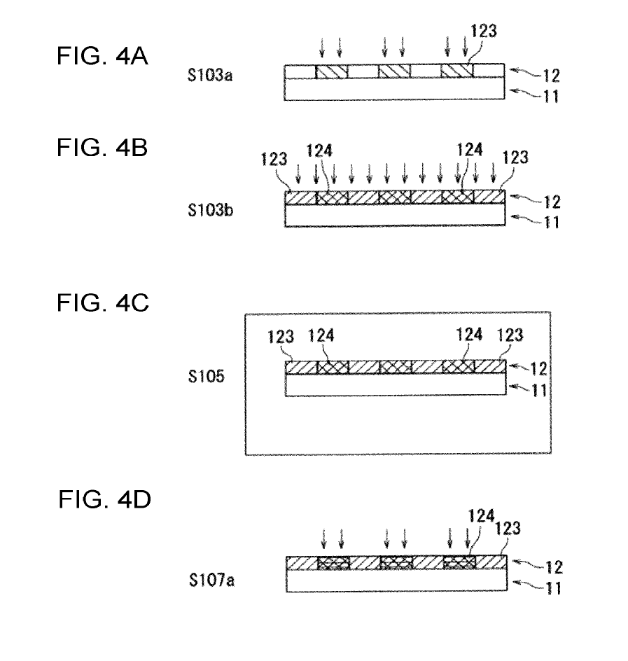

FIGS. 4A to 4D show explanatory views illustrating the steps of the resist pattern-forming method according to a further embodiment of the present invention. In the following, the resist pattern-forming method of the present embodiment will be described with reference to FIGS. 4, 1 and 2. The resist pattern-forming method of the present embodiment includes the resist film-forming step (S101), the exposure step (1) (S103), the exposure step (2) (S107) and the development step (S110). Except for the exposure step (1) carried out through two irradiation steps, and the exposure step (2) carried out through a single irradiation step, the other steps are carried out similarly to the embodiment described with reference to FIGS. 1 to 3, and therefore only necessary portions for the explanation will be described with reference to the drawings.

In the present embodiment, as shown in FIGS. 4A and 4B, the exposure step (1) includes a patternwise exposure step (i) (S103a) and a flood exposure step (i) (S103b). As shown in FIG. 4A, in the patternwise exposure step (i), the resist film 12 is irradiated patternwise with the exposure light (I). As shown in FIG. 4B, in the flood exposure step (i), a floodwise exposure is executed, i.e., one face of the resist film 12 is irradiated with the exposure light (I). The total irradiation dose Ef of the exposure light (I) in the patternwise exposure step (i) and the flood exposure step (i) does not exceed the latent image-forming energy dose Ea. Accordingly, after carrying out the exposure step (1), the resist film 12 has light-exposed regions (a) 123 which were irradiated only once with the exposure light (I), and light-exposed regions (b) 124 which were irradiated twice with the exposure light (I).

After completing the exposure step (1), the maintaining step (S105) may be carried out as shown in FIG. 4C. Next, the exposure step (2) is carried out. As shown in FIG. 4D, the exposure step (2) includes a patternwise exposure step (ii) (S107a). In the patternwise exposure step (ii), the resist film 12 is irradiated patternwise with the exposure light (II). Specifically, the light-exposed regions (b) 124 of the resist film 12 are irradiated with the exposure light (II). The irradiation dose of the exposure light (II) is predetermined such that the sum of the irradiation dose Ef of the exposure light (I) and the irradiation dose Ep of the exposure light (II) on the light-exposed regions (b) 124 after the irradiation exceeds the necessary energy dose Et.

In the present embodiment, since the irradiation dose Ef applied to the light-exposed regions (a) 123 of the resist film 12 does not exceed the latent image-forming energy dose Ea, the light-exposed regions (a) 123 are not made insoluble or hardly soluble in the development step. On the other hand, since the energy dose Es applied to the light-exposed regions (b) 124 of the resist film 12 exceeds the necessary energy dose Et, the light-exposed regions (b) 124 are made insoluble or hardly soluble in the development step. Thus, a predetermined resist pattern is formed on the substrate 11.

It is to be noted that the exposure step (1) is carried out with two irradiation steps, whereas the exposure step (2) is carried out with single irradiation step in FIGS. 4A to 4D, the present invention is not limited thereto. It is acceptable to carry out the exposure step (1) with single irradiation step, and to carry out the exposure step (2) with two irradiation steps. Alternatively, both the exposure step (1) and the exposure step (2) may be carried out with two or more exposure steps. For example, the exposure step (1) may include the flood exposure step (i), whereas the exposure step (2) may include the flood exposure step (ii) and the patternwise exposure step (ii).

Furthermore, when the exposure step (1) and/or the exposure step (2) are/is carried out through two irradiation procedures, the two irradiation procedures may be similar (any one of the flood exposure and the patternwise exposure), or different irradiation procedures may be employed. When a different irradiation procedure is employed, either the flood exposure or the patternwise exposure may be conducted in advance.

Still further, both the exposure step (1) and the exposure step (2) include the patternwise exposure step in FIG. 4A to 4D, but the present invention is not limited thereto. As long as the pattern latent image can be formed on the resist film 12, the patternwise exposure step may be included in any one of the exposure step (1) and the exposure step (2).

Although not shown in the figure, it is to be noted that the resist pattern-forming method of the embodiment of the present invention may further include a treatment step which is commonly carried out in the exposure step. For example, a heat treatment (PEB, e.g., pulse heat treatment) step carried out after the exposure step (2), as well as a reversal treatment step for reversing the resist film between the positive type and the negative type may be further included.

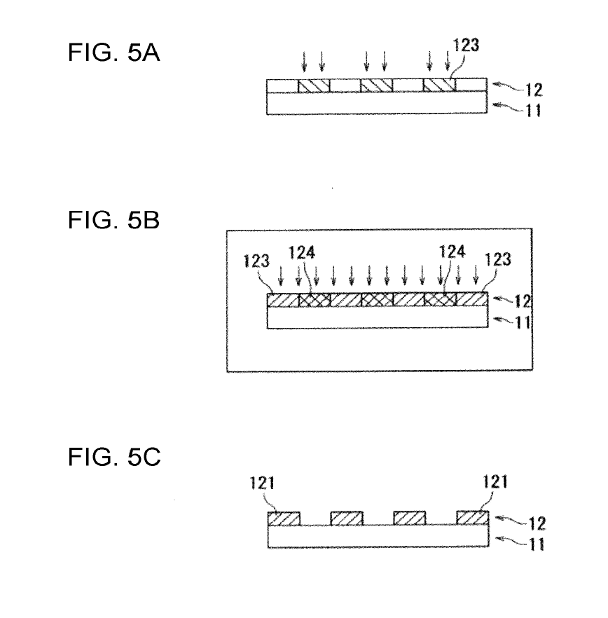

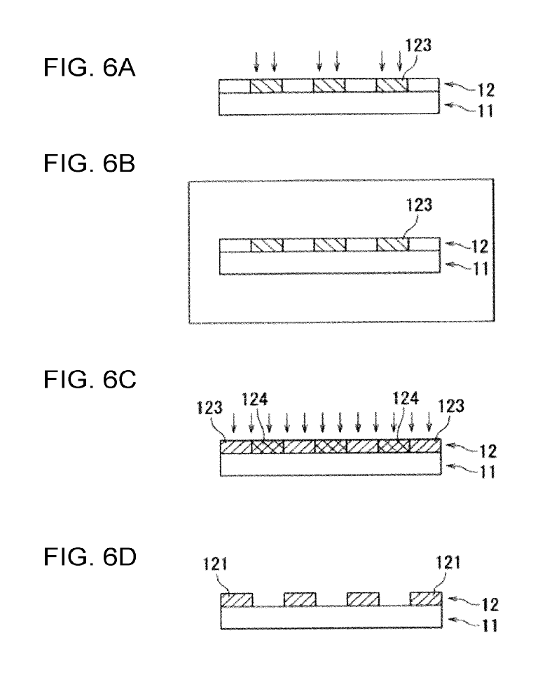

In the following, with reference to FIGS. 5 and 6, the resist pattern-forming method of the present embodiment will be described by way of Specific Examples. FIGS. 5A to 5C shows explanatory views illustrating Specific Example 1 of the resist pattern-forming method of the embodiment of present invention, and FIGS. 6A to 6D shows explanatory views illustrating Specific Example 2 of the resist pattern-forming method of the embodiment of the present invention. It is to be noted that in the following specific examples, the resist film 12 is formed from a chemically amplified radiation-sensitive resin composition (I).

### Specific Example 1

As shown in FIG. 5A, the exposure step (1) is carried out. In the exposure step (1), irradiation with the exposure light (I) is executed patternwise. When the exposure step (1) is carried out, the acid is generated from the component (B) in the regions irradiated patternwise with the exposure light (I), and the sensitizer is produced from the sensitizer precursor (C). In this step, due to a low patternwise irradiation dose, the resist pattern is not formed on the resist film 12 even if the development step is carried out.

Next, as shown in FIG. 5B, the maintaining step may be carried out. When the maintaining step is carried out, the resist film 12 is situated in an inert gas atmospheric or vacuum atmospheric environment. The decrease in the amount of the acid generated from the component (B) in the resist film 12, and the amount of the sensitizer produced from the sensitizer precursor (C) is inhibited.

Following or concurrently with the maintaining step, the exposure step (2) is carried out. In the exposure step (2), a floodwise exposure is executed, i.e., one face is irradiated with the exposure light (II). As shown in FIG. 5B, the exposure light (II) is appropriately selected such that: the acid from the component (B), and the sensitizer from the sensitizer precursor (C) are not generated substantially in unirradiated regions of the resist film 12; and the sensitizer produced from the sensitizer precursor (C) is activated. In the regions 123 of the resist film, the sensitizer is produced from the sensitizer precursor (C), and/or the acid (or an acid having a different structure from that of the aforementioned acid or a precursor of the acid) is generated from the component (B), by irradiating with the exposure light (II).

Accordingly, in the exposure step (2), even though the one face is irradiated with the exposure light (II), the acid is generated only in the regions irradiated patternwise first, and the activation of the sensitizer produced from the sensitizer precursor (C) occurs only in the regions irradiated patternwise first by irradiating the one face (floodwise). Thus, a large amount of the acid is generated only in the regions irradiated patternwise first, and even after the neutralization of the acid with a quencher that is a base, the acid is generated only in the regions irradiated patternwise first.

Thereafter, a heating step, and a development step are carried out to form a resist pattern as shown in FIG. 5C.

### Specific Example 2

As shown in FIG. 6A, the exposure step (1) is carried out. In the exposure step (1), irradiation with the exposure light (I) is executed patternwise. When the exposure step (1) is carried out, both the generation of the acid from the component (B), and the production of the sensitizer from the sensitizer precursor (C) occur in the regions irradiated patternwise with the exposure light (I). In this step, due to a low patternwise irradiation dose, the resist pattern is not formed on the resist film 12 even if the development step is carried out.

Next, as shown in FIG. 6B, the maintaining step is carried out. In the maintaining step, the resist film 12 is situated in an active gas atmospheric or active liquid environment so as to react with the sensitizer produced from the sensitizer precursor (C). The sensitizer is converted into the active substance α/stable substance α1 having a superior reaction efficiency, in the following exposure step (2).

Next, as shown in FIG. 6C, the exposure step (2) is carried out in the active atmospheric or active liquid environment. In the exposure step (2), a floodwise exposure is executed, i.e., one face is irradiated with the exposure light (II). The exposure light (II) is appropriately selected such that in unirradiated regions of the resist film 12, the acid from the component (B), and the sensitizer from the sensitizer precursor (C) are not generated substantially, and only the active substance α/stable substance α1 is activated. By irradiating with the exposure light (II), production of the sensitizer from the sensitizer precursor (C), and/or generation of the acid or the acid precursor from the component (B) occur in the regions 123 of the resist film. The sensitizer reacts with the active atmosphere or active liquid to be converted again into the active substance α/stable substance α1.

Accordingly, in the exposure step (2), even though the one face is irradiated with the exposure light (II), the acid is generated only in the regions irradiated patternwise first, and the active substance α/stable substance α1 is regenerated only in the regions irradiated patternwise first by irradiating the one face (floodwise). Thus, a large amount of the acid is generated only in the regions irradiated patternwise first, and even after the neutralization of the acid with the quencher, the acid is generated only in the regions irradiated patternwise first.

Thereafter, the heating step and the development step are carried out to form a resist pattern as shown in FIG. 6D.

As described in connection with Specific Example 1 and Specific Example 2, the resist pattern-forming method of the embodiment of the present invention enables a resist pattern with a high resolution to be formed through pattern-forming irradiation in a significantly low exposure dose than usual, by e.g., selections of an appropriate resist design, an appropriate exposure light source, etc.

It is to be noted that in the Specific Examples described above, a radioactive ray that does not react with the resist film 12 in the regions unirradiated with the exposure light (I) is selected as the exposure light (II) in the exposure step (2), but the present invention is not limited thereto. The exposure light which causes a negative type reaction with the resist film 12 in the regions unirradiated with the exposure light (I) may be selected as the exposure light (II) in the exposure step (2).

In the following, the resist pattern-forming method according to other embodiment of the present invention will be described. The resist pattern-forming method of the present embodiment includes the resist film-forming step, the exposure step (1), the exposure step (2), and the development step. Descriptions of the resist film-forming step, the exposure step (1) and the development step are now omitted since these steps are similarly carried out to the resist film-forming step (S101), the exposure step (1) (S105) and the development step (S110) of the embodiments described hereinabove with reference to FIGS. 1 to 6.

In the exposure step (2), the pattern latent image is formed on the resist film in a state in which the acid and the sensitizer are generated through the irradiation with the exposure light (I). Specifically, in the state of the resist film including the sensitizer present therein, the pattern latent image is formed on the resist film. The exposure step (2) is preferably carried out in the state in which a large amount of the sensitizer is present. When the pattern latent image is formed in the state in which the acid and the sensitizer are generated in the resist film, the acid can be generated from the component (B) by irradiating with the exposure light (II), due to the action of the sensitizer. It is to be noted that the resist pattern-forming method of the present embodiment may further include a maintaining step for inhibiting a decrease in the amount of the acid and the sensitizer generated in the resist film. Since the maintaining step is carried out similarly to the maintaining step (S105) in the embodiments described with reference to FIGS. 1 to 6, the description thereof is omitted here.

In the resist pattern-forming method of the embodiments described with reference to FIGS. 1 to 6, the sensitizer is generated in the resist film 12, and the acid is directly generated from the component (B) by the action of the sensitizer, or the sensitizer is converted into the active substance α/stable substance α1 and thereafter the acid is generated from the component (B) by using the active substance α/stable substance α1, but the present invention is not limited thereto. A stable substance B1 may be generated in the resist film, and the acid may be directly generated from the component (B) by the action of the stable substance B1, or the stable substance B1 may be converted into the active substance α/stable substance α1 and thereafter the acid may be generated from the component (B) by the action of the active substance α/stable substance α1. In the following, the resist pattern-forming method according to another embodiment of the present invention will be described.

The resist pattern-forming method of the present embodiment includes the resist film-forming step, a stable substance-generating step, a converting step, the exposure step (2) and the development step. Descriptions of the resist film-forming step and the development step are now omitted since these steps are similarly carried out to the resist film-forming step (S101) and the development step (S110) of the embodiments described hereinabove with reference to FIGS. 1 to 6.

In the stable substance-generating step, the stable substance is generated in the resist film through the irradiation with the exposure light (I). Specifically, both the acid from the component (B), and the stable substance B1 are generated in the resist film 12 through the irradiation with the exposure light (I). It is to be noted that the stable substance B1 is, for example, an aromatic iodine compound or an aromatic sulfur compound.

In the converting step, the stable substance B1 is converted in regions irradiated with the exposure light (I) of the resist film 12. Specifically, until an exposure step (2) (S107) described later is carried out, the stable substance B1 is converted into the active substance α/stable substance α1 by controlling the environment. For the conversion procedure, the active gas atmosphere or active liquid may be used as described in the embodiment described above.

In the exposure step (2), by irradiating with the exposure light (II), the pattern latent image is formed on the resist film in which the stable substance B1 is generated. Specifically, the exposure light (II) is a radioactive ray that generates: the stable substance B1 in the regions irradiated with the exposure light (I); and the acid from the component (B) by the action of the active substance α/stable substance α 1. In the regions irradiated with the exposure light (I) of the resist film 12 that was irradiated with the exposure light (II), by the action of the stable substance B1 and active substance α/stable substance α1, the acid (or an acid having a different structure from that of the aforementioned acid or a precursor of the acid) is generated from the stable substance B1 and the component (B).

It is to be noted that as described above, the irradiation patternwise with the exposure light (I), and the irradiation of one face (floodwise) with the exposure light (II) may be acceptable. In the following, the radiation-sensitive resin composition (I) suitably used in the case including: irradiating patternwise with the exposure light (I); and irradiating floodwise with the exposure light (II) will be described.

The radiation-sensitive resin composition (I) of the present embodiment contains: the component (A) having the solubility in a developer solution to be altered by an action of an acid; the component (B) that is capable of generating an acid by an action of the exposure light (I) including a radioactive ray having the wavelength (I); and the sensitizer precursor (C) to be converted into a sensitizer by an action of the exposure light (I). In the resist film formed from the radiation-sensitive resin composition (I) of the present embodiment, the acid is generated from the component (B) through the irradiation with the exposure light (I), and the sensitizer is produced from the sensitizer precursor (C), whereas neither the acid nor the sensitizer is generated even if the irradiation with only the exposure light (II) that accelerates the resist reaction by this sensitizer is executed. It is desired that the radiation-sensitive resin composition (I) (the component (A) and the sensitizer precursor (C)) of the present embodiment is transparent to the exposure light (II). Thus, when the sensitizer precursor (C) is irradiated with the exposure light (I), the sensitizer that exhibits intense absorption at a different wavelength is produced.

In the radiation-sensitive resin composition (I) of the present embodiment, when the sensitizer generated from the sensitizer precursor (C) through the irradiation with the exposure light (I) is irradiated with the exposure light (II), the exposure light (II) is absorbed to accelerate the generation of the acid from the component (B). On the other hand, in the regions of the resist film where the irradiation with the exposure light (I) was not executed, neither the acid nor the sensitizer is generated even if irradiation with the exposure light (II) is executed.

When the radiation-sensitive resin composition (I) of the present embodiment is irradiated patternwise with the exposure light (I), the sensitizer is produced patternwise. Thereafter, when predetermined regions of the resist film are irradiated with the exposure light (II), the resist reaction proceed resulting from the sensitizer. Accordingly, the predetermined resist pattern can be conveniently formed.

In addition to the components (A) to (C), the radiation-sensitive resin composition (I) may contain (D) a quencher, (E) a solvent and a polymer having a greater total mass percentage content of fluorine atom and silicon atom than the component (A) (hereinafter, may be also referred to as “(F) polymer” or “polymer (F)”), and other component than the components described above may be also contained. In the following, each component will be described.

### (A) Component

The component (A) has the solubility in a developer solution to be altered by an action of an acid. The component (A) is not particularly limited as long as it has the aforementioned property, and may include not only a polymer compound but also a low molecular compound; however, the polymer compound is preferred. As the polymer compound, a first polymer (hereinafter, may be also referred to as“(A) polymer” or “polymer (A)”) that includes a group that generates a polar group through dissociation of an acid-labile group by an action of an acid (hereinafter, may be also referred to as “group (a)”) is preferred.

### (A) Polymer

The polymer (A) includes the group (a). The polymer (A) typically has a structural unit that includes the group (a) (hereinafter, may be also referred to as “structural unit (I)”). In addition to the structural unit (I), the polymer (A) preferably has a structural unit (II) that includes a lactone structure, a cyclic carbonate structure, a sultone structure or a combination thereof, and other structural unit than the structural unit (I) and the structural unit (II) may be also included. The polymer (A) may have one, or two or more types of the structural unit. In the following, each structural unit will be described.

Structural Unit (I)

The structural unit (I) includes the group (a).

Group (a)

The group (a) generates a polar group through dissociation of the acid-labile group by an action of an acid. The group (a) is exemplified by groups obtained by substituting a hydrogen atom included in a polar group, with an acid-labile group, and the like. Examples of the polar group include hydroxy groups such as an alcoholic hydroxy group and a phenolic hydroxy group, a carboxy group, a sulfo group, an amino group, and the like.

The group (a) is exemplified by a group represented by the following formula (1), and the like.

—Y—R¹ (1)

In the above formula (1), Y represents a divalent group obtained by removing one hydrogen atom from a monovalent polar group; and R¹ represents a monovalent acid-labile group having 1 to 20 carbon atoms.

The acid-labile group represented by R¹ is exemplified by a tertiary alkyl group, a tertiary cycloalkyl group, a 1-alkoxy-substituted alkyl group, a 1-cycloalkyloxy-substituted alkyl group and the like, and examples thereof include a t-butyl group, a 1-methylcyclopentan-1-yl group, a 1-ethylcyclopentan-1-yl group, a 1-i-propylcyclopentan-1-yl group, a 2-ethyladamantan-2-yl group, a 1-cyclohexyl ethoxyethyl group, and the like.

Examples of the structural unit (I) include: a structural unit represented by the following formula (2-1) (hereinafter, may be also referred to as “structural unit (I-1)”), a structural unit represented by the following formula (2-2) (hereinafter, may be also referred to as “structural unit (I-2)”), and the like.

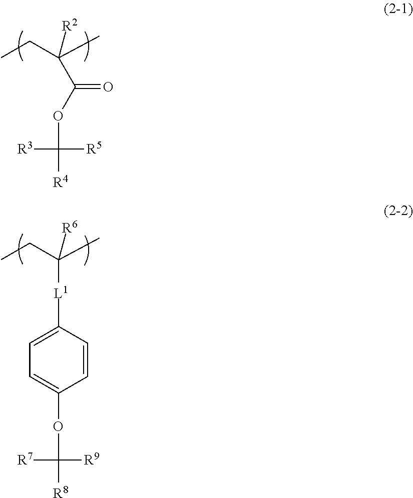

In the above formula (2-1), R² represents a hydrogen atom, a fluorine atom, a methyl group or a trifluoromethyl group; R³ represents a monovalent hydrocarbon group having 1 to 20 carbon atoms; and R⁴ and R⁵ each independently represent a monovalent hydrocarbon group having 1 to 20 carbon atoms, or R⁴ and R⁵ taken together represent an alicyclic structure having 3 to 20 ring atoms together with the carbon atom to which R⁴ and R⁵ bond.

In the above formula (2-2), R⁶ represents a hydrogen atom or a methyl group; L¹ represents a single bond, —COO— or —CONH—; R⁷ represents a hydrogen atom or a monovalent hydrocarbon group having 1 to 20 carbon atoms; and R⁸ and R⁹ each independently represent a monovalent hydrocarbon group having 1 to 20 carbon atoms or a monovalent oxyhydrocarbon group having 1 to 20 carbon atoms.

The structural unit (I-1) is preferably a structural unit represented by the following formulae (2-1-1) to (2-1-4) (hereinafter, may be also referred to as “structural units (I-1-1) to (I-1-4)”). The structural unit (I-2) is preferably a structural unit represented by the following formula (2-2-1) (hereinafter, may be also referred to as “structural unit (I-2-1)”).

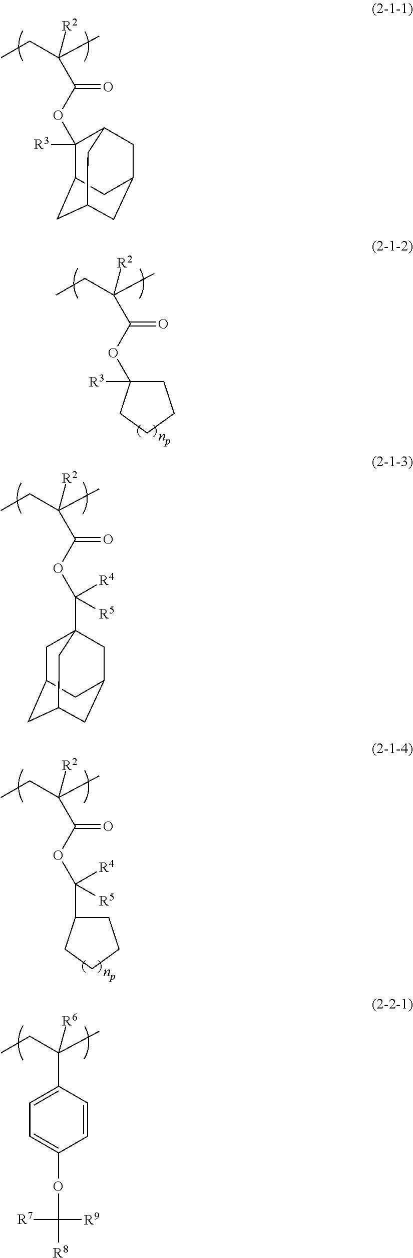

In the above formulae (2-1-1) to (2-1-4), R² to R⁵ are as defined in the above formula (2-1); and nₚ is each independently an integer of 1 to 4.

In the above formula (2-2-1), R⁶ to R⁹ are as defined in the above formula (2-2).

Examples of the structural unit (I-1) include structural units represented by the following formulae, and the like.

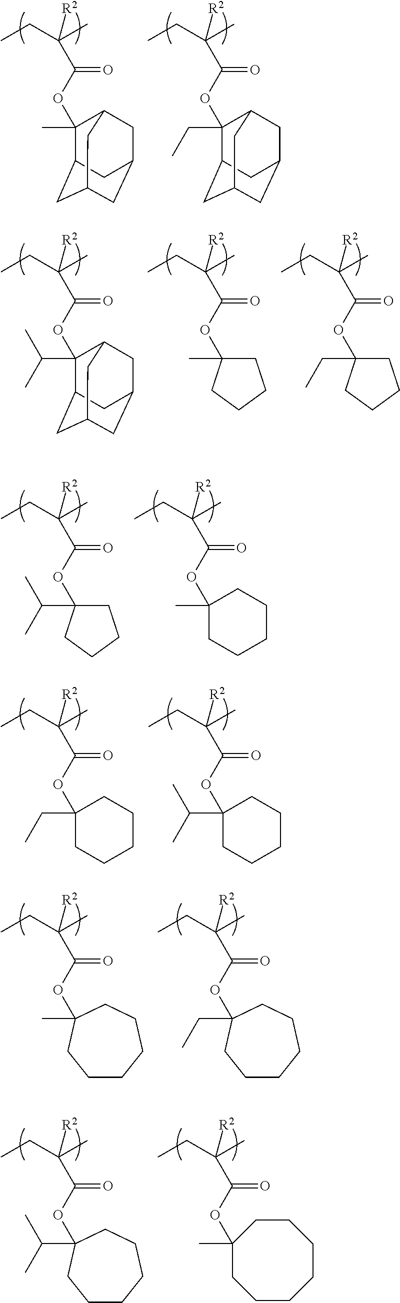

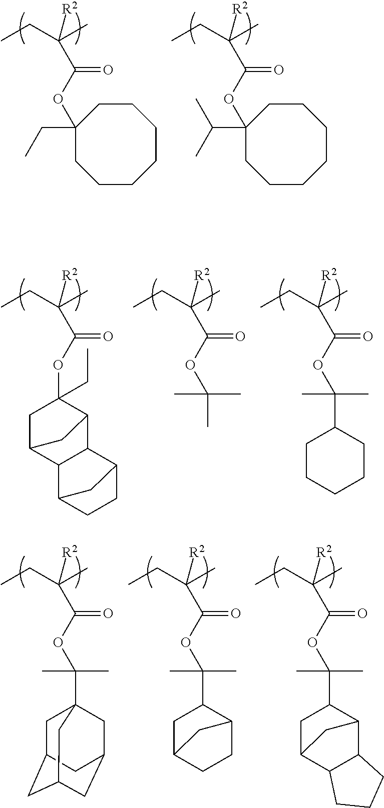

In the above formulae, R² are as defined in the above formula (2-1).

Examples of the structural unit (I-2) include structural units represented by the following formulae, and the like.

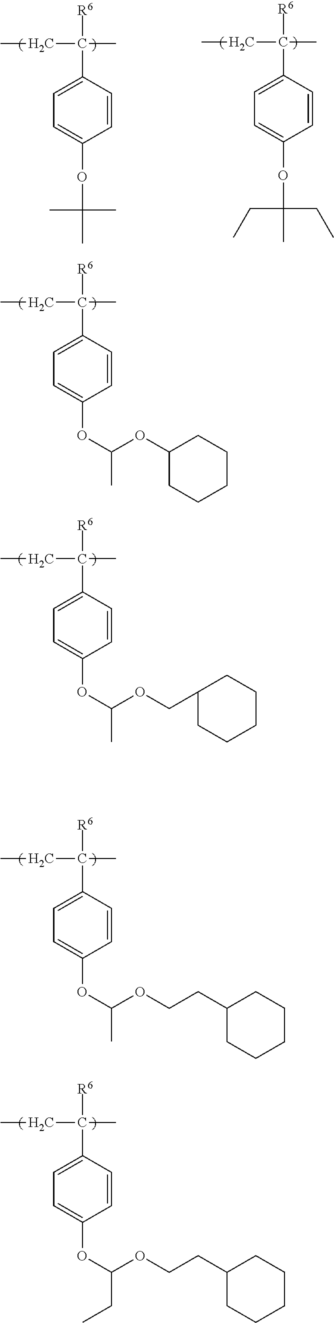

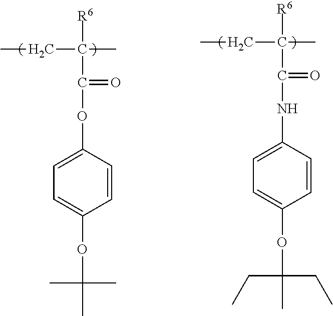

In the above formulae, R⁶ is as defined in the above formula (2-2).

As the structural unit (I-1), the structural unit (I-1-1) and the structural unit (I-1-2) are preferred, and a structural unit derived from 1-alkylcyclopentan-1-yl (meth)acrylate and a structural unit derived from 2-alkyladamantan-2-yl (meth)acrylate are more preferred.

As the structural unit (I-2), the structural unit (I-2-1) is preferred, and a structural unit derived from 1-cycloalkyloxy alkan-1-yloxystyrene is more preferred.

The lower limit of the proportion of the structural unit (I) with respect to the total structural units constituting the polymer (A) is preferably 10 mol %, more preferably 20 mol %, still more preferably 30 mol %, and particularly preferably 40 mol %. The upper limit of the proportion of the structural unit (I) is preferably 80 mol %, more preferably 70 mol %, still more preferably 60 mol %, and particularly preferably 55 mol %. When the proportion of the structural unit (I) falls within the above range, the sensitivity, nanoedge roughness performance and resolution can be more improved.

Structural Unit (II)

The structural unit (II) is a structural unit that includes a lactone structure, a cyclic carbonate structure, a sultone structure or a combination thereof. When the polymer (A) has the structural unit (II), the sensitivity, nanoedge roughness performance and resolution can be more improved. In addition, the adhesiveness between the resultant resist pattern and the substrate can be more improved.

Examples of the structural unit (II) include structural units represented by the following formulae, and the like.

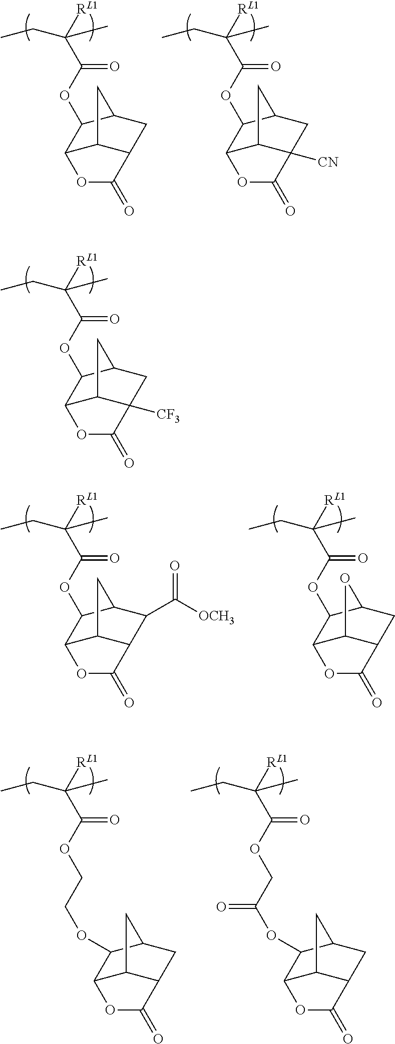

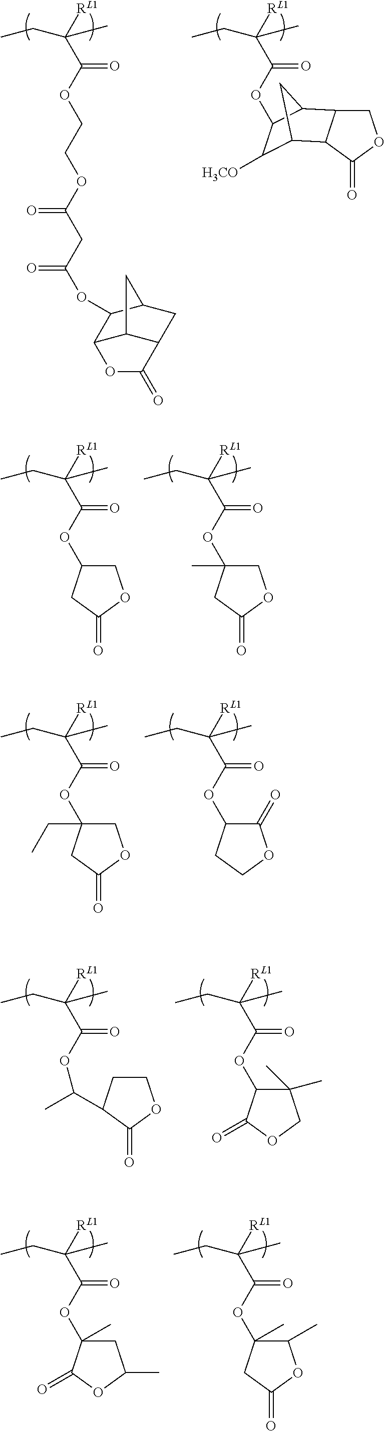

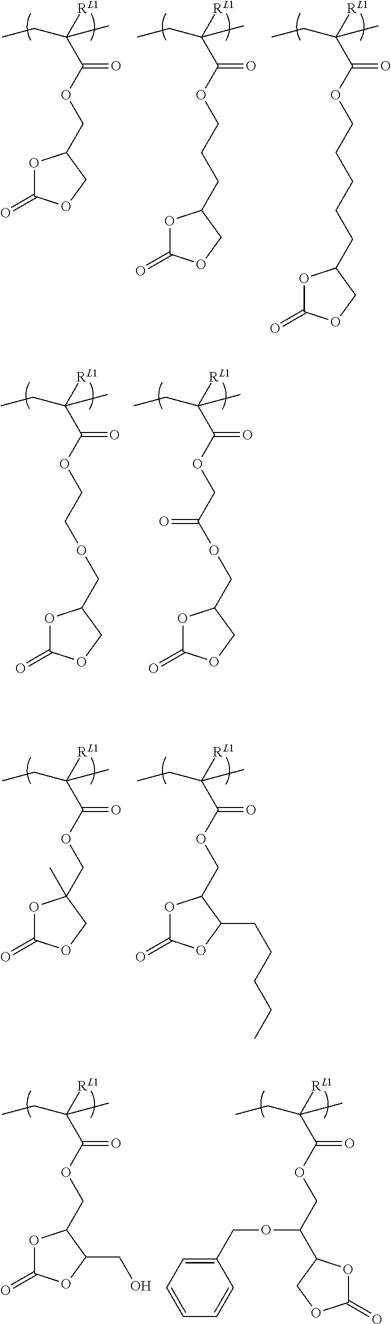

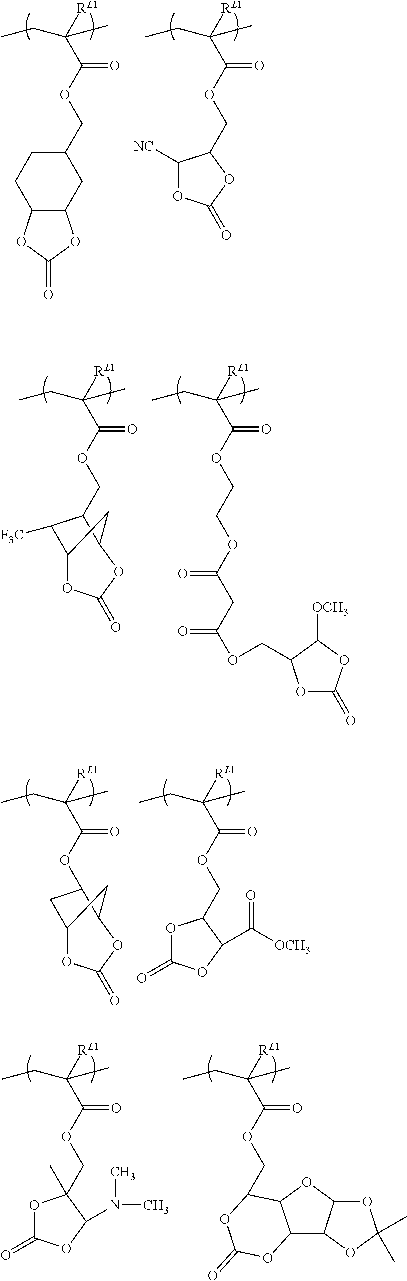

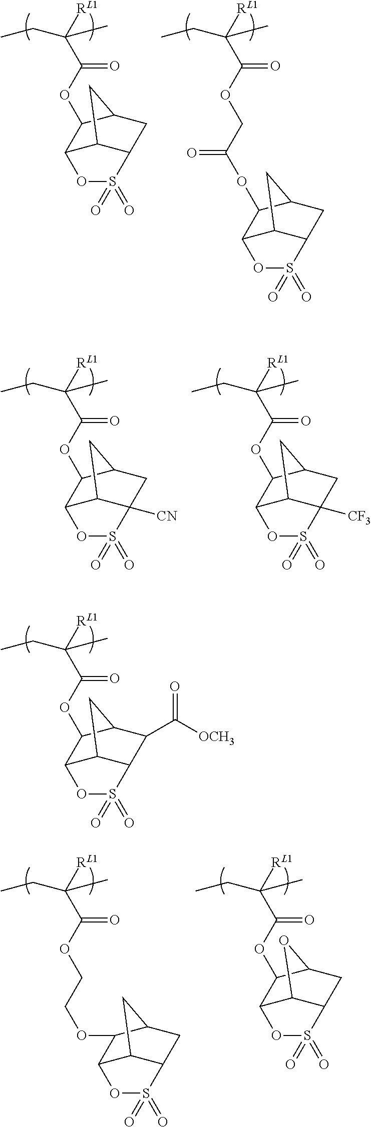

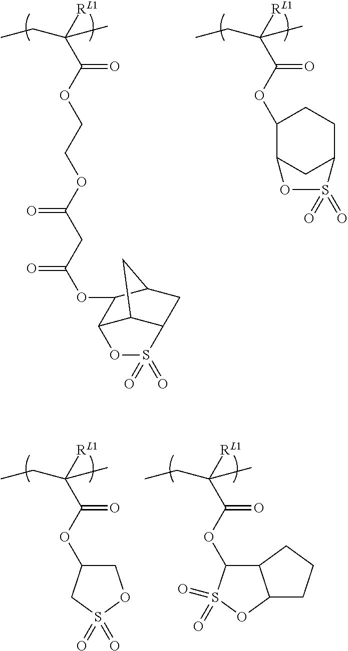

In the above formulae, R^{L1} represents a hydrogen atom, a fluorine atom, a methyl group or a trifluoromethyl group.

As the structural unit (II), a structural unit that includes a lactone structure and a structural unit that includes a cyclic carbonate structure are preferred, and a structural unit derived from (meth)acrylate that includes a group having a lactone structure, and a structural unit derived from (meth)acrylate that includes a group having a cyclic carbonate structure are more preferred.

In a case where the polymer (A) has the structural unit (II), the lower limit of the proportion of the structural unit (II) with respect to the total structural units constituting the polymer (A) is preferably 10 mol %, more preferably 20 mol %, and still more preferably 30 mol %. The upper limit of the proportion of the structural unit (II) is preferably 80 mol %, more preferably 70 mol %, and still more preferably 60 mol %. When the proportion of the structural unit (II) falls within the above range, the sensitivity, nanoedge roughness performance and resolution can be further improved. In addition, the adhesiveness between the resultant resist pattern and the substrate can be further improved.

Other Structural Unit

The polymer (A) may have other structural unit in addition to the structural units (I) and (II). The other structural unit is exemplified by a structural unit that includes a phenolic hydroxy group, a structural unit that includes an alcoholic hydroxy group, a structural unit that includes a ketonic carbonyl group, a cyano group, a carboxy group, a nitro group, an amino group or a combination thereof, a structural unit derived from a (meth)acrylic acid ester that includes a nonlabile monovalent alicyclic hydrocarbon group, and the like. The upper limit of the proportion of the other structural unit with respect to the total structural units constituting the polymer (A) is preferably 20 mol %, and more preferably 10 mol %.

The lower limit of the content of the component (A) with respect to the total solid content of the radiation-sensitive resin composition (I) is preferably 70% by mass, more preferably 80% by mass, and still more preferably 85% by mass. The “total solid content” as referred to means the sum of the components other than the solvent (E) in the radiation-sensitive resin composition (I).

The lower limit of the polystyrene equivalent weight average molecular weight (Mw) as determined by gel permeation chromatography (GPC) of the polymer (A) is preferably 6,000, more preferably 7,000, still more preferably 8,000, and particularly preferably 10,000. The upper limit of the Mw is preferably 100,000, more preferably 30,000, still more preferably 20,000, and particularly preferably 15,000. When the Mw of the polymer (A) falls within the above range, the film loss can be inhibited.

The lower limit of the polystyrene equivalent number average molecular weight (Mn) of the polymer (A) is preferably 3,000, more preferably 3,500, still more preferably 4,000, and particularly preferably 5,000. The upper limit of the Mn is preferably 60,000, more preferably 20,000, still more preferably 15,000, and particularly preferably 10,000.

The lower limit of the ratio (Mw/Mn) of the Mw to the polystyrene equivalent number average molecular weight (Mn) as determined by GPC of the polymer (A) is typically 1, and preferably 1.3. The upper limit of the ratio is preferably 5, more preferably 3, still more preferably 2, and particularly preferably 1.7.

As used herein, the Mw and the Mn of the polymer are determined using GPC under the following conditions.

GPC columns: for example, “G2000 HXL” x 2, “G3000 HXL” x 1 and “G4000 HXL” x 1 each available from Tosoh Corporation

column temperature: 40° C.

elution solvent: tetrahydrofuran

flow rate: 1.0 mL/min

sample concentration: 1.0% by mass

amount of injected sample: 100 μL

detector: differential refractometer

standard substance: mono-dispersed polystyrene

### (B) Component

The component (B) is capable of generating an acid by an action of the exposure light (1). With respect to the form of the component (B) contained in the radiation-sensitive resin composition (I), the component (B) may be contained: as a component that differs from the component (A); as a part of the polymer (A), i.e., as a component included in the polymer (A); or as both of these forms. In the case where the component (B) is contained as a component that differs from the component (A), the component (B) may be contained: in the form of a low molecular weight compound as described later (hereinafter, may be also referred to as “(B) acid generating agent” or “acid generating agent (B)”); in the form of a polymer; or in both of these forms.

The acid generating agent (B) is exemplified by an onium salt compound, an N-sulfonyloxyimide compound, sulfonimide compound, a halogen-containing compound, a diazo ketone compound, and the like.

The onium salt compound is exemplified by a sulfonium salt, a tetrahydrothiophenium salt, an iodonium salt, a phosphonium salt, a diazonium salt, a pyridinium salt, and the like.

Specific examples of the acid generating agent (B) include compounds disclosed in paragraphs [0080] to [0113] of Japanese Unexamined Patent Application, Publication No. 2009-134088, and the like.

The acid generating agent (B) is preferably a compound represented by the following formula (3). When the acid generating agent (B) has the following structure, it is believed that due to an interaction, etc., with the structure of the component (A) the diffusion length of the generated acid in the resist film would decrease moderately, and consequently, the sensitivity, nanoedge roughness performance and resolution of the radiation-sensitive resin composition (I) can be more improved.

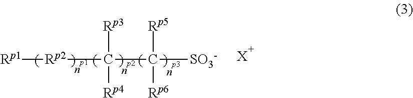

In the above formula (3), R^{p1} represents a monovalent group that includes a ring structure having 6 or more ring atoms; R^{p2} represents a divalent linking group; R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10; n^{p2} is an integer of 0 to 10; n^{p3} is an integer of 1 to 10, wherein in a case where n^{p1} is no less than 2, a plurality of R^{p2}s may be identical or different, wherein in a case where n^{p2} is no less than 2, a plurality of R^{p3}s may be identical or different, and a plurality of R^{p4}s may be identical or different, and wherein in a case where n^{p3} is no less than 2, a plurality of R^{p5}s may be identical or different, and a plurality of R^{p6}s may be identical or different; and X⁺ represents a monovalent radiation-sensitive onium cation.

The monovalent radiation-sensitive onium cation represented by X⁺ is degraded by the irradiation with the exposure light (I). In the light-exposed regions, a sulfonic acid is generated from the sulfonate anion, and a proton generated through the degradation of the radiation-sensitive onium cation. The monovalent radiation-sensitive onium cation represented by X⁺ is exemplified by a cation represented by the following formula (X-1) (hereinafter, may be also referred to as “cation (X-1)”), a cation represented by the following formula (X-2) (hereinafter, may be also referred to as “cation (X-2)”), a cation represented by the following formula (X-3) (hereinafter, may be also referred to as “cation (X-3)”), and the like.

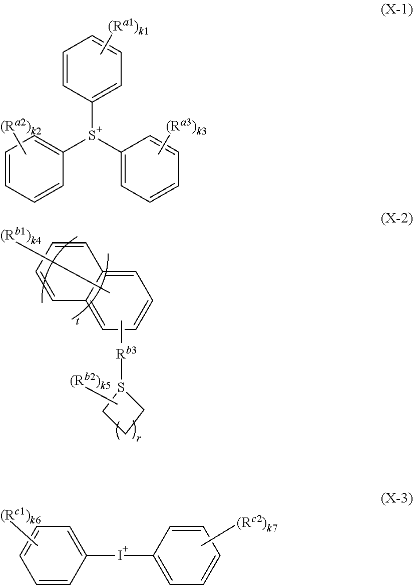

In the above formula (X-1), R^{a1}, R^{a2} and R^{a3} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{P} or —SO₂—R^{Q}, or at least two of R^{a1}, R^{a2} and R^{a3} taken together represent a ring structure; R^{P} and R^{Q} each independently represent a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms; and k1, k2 and k3 are each independently an integer of 0 to 5, wherein in a case where R^{a1} to R^{a3}, and R^{P} and R^{Q} are each present in a plurality of number, a plurality of R^{a1}s may be identical or different, a plurality of R^{a2}s may be identical or different, a plurality of R^{a3}s may be identical or different, a plurality of R^{P}s may be identical or different, and a plurality of R^{Q}s may be identical or different.

In the above formula (X-2), R^{b1} represents a substituted or unsubstituted linear or branched alkyl group having 1 to 8 carbon atoms or a substituted or unsubstituted aromatic hydrocarbon group having 6 to 8 carbon atoms; k4 is an integer of 0 to 7, wherein in a case where R^{b1} is present in a plurality of number, a plurality of R^{b1} s may be identical or different, or the plurality of R^{b1}s may taken together represent a ring structure; R^{b2} represent a substituted or unsubstituted linear or branched alkyl group having 1 to 7 carbon atoms or a substituted or unsubstituted aromatic hydrocarbon group having 6 or 7 carbon atoms; k5 is an integer of 0 to 6, wherein in a case where R^{b2} is present in a plurality of number, a plurality of R^{b2}s may be identical or different, or the plurality of R^{b2}s may taken together represent a ring structure; r is an integer of 0 to 3; R^{b3} represents a single bond or a divalent organic group having 1 to 20 carbon atoms; and t is an integer of 0 to 2.

In the above formula (X-3), R^{c1} and R^{c2} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{R} or —SO₂—R^{S}, or R^{c1} and R^{c2} taken together represent a ring structure; R^{R} and R^{S} each independently represent a substituted or unsubstituted linear or branched alkyl group having 1 to 12 carbon atoms, a substituted or unsubstituted alicyclic hydrocarbon group having 5 to 25 carbon atoms or a substituted or unsubstituted aromatic hydrocarbon group having 6 to 12 carbon atoms; and k6 and k7 are each independently an integer of 0 to 5, wherein in a case where R^{c1}, R^{c2}, R^{R} and R^{S} are each present in a plurality of number, a plurality of R^{c1}s may be identical or different, a plurality of R^{c2}s may be identical or different, a plurality of R^{R}s may be identical or different, and a plurality of R^{S}s may be identical or different.

Of these, as X⁺, the cation (X-1) and the cation (X-3) are preferred, and a triphenylsulfonium cation, a 4-cyclohexylsulfonylphenyldiphenylsulfonium cation and a diphenyliodonium cation are more preferred.

Examples of the acid generating agent represented by the above formula (3) include compounds represented by the following formulae (3-1) to (3-15) (hereinafter, may be also referred to as “compounds (3-1) to (3-15)”), and the like.

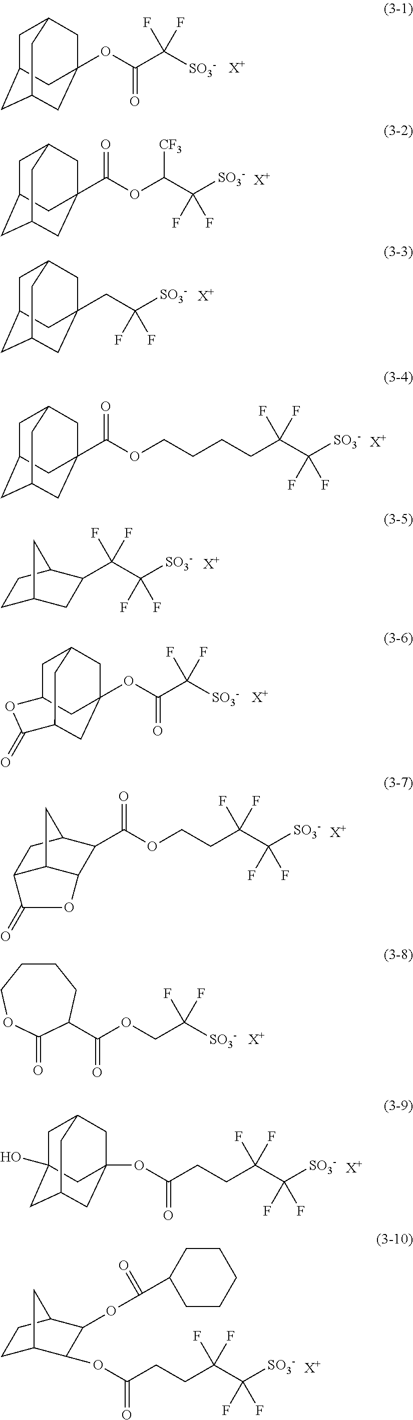

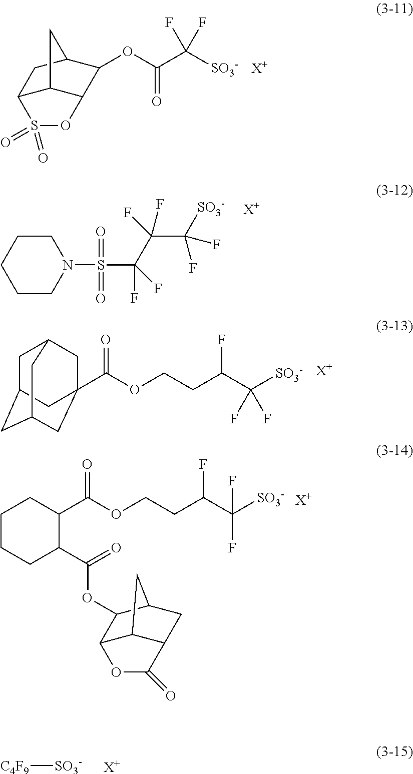

In the above formulae (3-1) to (3-15), X⁺ represents a monovalent radiation-sensitive onium cation.

As the acid generating agent (B), the onium salt compound is preferred, and the compound (3-15) and an onium salt compound of nonafluoro-n-butane-1-sulfonate are more preferred.

The component (B) may be, for example, included in the polymer (A), as a structural unit such as a structural unit represented by the following formula (4).

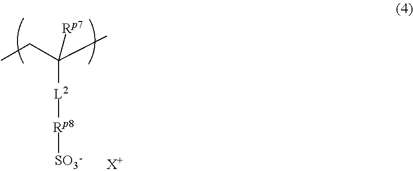

In the above formula (4), R^{p7} represents a hydrogen atom or a methyl group; L² represents a single bond, —O— or a divalent organic group having 1 to 20 carbon atoms; R^{p8} represents a fluorinated alkanediyl group having 1 to 10 carbon atoms; and X⁺ represents a monovalent radiation-sensitive onium cation.

As R^{p7}, in light of the degree of copolymerization of the monomer that gives the structural unit represented by the above formula (4), a hydrogen atom and a methyl group are preferred, and a methyl group is more preferred.

L² is preferably —COO—.

R^{p8} is preferably a fluorinated alkanediyl group having 1 to 4 carbon atoms, more preferably a fluorinated alkanediyl group having 1 to 2 carbon atoms, and still more preferably 1,2-difluoroethane-1,2-diyl group.

The lower limit of the common logarithmic value (log P value) of the water/octanol distribution coefficient of the acid generated from the component (B) is preferably 1.5, more preferably 2.0, and still more preferably 2.5. The upper limit of the log P value is preferably 12.0, more preferably 11.0, and still more preferably 10.5. When the log P value falls within the above range, in forming a resist pattern using a developer solution containing an organic solvent as a principal component, the line edge roughness property may be more favorable, and thus a resist pattern that is superior in intra-plane uniformity of the line width, and in bridge margin can be obtained. Although the reason therefor is not necessarily clear, it is envisaged that, for example, when the log P value falls within the above range, the acid generated from the component (B), and the component (B) would be more homogenously and more rapidly dissolved in the developer solution (I) containing an organic solvent as a principal component. More specifically, when the log P value is less than the upper limit, hydrophobicity of the acid generated from the component (B), and the anion of the component (B) would fall within an adequate range. As a result, it is inferred that, e.g., aggregation resulting from hydrophobic interaction of the acid and component (B) molecules in the development step can be inhibited, whereby the development uniformly proceeds. On the other hand, when the log P value is no less than the lower limit, e.g., the acid generated from the component (B) and the component (B) sufficiently dissolves in the developer solution (I), and consequently, deposition and the like of insoluble matter would be inhibited. Moreover, when the log P value falls within the above range, the development uniformity is improved, and the line-pattern is less likely to be swollen, and as a result, formation of a bridge between patterned portions is prevented, whereby the bridge margin is considered to be improved.

It is to be noted that the log P value as referred to means a logarithmic value of the distribution coefficient of octanol/water, and has been known as an important parameter that indicates hydrophilicity/hydrophobicity of molecules. Known process for determining the log P value of a compound is generally classified into experimentally measuring process, and arithmetically calculating process.

In the following, the process for determining the log P value will be described. When the log P value is experimentally measured, the procedure described in the document below may be employed for the measurement. Alternatively, when the log P value is arithmetically calculated, the calculated log P value (hereinafter, may be also referred to as “Clog P value”) may be derived by computation using a fragment method described in the document below, or the following commercially available software packages 1 and/or 2. The log P value as referred to herein means such a Clog P value, and the log P value described herein is the “Clog P value” calculated using the software package 2 below”.

Document: C. Hansch and A. Leo, “Substituent Constants for Correlation Analysis in Chemistry and Biology (John Wiley & Sons, New York, 1969)

Software package 1: MedChem Software (Release 3.54, August 1991, Medicinal Chemistry Project, Pomona College, Claremont, Calif.)

Software package 2: Chem Draw Ultra ver. 8.0. (April 2003, CambridgeSoft Corporation, USA)

As the compound that is capable of generating the acid having the log P value of no less than 1.5 and no greater than 12.0 (hereinafter, may be also referred to as “compound (I)”), a compound having a group that includes a fluorine-unsubstituted hydrocarbon skeleton having two or more carbon atoms in an anion (hereinafter, may be also referred to as “compound (I-1)”) is preferred. When the compound (I-1) is used as the acid generating agent (B), in forming a resist pattern using the developer solution containing an organic solvent as a principal component, the line edge roughness property becomes more favorable, and more favorable intra-plane uniformity of the line width and more favorable bridge margin can be attained. The number of carbon atoms of the group that includes the fluorine-unsubstituted hydrocarbon skeleton is preferably no less than 3, and more preferably no less than 4.

The fluorine-unsubstituted hydrocarbon skeleton having two or more carbon atoms may be included at any position in the anion of the compound (I-1), but is preferably included at the end of the anion.

Examples of the acid that the compound (I-1) generates include acids represented by the following formulae, and the like.

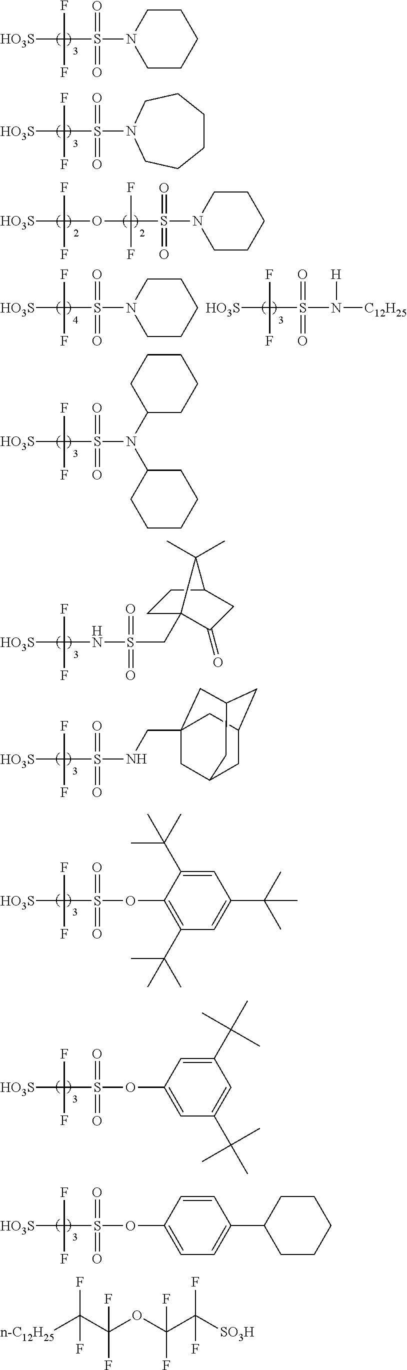

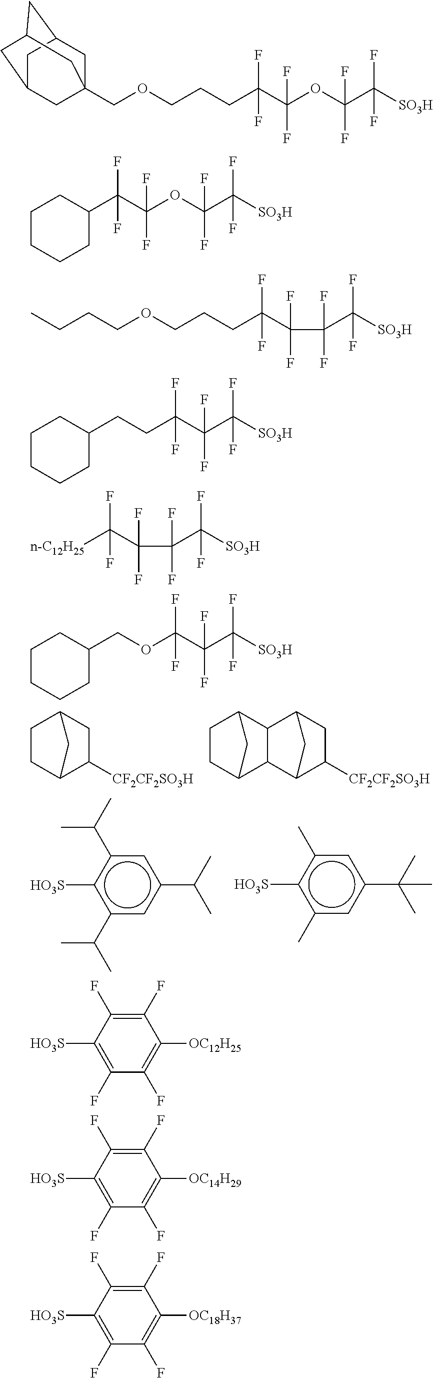

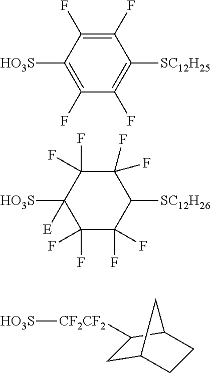

The acid that the compound (I) generates is also exemplified by the acids represented by the following formula (I) or (I′), and the like.

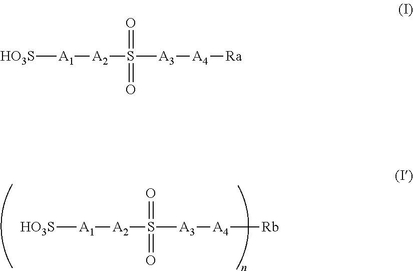

In the above formulae (I) and (I′), A₁ represents a methylene group, an alkylene group having 2 to 20 carbon atoms, a fluorinated alkylene group having 2 to 20 carbon atoms, a group that includes an oxygen atom, a sulfur atom, —CO—, —COO— and/or the like between two adjacent carbon atoms of the alkylene group or the fluorinated alkylene group; A₂ and A₃ each independently represent a single bond, an oxygen atom or —N(Rxb)-; Rxb represents a hydrogen atom, a substituted or unsubstituted aryl group, alkyl group or alkoxy group each having 6 to 14 carbon atoms, an alkyl group having 1 to 20 carbon atoms, a cycloalkyl group having 3 to 20 carbon atoms or an oxacycloalkyl group; A₄ represents a single bond or —CO—; Ra represents a hydrogen atom, an alkyl group having 1 to 20 carbon atoms, a cycloalkyl group, an aryl group, an aralkyl group having 7 to 20 carbon atoms or an alkenyl group; n is 2 or 3; and Rb represents a linking group having 1 to 20 carbon atoms and having a valency of n, wherein in a case where A₃ is —N(Rxb)-, Ra and Rxb, or Rb and Rxb may taken together represent a monocyclic or polycyclic azacycloalkane structure having 4 to 10 ring atoms, or a monocyclic or polycyclic azaoxacycloalkane structure having 4 to 10 ring atoms.

The substituent that each group may have is exemplified by a halogen atom, a hydroxy group, a nitro group, a cyano group, a carboxy group, a cycloalkyl group, an aryl group, an alkoxy group, an acyl group, an acyloxy group, and the like.

As the sulfonic acid represented by the formula (I) or (I′), sulfonic acids represented by the following formulae (IA) to (IC) and (I′A) to (I′C) are preferred.

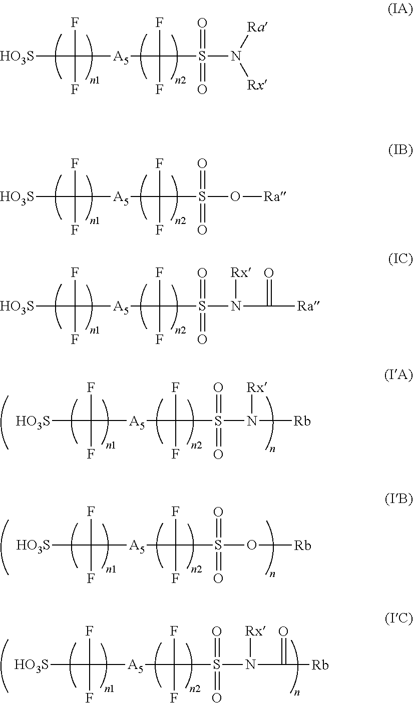

In the above formulae (IA) to (IC) and (I′A) to (I′C), Ra′ is as defined in connection with Ra in the above formula (I); Rb and n are as defined in connection with Rb and n in the above formula (I′); Ra″ represents an alkyl group, an aryl group, an aralkyl group or an alkenyl group; Rx′ is as defined in connection with Rxb in the above formulae (I) and (I′); n1 is an integer of 1 to 10; n2 is an integer of 0 to 10; and A₅ represents a single bond, —O—, an alkylene group, a cycloalkylene group or an arylene group.

The alkylene group and cycloalkylene group which may be represented by A₅ is preferably a fluorine-unsubstituted alkylene group and a fluorine-unsubstituted cycloalkylene group. In the above formula (IA), it is preferred that Ra′ and Rx′ taken together form a ring through binding. By forming a ring structure, stability of the compound represented by the above formula (IA) is improved, and the storage stability of the radiation-sensitive resin composition (I) containing the same can be improved. The number of carbon atoms of the formed ring is preferably 4 to 20. Examples of the alkyl group, the aryl group, the aralkyl group and the alkenyl group which may be represented by Ra″ include groups similar to those exemplified in connection with Ra, and the like. The sum of n1+n2 is preferably 2 to 8, and more preferably 2 to 6.

As the sulfonic acid represented by the above formulae (I) and (I′), sulfonic acids represented by the following formulae are preferred.

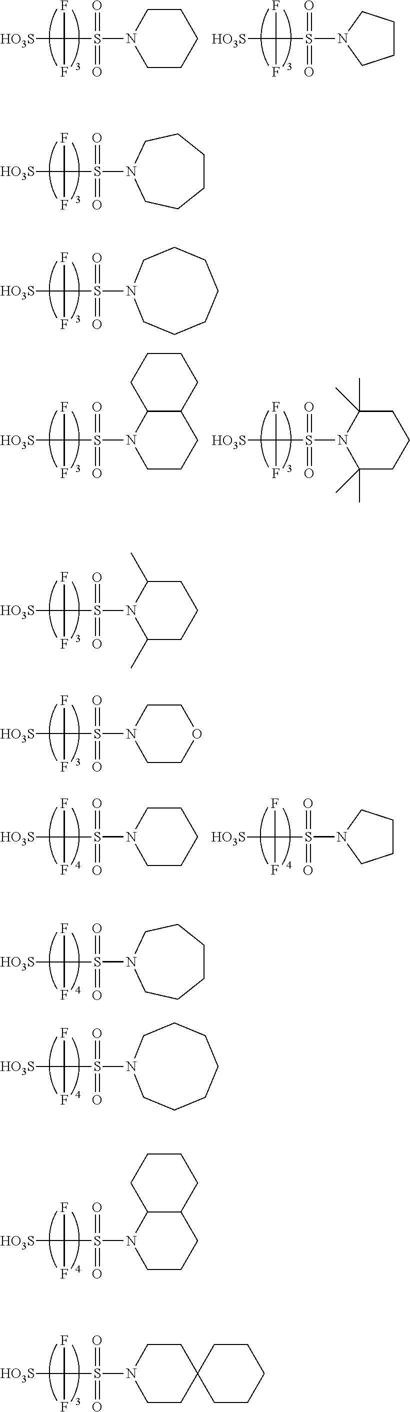

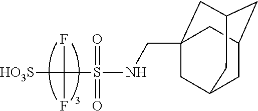

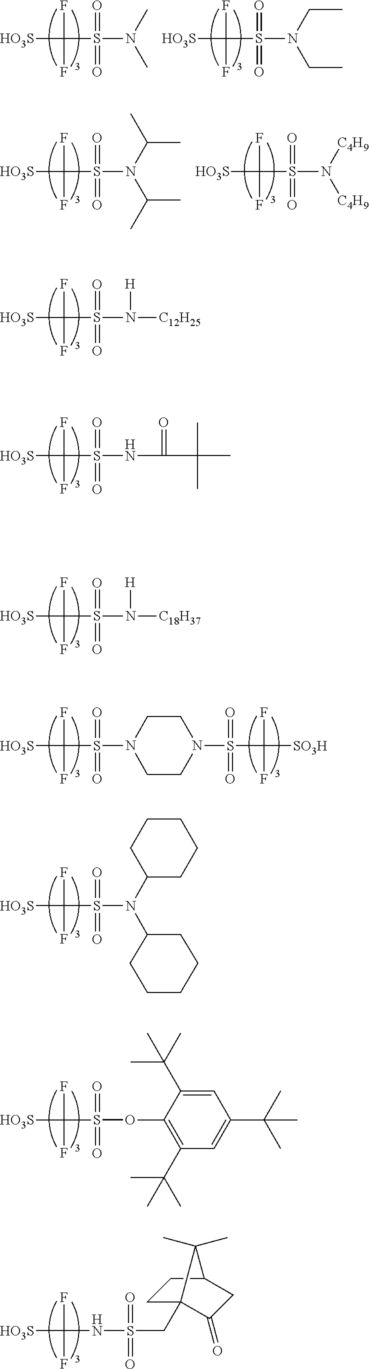

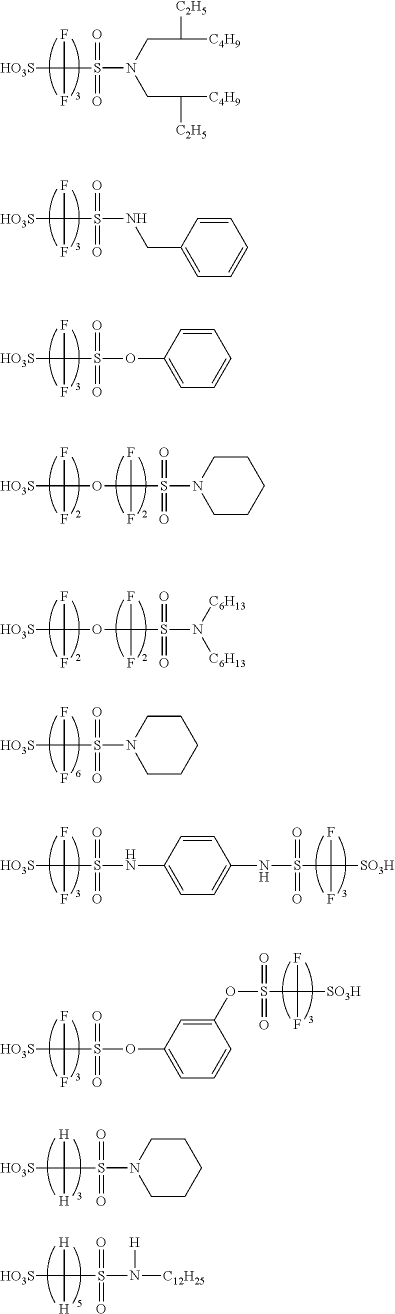

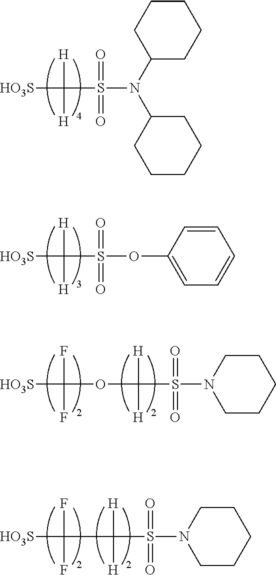

Of these, sulfonic acids that include a fluorine-unsubstituted hydrocarbon skeleton having two or more carbon atoms are preferred. Examples of such sulfonic acids include compounds represented by the following formulae, and the like.

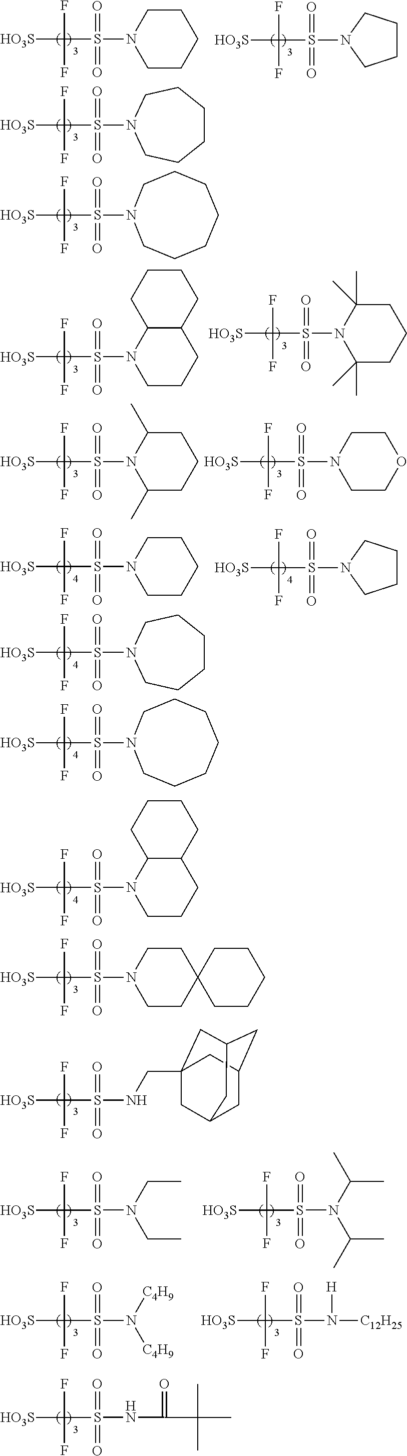

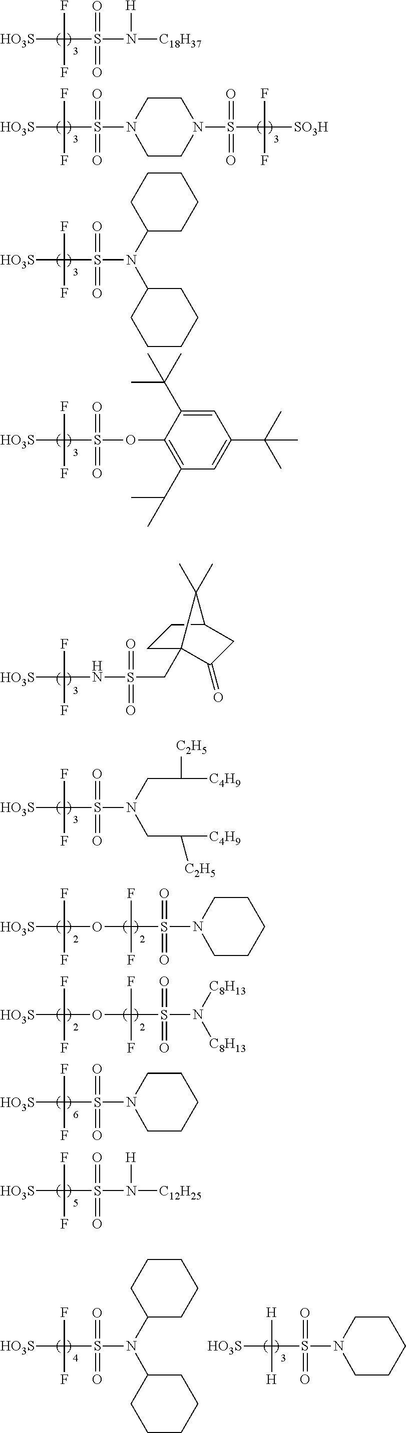

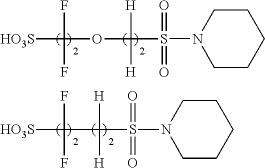

The compound (I) that is capable of generating a sulfonic acid represented by the following formula (II) is also preferred.

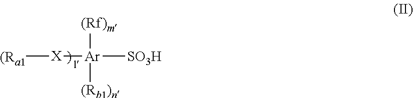

In the above formula (II), Rf represents a fluorine atom or an organic group having a fluorine atom; Rₐ₁ and R_{b1} each independently represent an alkyl group, an aryl group, a cycloalkyl group, an alkoxy group, an aryloxy group, an aralkyl group, an aralkyloxy group, a cycloalkoxy group, an alkoxycarbonyl group, an aryloxycarbonyl group, an acyloxy group, an alkylthio group, an arylthio group, an acyl group, an acylamino group, an alkenyl group, an alkenyloxy group, an arylcarbonyloxy group, an alkylcarbonyloxy group, an alkylaminocarbonyl group, an alkylcarbonylamino group, an alkylsilyloxy group, a cyano group, a group obtained by incorporating a linking group such as an oxygen atom, a sulfur atom or —COO— into one or a plurality of positions between adjacent carbon atoms of these groups, or a monovalent group having 2 to 30 carbon atoms obtained by substituting a part or all of hydrogen atoms of these groups; Ar represents an aromatic group which may have a tetravalent substituent having 6 to 20 carbon atoms; X represents —SO—, —SO₂—, —S— or —O—; 1′ is an integer of 0 to 6; m′ is an integer of 0 to 5; n′ is an integer of 0 to 5, wherein in a case where l′ and n′ are no less than 2, a plurality of Rₐ₁s may be identical or different and R_{b1}s may be identical or different; Rf represents a fluorine atom or an organic group having a fluorine atom, wherein in a case where m′ is no less than 2, a plurality of Rfs may be identical or different.

The sum of the number of carbon atoms of Rf, Rₐ₁ and R_{b1} is preferably 4 to 34, more preferably 6 to 30, and still more preferably 8 to 24. By adjusting the number of carbon atoms of Rf, Rₐ₁ and R_{b1}, diffusibility of the acid can be adjusted, whereby the resolving power is improved.

The sulfonic acid represented by the above formula (II) is preferably a sulfonic acid represented by the following formula (IIa), more preferably a sulfonic acid represented by the following formula (IIb), and still more preferably a sulfonic acid represented by the following formula (IIc).

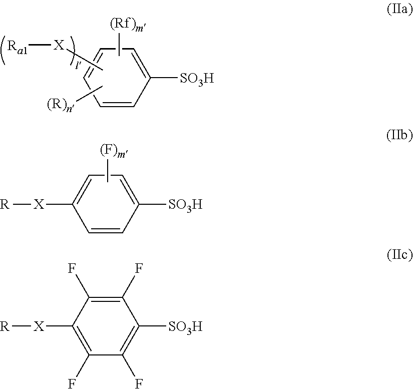

In the above formulae (IIa), (IIb) and (IIc), Rₐ₁, Rf, X, l′, m′, n′ are as defined in connection with Rₐ₁, Rf, X, l′, m′, n′ in the above formula (II); and R represents a monovalent organic group.

The sulfonic acid represented by the above formula (II) is preferably sulfonic acids represented by the following formulae.

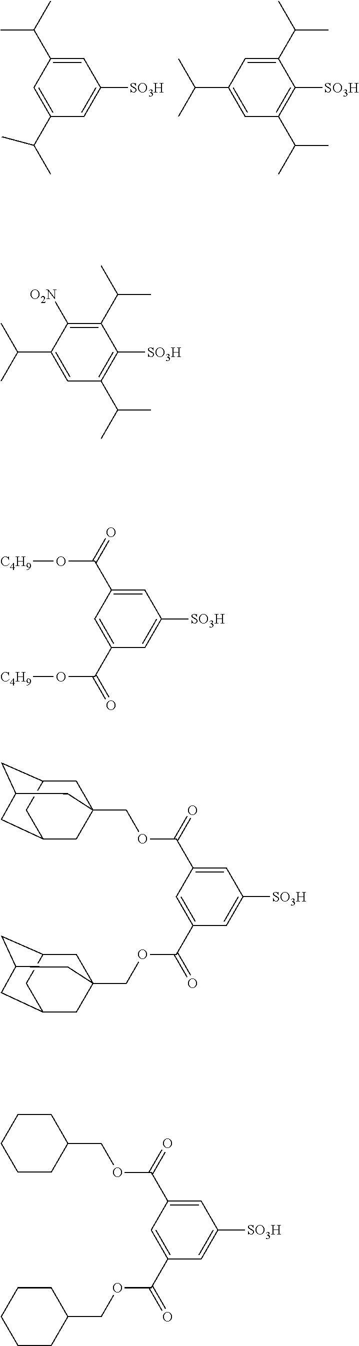

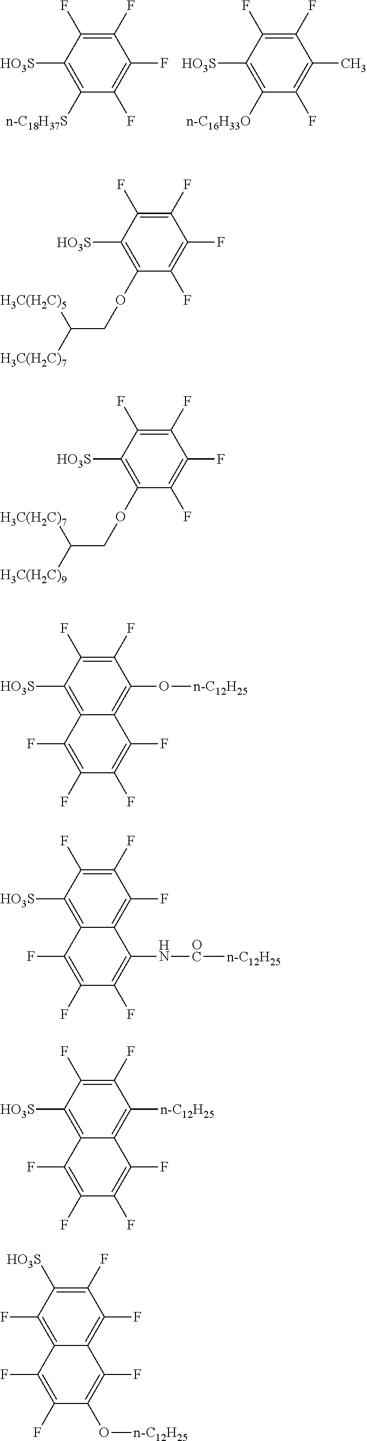

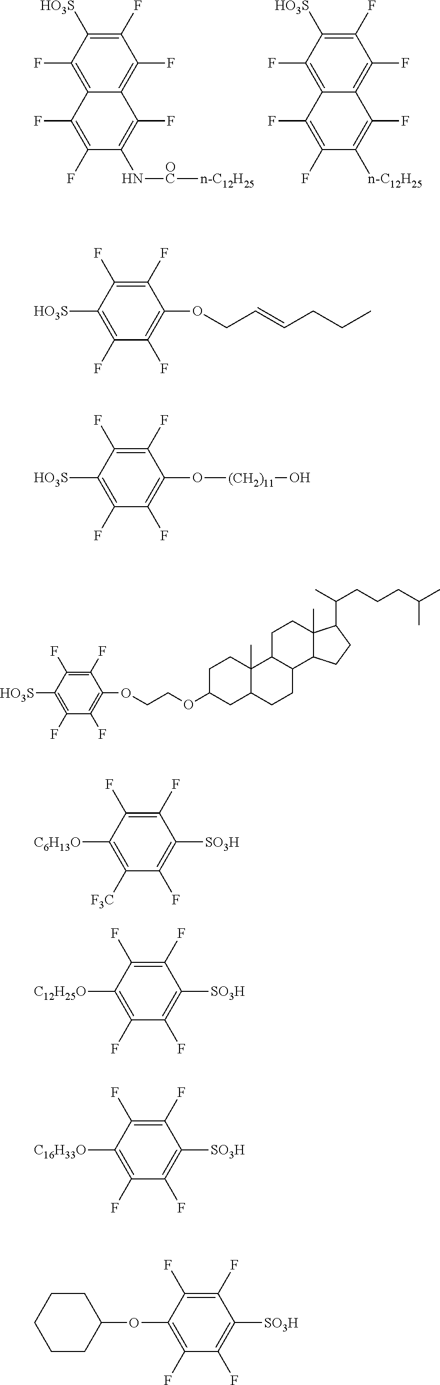

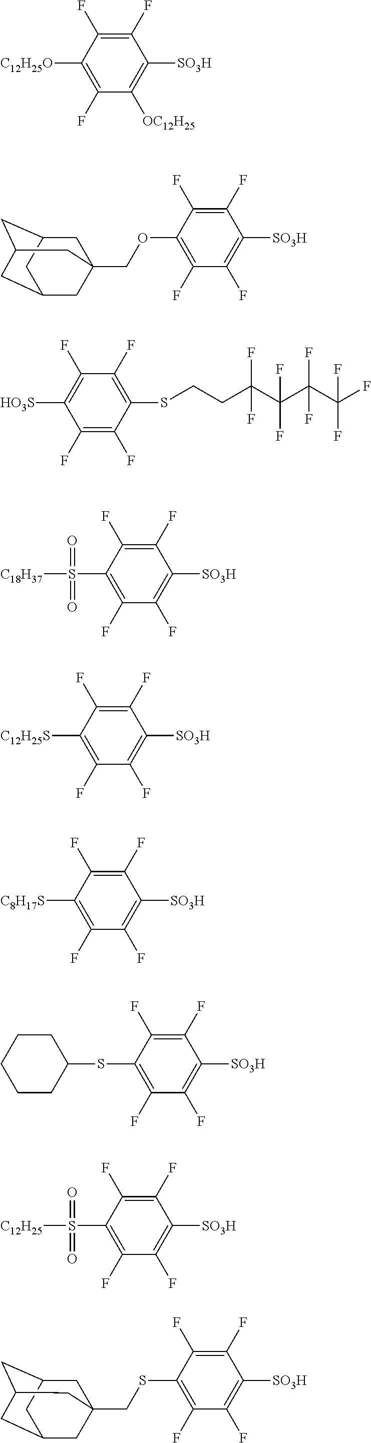

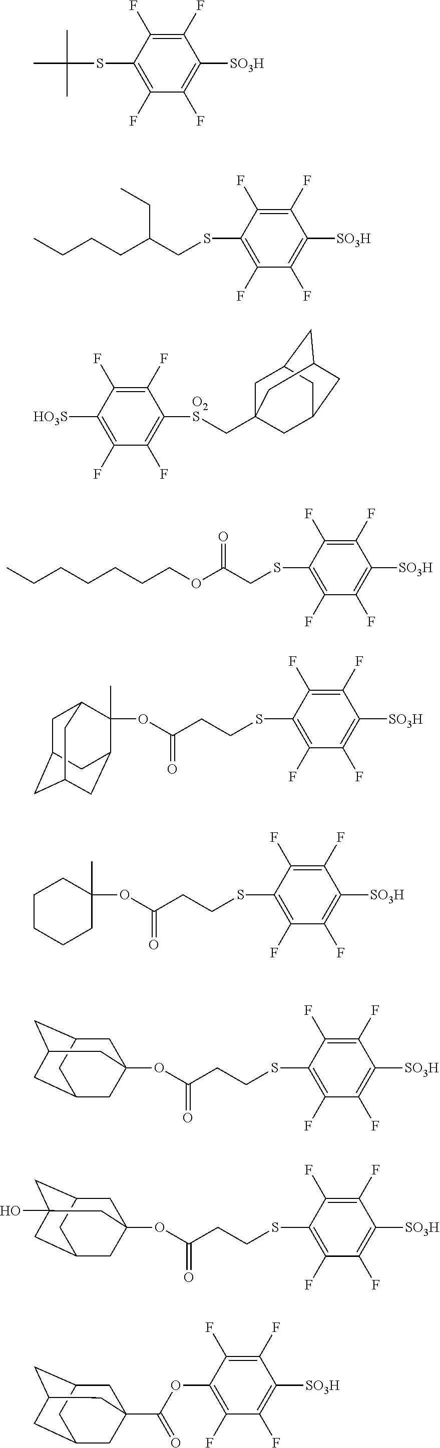

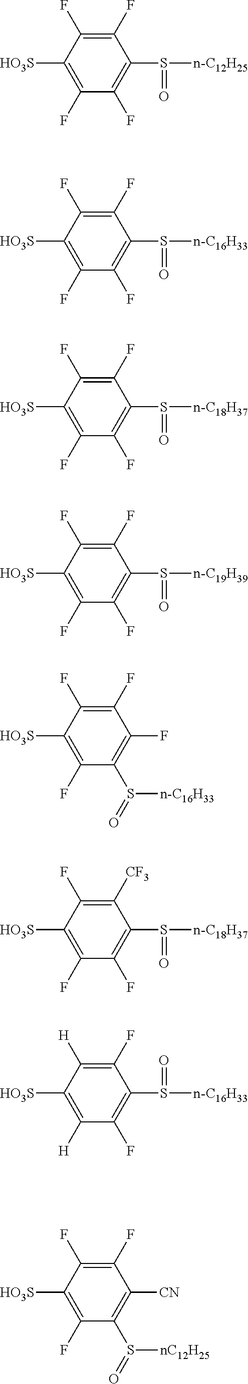

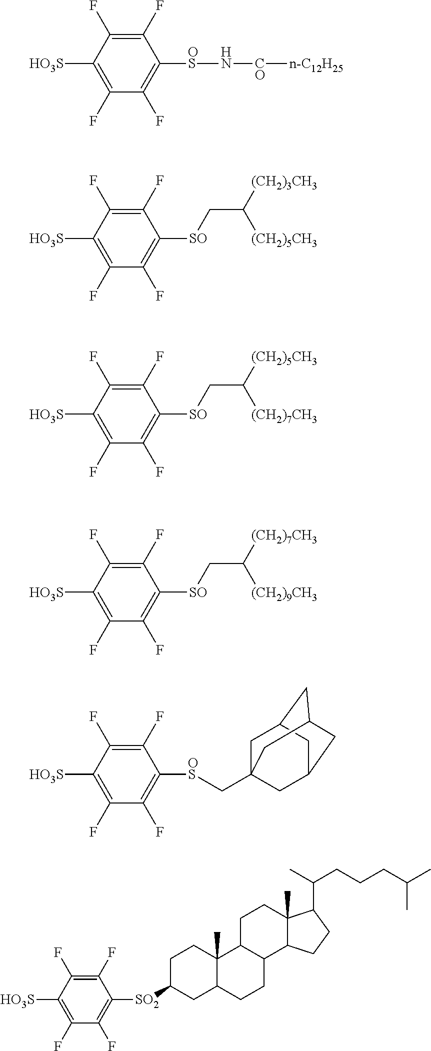

Of these, sulfonic acids that include a fluorine-unsubstituted hydrocarbon skeleton having two or more carbon atoms are preferred.

As the compound that is capable of generating the sulfonic acid represented by the above formulae (I), (I′) and (II), an iodonium salt compound and a sulfonium salt compound of the sulfonic acid represented by the above formulae (I), (I′) and (II), and an ester compound of the sulfonic acid represented by the formulae (I), (I′) and (II) are preferred, and compounds represented by the following formulae (B1) to (B5) are more preferred.

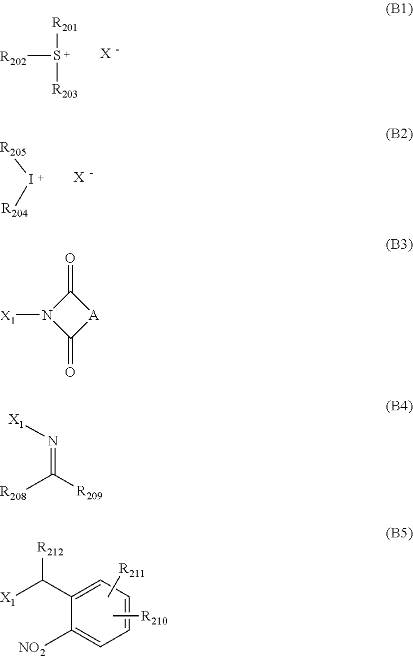

In the above formula (B1), R₂₀₁, R₂₀₂ and R₂₀₃ each independently represent a monovalent organic group, wherein two of R₂₀₁, R₂₀₂ and R₂₀₃ may taken together form a ring structure through binding.

In the above formula (B2), R₂₀₄ and R₂₀₅ each independently represent a substituted or unsubstituted aryl group, alkyl group or cycloalkyl group.

In the above formula (B3), A represents a substituted or unsubstituted alkylene group, alkenylene group or arylene group.

In the above formula (B4), R₂₀₈ represents a substituted or unsubstituted alkyl group, cycloalkyl group or aryl group; and R₂₀₉ represents an alkyl group, a cyano group, an oxoalkyl group or an alkoxycarbonyl group.

In the above formula (B5), R₂₁₀ and R₂₁₁ each independently represent a hydrogen atom, an alkyl group, a cyano group, a nitro group or an alkoxycarbonyl group; and R₂₁₂ represents a hydrogen atom, an alkyl group, a cyano group or an alkoxycarbonyl group.

In the above formulae (B1) to (B5), X⁻ represents a sulfonic acid anion obtained by removing a proton from the sulfonic acid represented by the above formula (I), (I′) or (II).

The number of carbon atoms of the organic group represented by R₂₀₁, R₂₀₂ and R₂₀₃ is typically 1 to 30, and preferably 1 to 20. The ring structure which may be taken together formed by two of R₂₀₁ to R₂₀₃ through binding may include an oxygen atom, a sulfur atom, an ester bond, an amide bond or a carbonyl group in the ring thereof.

The organic group represented by R₂₀₁, R₂₀₂ and R₂₀₃ is exemplified by groups corresponding to compounds represented by the formulae (B1a), (B1b) and (B1c) described later, and the like.

The compound (I) may have a plurality of structures represented by the above formula (B1).

For example, a compound having a structure in which at least one of R₂₀₁ to R₂₀₃ of the compound represented by the above formula (B1) is/are bonded to at least one of R₂₀₁ to R₂₀₃ of another compound represented by the above formula (B1).

As the compound represented by the above formula (B1), the following compounds (B1a), (B1b) and (B1c) are preferred.

The compound (B1a) is an arylsulfonium compound having an aryl group as at least one of R₂₀₁ to R₂₀₃ in the compound (B1), i.e., a compound having an arylsulfonium cation. In the arylsulfonium compound, all R₂₀₁ to R₂₀₃ may be an aryl group, or a part of R₂₀₁ to R₂₀₃ may be an aryl group with the rest being an alkyl group or a cycloalkyl group.

In the compound (B1b), R₂₀₁ to R₂₀₃ in the above formula (B1) each independently represent an organic group not having an aromatic ring, i.e., a group selected from an alkyl group, a cycloalkyl group, an allyl group and a vinyl group. The aromatic ring as referred to also encompasses an aromatic heteroring having a hetero atom. The number of carbon atoms of the organic group not having an aromatic ring is typically 1 to 30, and preferably 1 to 20.

The compound (B1c) is represented by the following formula (B1c), in other words, is an arylacylmethylsulfonium salt compound.

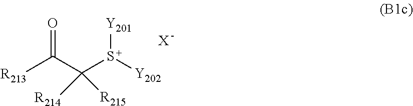

In the above formula (B1c), R₂₁₃ represents a substituted or unsubstituted aryl group; R₂₁₄ and R₂₁₅ each independently represent a hydrogen atom, an alkyl group or a cycloalkyl group; Y₂₀₁ and Y₂₀₂ each independently represent a substituted or unsubstituted alkyl group, cycloalkyl group, aryl group or vinyl group; R₂₁₃ and R₂₁₄ may taken together form a ring structure through binding; R₂₁₄ and R₂₁₅ may taken together form a ring structure through binding; Y₂₀₁ and Y₂₀₂ may taken together form a ring structure through binding; and X⁻ represents a sulfonic acid anion obtained by removing a hydrogen atom from the sulfonic acid represented by the above formula (I), (I′) or (II).

The compound (I) is preferably a compound represented by the above formula (B1), and more preferably the compounds (B1a) to (B1c).

The compound (I) preferably has a triphenylsulfonium structure.

The compound (I) is preferably a triphenylsulfonium salt compound having a cation that includes a fluorine-unsubstituted alkyl group or a cycloalkyl group.

As the compound (I), compounds represented by the following formulae b1 to b84 are preferred.

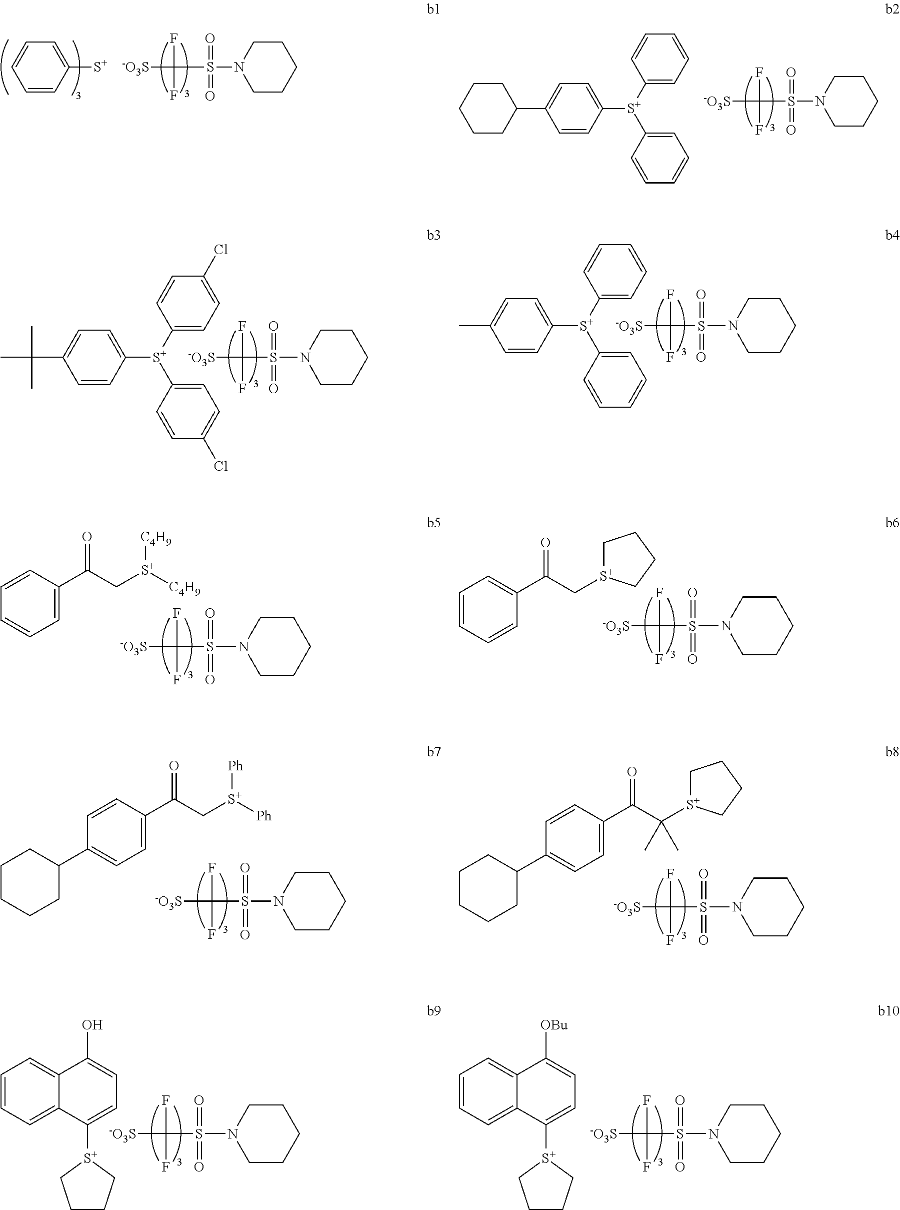

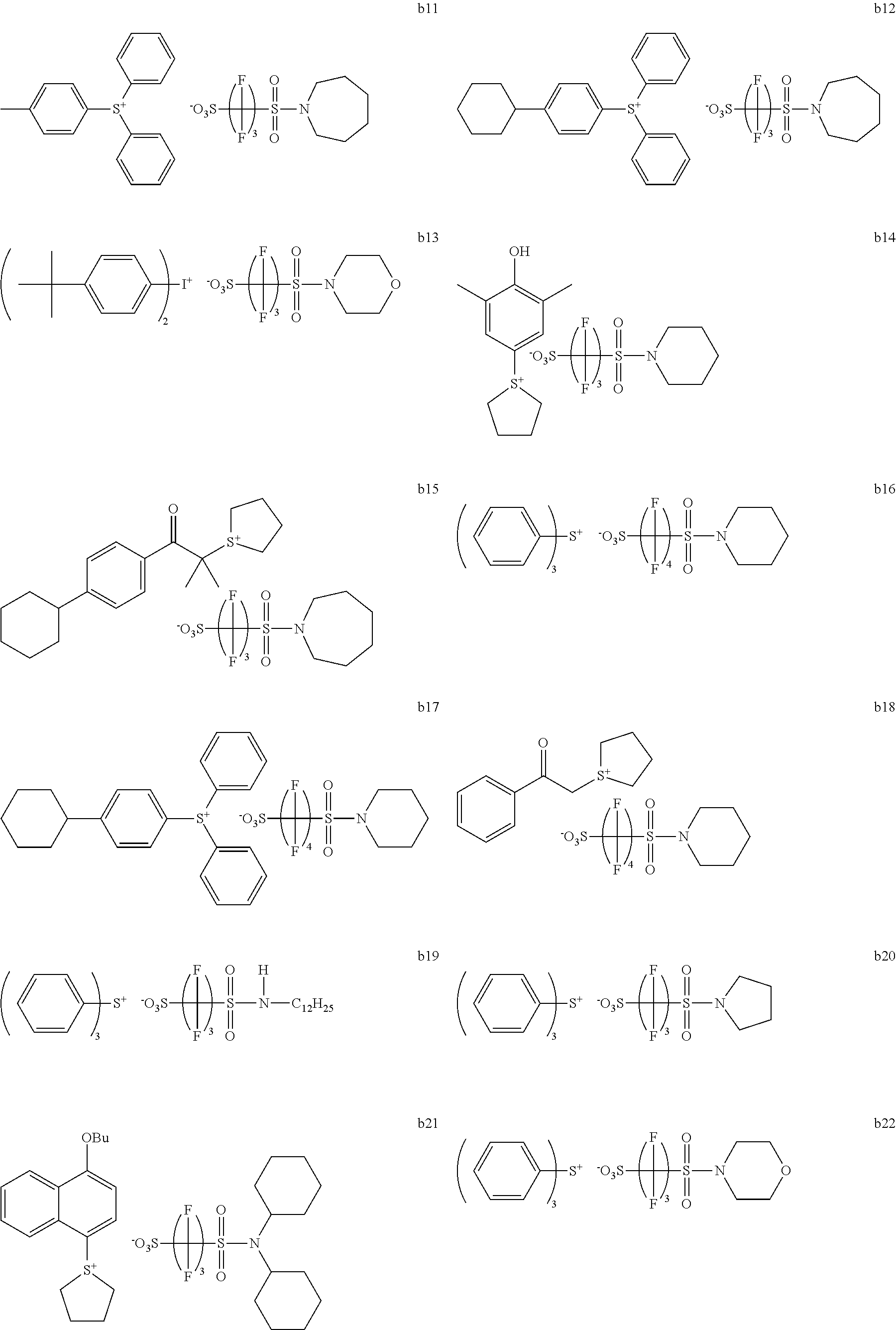

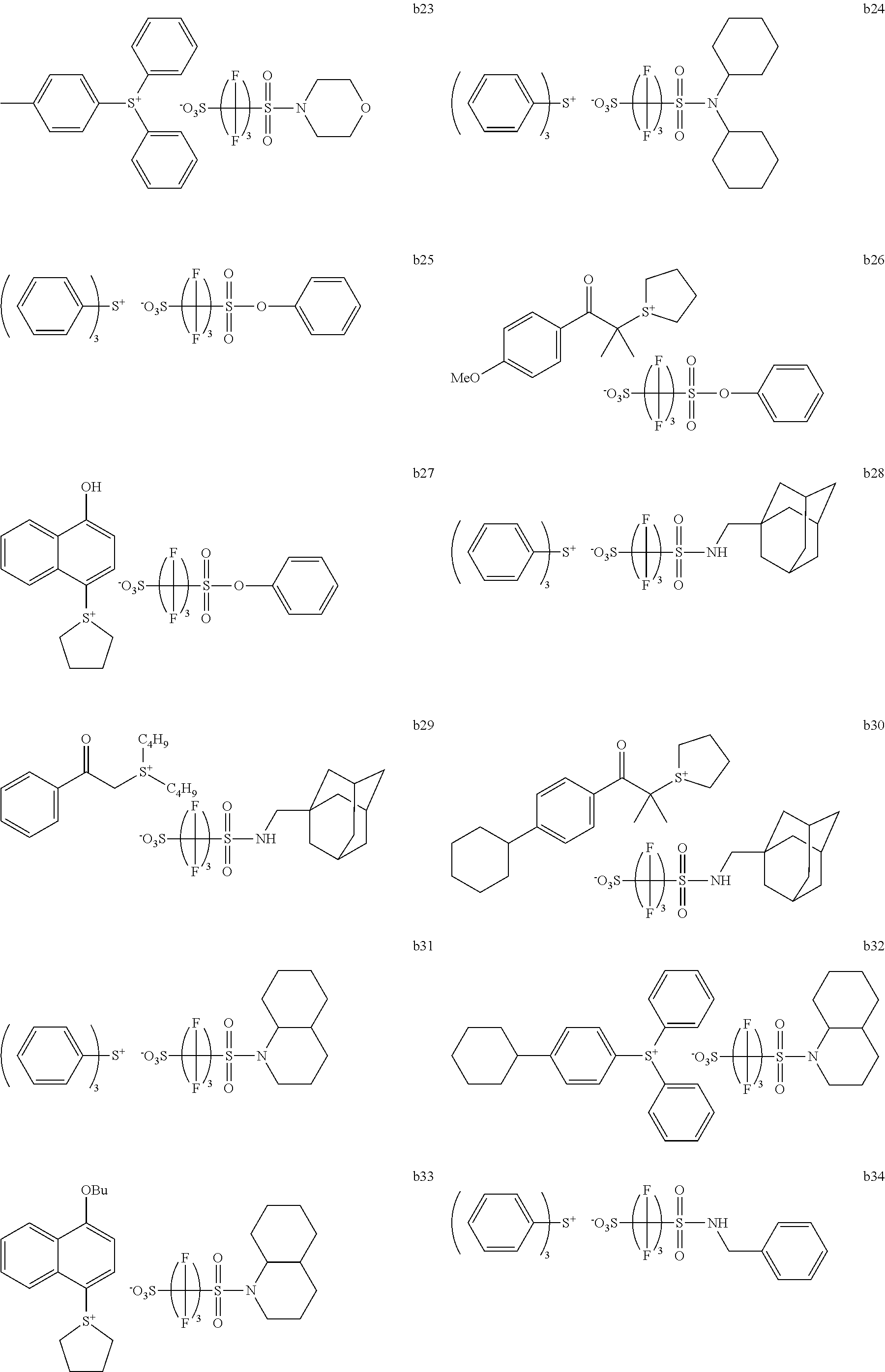

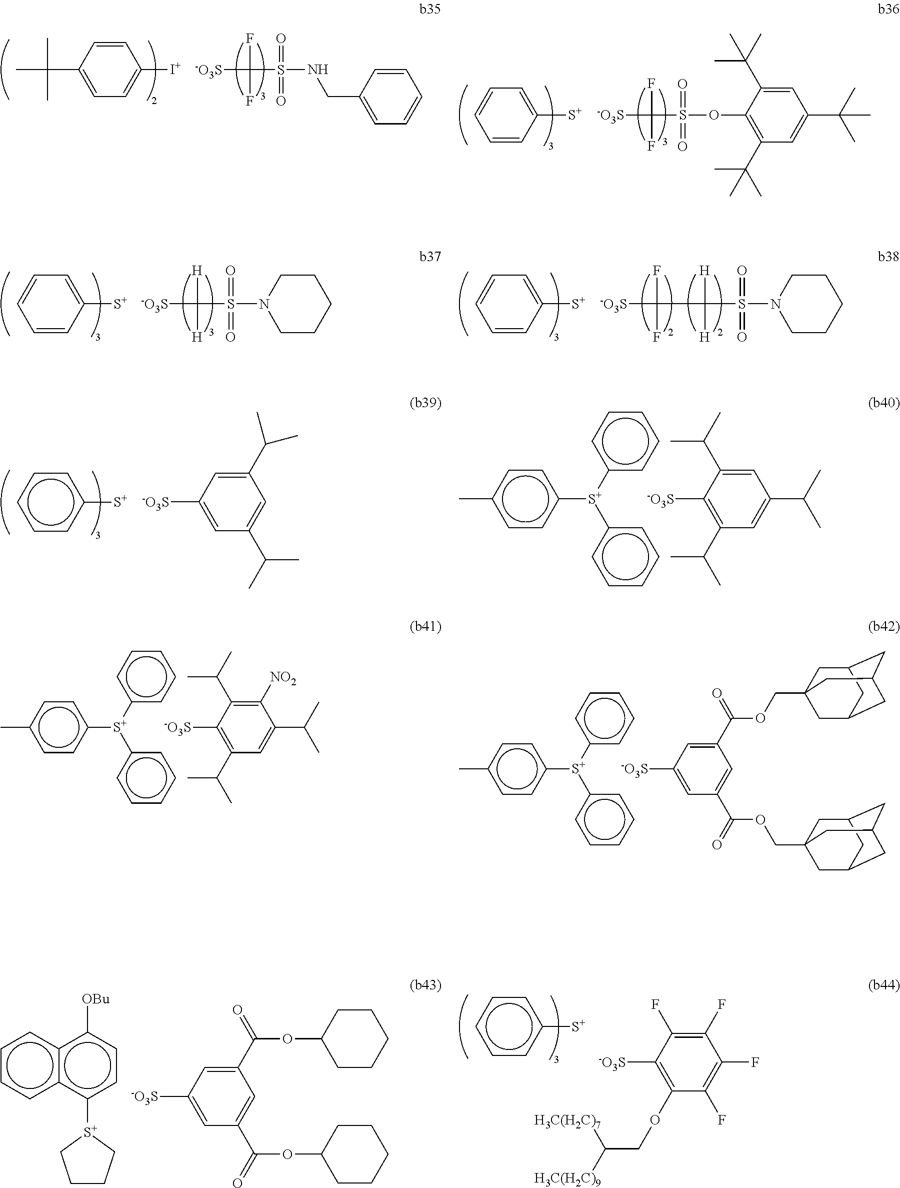

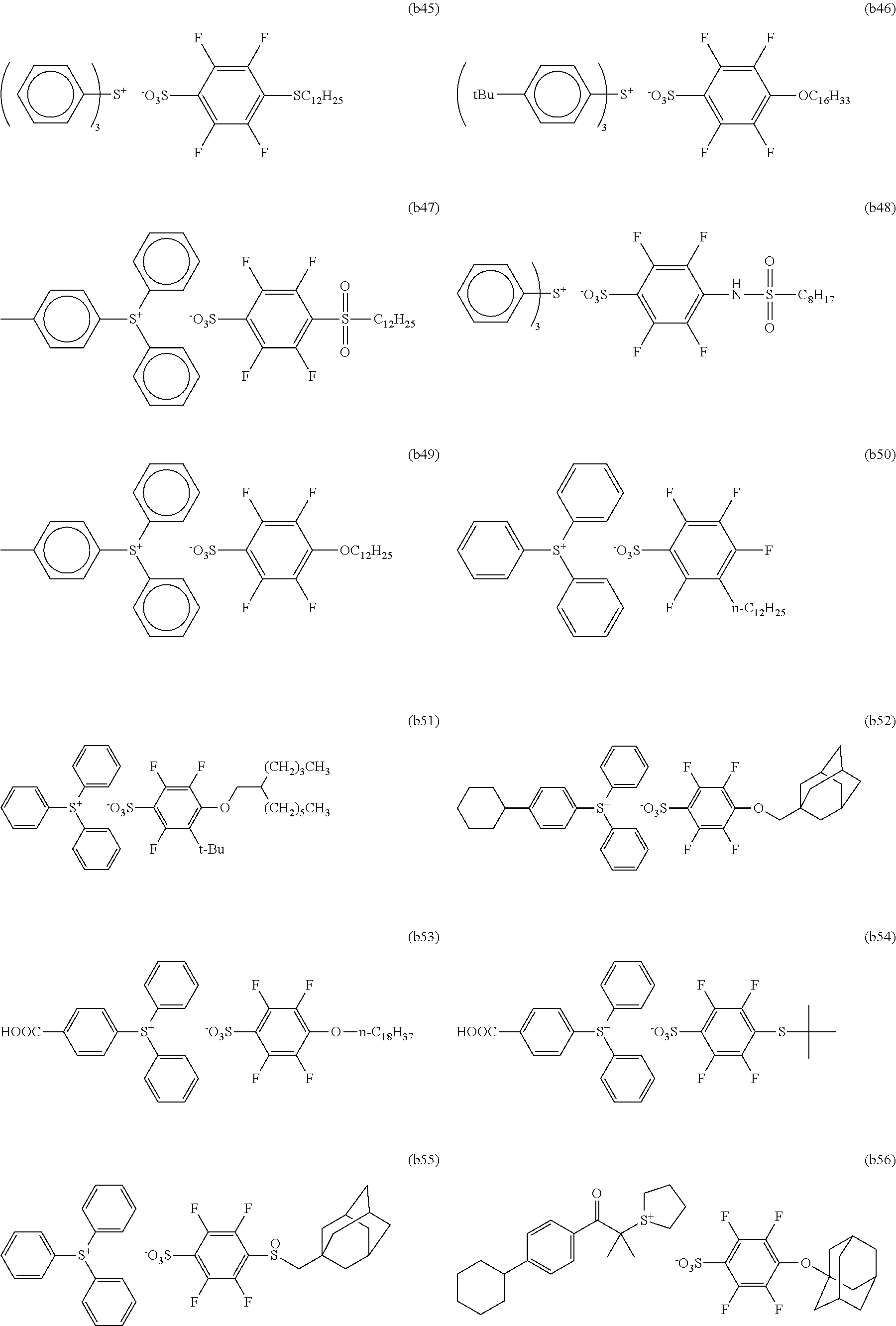

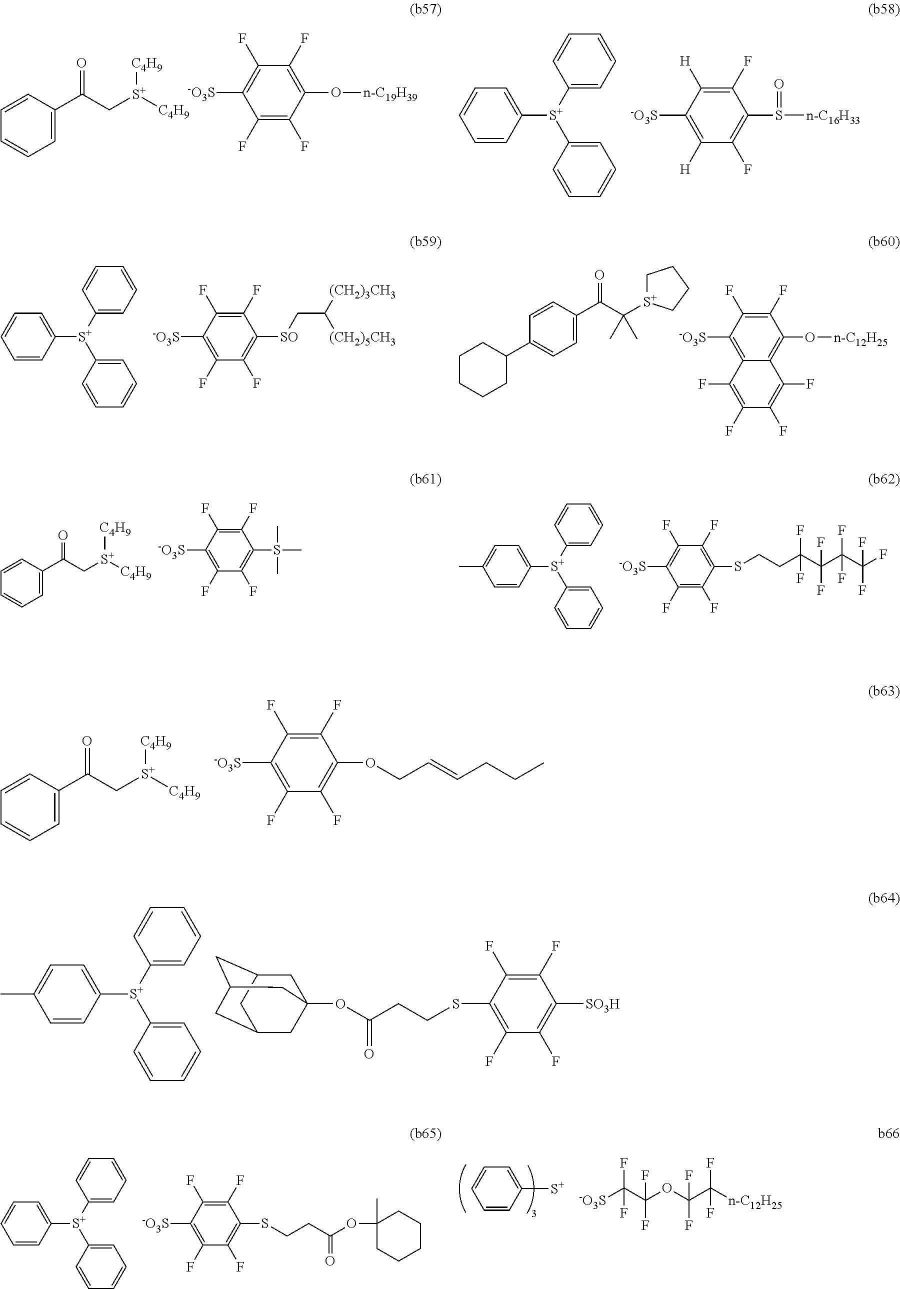

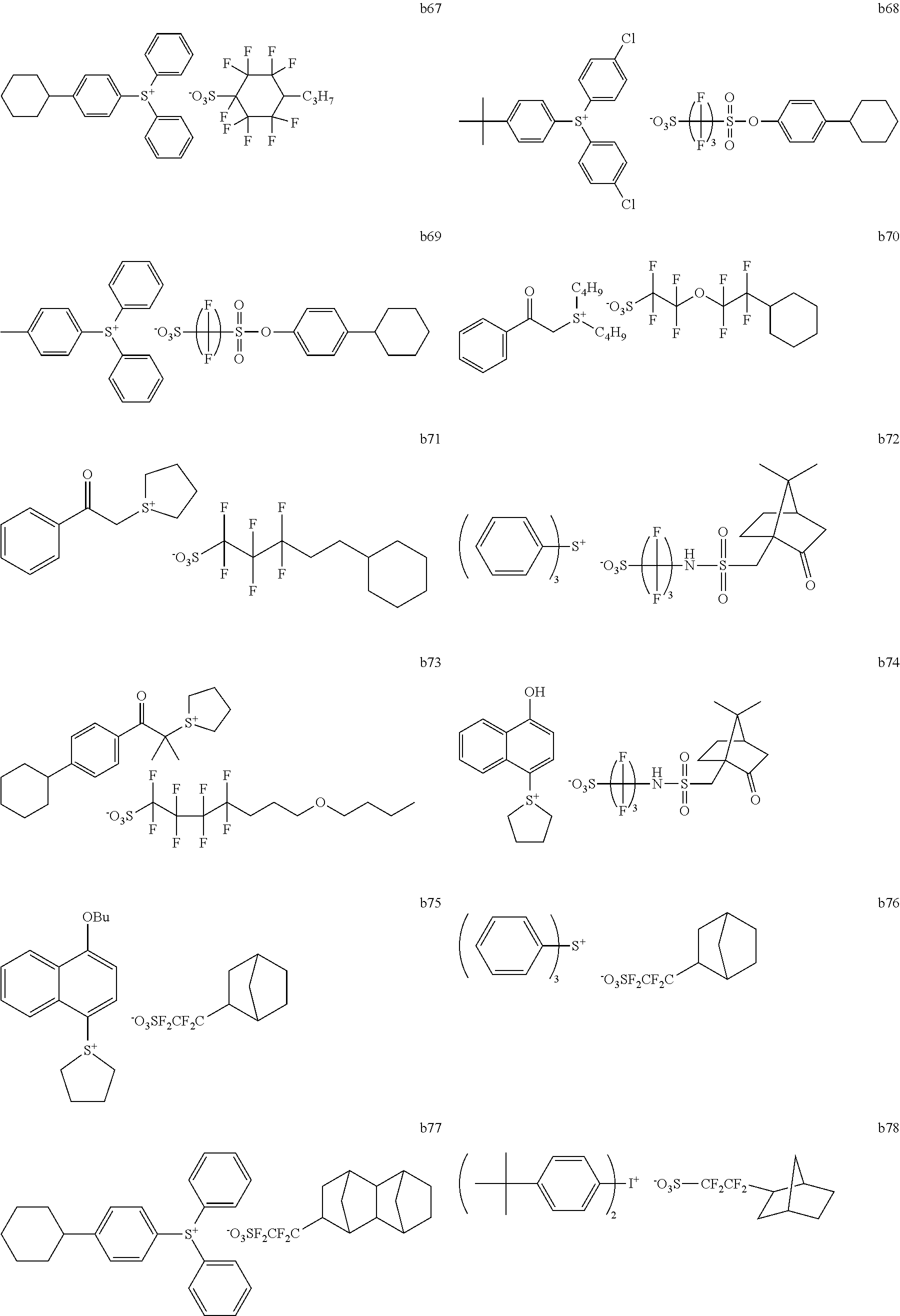

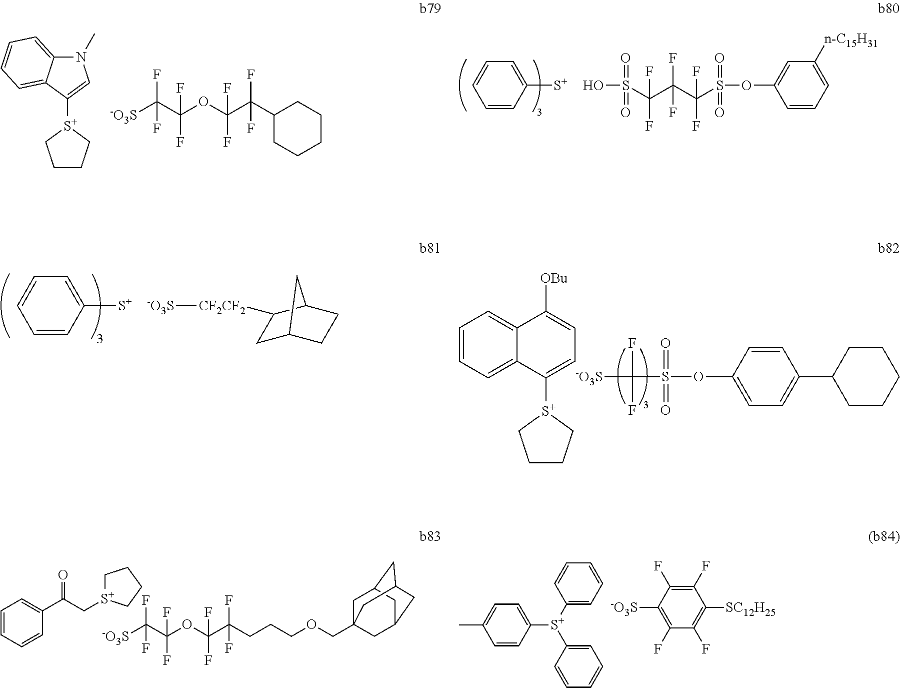

In a case where the component (B) is the acid generating agent (B), the lower limit of the content of the acid generating agent (B) with respect to the total solid content of the radiation-sensitive resin composition (I) is preferably 0.1% by mass, more preferably 1% by mass, still more preferably 5% by mass, particularly preferably 10% by mass, further particularly preferably 18% by mass, and most preferably 20% by mass. The upper limit of the content of the acid generating agent (B) is preferably 50% by mass, more preferably 40% by mass, still more preferably 35% by mass, particularly preferably 30% by mass, further particularly preferably 27% by mass, and most preferably 25% by mass.

In a case where the component (B) is the acid generating agent (B), the lower limit of the content of the acid generating agent (B) with respect to 100 parts by mass of the component (A) is preferably 0.1 parts by mass, more preferably 1 part by mass, still more preferably 5 parts by mass, particularly preferably 10 parts by mass, further particularly preferably 15 parts by mass, and most preferably 20 parts by mass. The upper limit of the content of the acid generating agent (B) is preferably 100 parts by mass, more preferably 70 parts by mass, still more preferably 50 parts by mass, particularly preferably 40 parts by mass, further particularly preferably 35 parts by mass, and most preferably 30 parts by mass.

When the content of the acid generating agent (B) falls within the above range, the sensitivity, nanoedge roughness performance and resolution can be more improved. One, or two or more types of the component (B) may be used.

### (C) Sensitizer Precursor

The sensitizer precursor (C) is a compound to be converted into a sensitizer by an action of the exposure light (I). With respect to the form of the sensitizer precursor (C) contained in the radiation-sensitive resin composition (I), the sensitizer precursor (C) may be contained: as a component that differs from the component (A); as a part of the polymer (A), i.e., as a component included in the polymer (A); or as both of these forms. In the case where the sensitizer precursor (C) is contained as a component that differs from the component (A), the sensitizer precursor (C) may be contained: in the form of a low molecular weight compound; in the form of a polymer; or in both of these forms.

The upper limit of the ratio ((I^{PP})/(I^{P})) of the absorbance (I^{PP}) of the sensitizer precursor (C) at the wavelength (II) to the absorbance (I^{P}) of the sensitizer at the wavelength (II) is 0.2, preferably 0.15, and more preferably 0.1. The lower limit of the value of the ratio ((I^{PP})/(I^{P})) is not particularly limited, and for example, 0.05. When the value of the ratio of the absorbance of the sensitizer precursor (C) to that of the sensitizer at the wavelength (II) falls within the above range, efficiency of the pattern-forming method can be more improved, and consequently, the sensitivity, nanoedge roughness and resolution can be more improved.

Examples of the sensitizer precursor (C) include bis(4-methoxyphenyl)methanol (DOMeBzH), a dimethoxybenzhydrol derivative (DOBzMM), trimethoxybenzhydrol (TriOMeBzH), and the like.

When the resist film is irradiated with the exposure light (I), the sensitizer is produced from the sensitizer precursor (C). For example, the exposure light (I) is an electron beam or EUV light. Alternatively, the exposure light (I) may be ArF laser light.

When the sensitizer is irradiated with the exposure light (II), the latent image is formed on the resist film. As described above, the irradiation with the exposure light (II) may be carried out either in the ambient air, or in vacuum. For example, the exposure light (II) is UV light.

In addition, the radiation-sensitive resin composition (I) does not absorb the exposure light (II). Typically, as the exposure light (II), a radioactive ray having a wavelength longer than that of the exposure light (I) may be used. It is preferred that the exposure light (I) does not substantially contain the radioactive ray having the wavelength (II) of the exposure light (II). When the exposure light (I) does not substantially contain the radioactive ray having the wavelength (II), contrast of the resist pattern can be more favorably provided, and as a result, the sensitivity, nanoedge roughness performance and resolution can be more improved. However, the present invention is not limited thereto, and the radioactive ray having the wavelength shorter than that of the exposure light (I) may be used as the exposure light (II).

### (D) Quencher

The radiation-sensitive resin composition (I) may contain the quencher (D). For example, the quencher (D) may perform neutralization with the acid. Also, the quencher (D) may deactivate the reaction intermediate to be a precursor of the sensitizer.

The quencher (D) is exemplified by an amine compound, an amide group-containing compound, a urea compound, a nitrogen-containing heterocyclic compound, and the like.

Examples of the amine compound include: monoalkylamines such as n-hexylamine; dialkylamines such as di-n-butylamine; trialkylamines such as triethylamine; aromatic amines such as aniline and 2,6-i-propylaniline; diamines such as ethylenediamine and N,N,N′,N′-tetramethylethylene diamine; polyamine compound s such as polyethyleneimine and polyallylamine; polymers of dimethylaminoethylacrylamide; and the like.

Examples of the amide group-containing compound include formamide, N-methylformamide, N,N-dimethylformamide, acetamide, N-methylacetamide, N,N-dimethylacetamide, propionamide, benzamide, pyrrolidone, N-methylpyrrolidone, and the like.

Examples of the urea compound include urea, methylurea, 1,1-dimethylurea, 1,3-dimethylurea, 1,1,3,3-tetramethylurea, 1,3-diphenylurea, tributylthiourea, and the like.

Examples of the nitrogen-containing heterocyclic compound include: pyridines such as pyridine and 2-methylpyridine; morpholines such as N-propylmorpholine and N-(undecyl carbonyloxyethyl)morpholine; pyrazine, pyrazole; and the like.

As the nitrogen-containing compound, a compound having an acid-labile group may be also used. Examples of such a nitrogen-containing compound having an acid-labile group include N-t-butoxycarbonylpiperidine, N-t-butoxycarbonylimidazole, N-t-butoxycarbonylbenzimidazole, N-t-butoxycarbonyl-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-t-butoxycarbonyl-4-hydroxypiperidine, N-t-amyloxycarbonyl-4-hydroxypiperidine, and the like.

Alternatively, as the quencher (D), a photodegradable base that generates a weak acid through photosensitization upon an exposure may be also used. The photodegradable base is exemplified by onium salt compounds that loses acid diffusion controllability through degradation upon an exposure, and the like. Examples of the onium salt compound include a sulfonium salt compound represented by the following formula (5-2-1), an iodonium salt compound represented by the following formula (5-2-2), and the like.

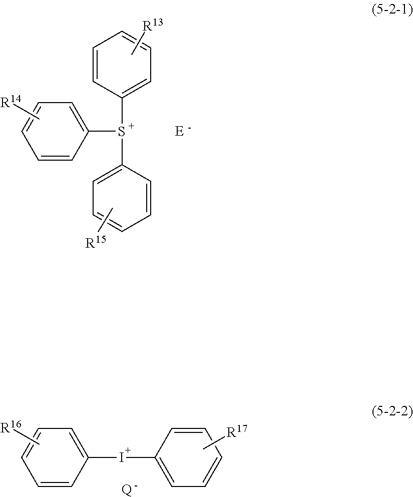

In the above formula (5-2-1) and formula (5-2-2), R¹³ to R¹⁷ each independently represent a hydrogen atom, an alkyl group, an alkoxy group, a hydroxy group or a halogen atom; and E⁻ and Q⁻ each independently represent OH⁻, R^{β}—COO⁻, R^{β}—SO₃⁻ or an anion represented by the following formula (5-2-a), wherein R^{β} represents an alkyl group or an aralkyl group.

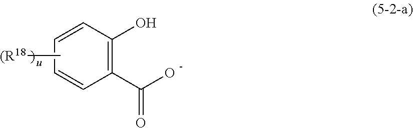

In the above formula (5-2-a), R¹⁸ represents an alkyl group having 1 to 12 carbon atoms, a fluorinated alkyl group having 1 to 12 carbon atoms or an alkoxy group having 1 to 12 carbon atoms; and u is an integer of 0 to 2, wherein in a case where u is 2, two R¹⁸s may be identical or different.

Examples of the photodegradable base include compounds represented by the following formulae, and the like.

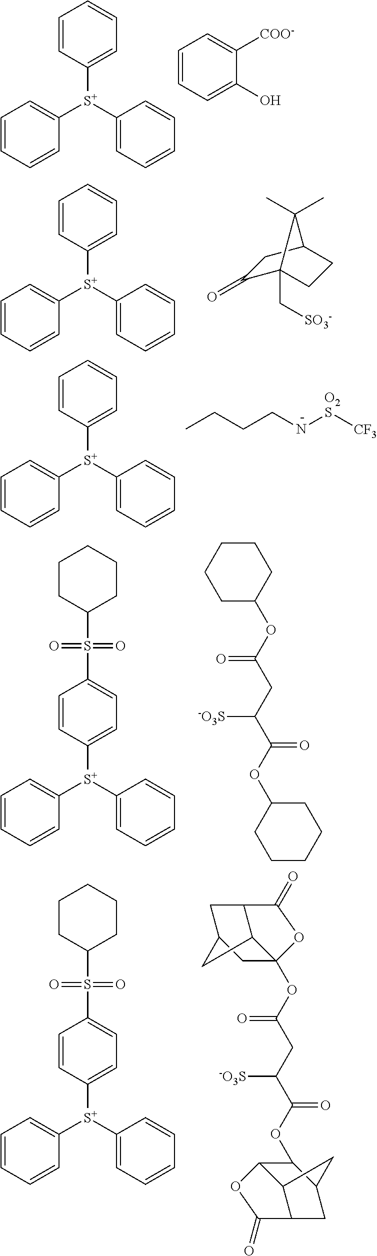

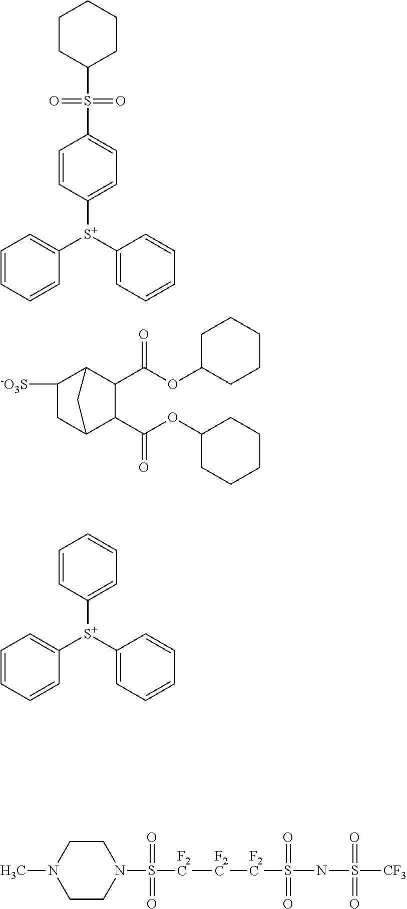

Of these, the photodegradable base is preferably a sulfonium salt, more preferably a triarylsulfonium salt, still more preferably a triphenylsulfonium salt or a 4-cyclohexylsulfonylphenyldiphenyl sulfonium salt, and particularly preferably a salicylate compound, a 10-camphorsulfonate compound, a N-n-butyltrifluoromethylsulfonamide compound, a 1,2-di(cyclohexyloxycarbonyl)ethane-1-sulfonate compound and a 1,2-di(norbomanelacton-2-yloxycarbonyl)ethane-1-sulfonate compound.

When the radiation-sensitive resin composition (I) contains the quencher (D), the lower limit of the content of the quencher (D) with respect to 100 parts by mass of the component (A) is preferably 0.1 parts by mass, more preferably 0.5 parts by mass, still more preferably 1 part by mass, and particularly preferably 3 parts by mass.

The upper limit of the content of the quencher (D) is preferably 20 parts by mass, more preferably 15 parts by mass, and still more preferably 10 parts by mass.

### (E) Solvent

The radiation-sensitive resin composition (I) typically contains the solvent (E). The solvent (E) is not particularly limited as long as it is a solvent capable of dissolving or dispersing at least the component (A), the component (B) and the sensitizer precursor (C) as well as the quencher (D), etc., contained as desired.

Examples of the solvent (E) include those exemplified as the organic solvent contained in the developer solution for use in the development step, and the like.

Of these, the ester solvents and the ketone solvents are preferred, the polyhydric alcohol partial ether acetate solvents, the cyclic ketone she solvents and lactone solvents are more preferred, and propylene glycol monomethyl ether acetate, cyclohexanone and γ-butyrolactone are still more preferred. The radiation-sensitive resin composition (I) may contain one, or two or more types of the solvent (E).

### (F) Polymer

The radiation-sensitive resin composition (I) may contain the polymer (F). The polymer (F) has a total mass percentage content of fluorine atom and silicon atom greater than that of the component (A).

When the radiation-sensitive resin composition (I) contains the polymer (F), in forming the resist film, the polymer (F) in the resist film tends to be localized in the surface region of the resist film due to the oil repellency characteristics thereof. Thus, the elution of the acid generating agent, the acid diffusion control agent and/or the like into a liquid immersion medium in the liquid immersion lithography can be inhibited, and development defects can be prevented by imparting a function of increasing the solubility in a developer solution.

The lower limit of the total mass percentage content of fluorine atom and silicon atom of the polymer (F) is preferably 1% by mass, more preferably 2% by mass, still more preferably 4% by mass, and particularly preferably 7% by mass. The upper limit of the total mass percentage content is preferably 60% by mass, more preferably 40% by mass, and still more preferably 30% by mass. When the total mass percentage content falls within the above range, the hydrophobicity of the surface of the resist film can be more adequately adjusted. The total mass percentage content of fluorine atom and silicon atom of a polymer can be calculated based on the polymer structure determined by ¹³C-NMR spectroscopy, for example.

The polymer (F) is exemplified by a polymer having a fluorine atom, a polymer having a silicon atom, and the like.

Polymer Having Fluorine Atom

The polymer (F) preferably has at least one of a structural unit represented by the following formula (6-1) (hereinafter, may be also referred to as “structural unit (Fa)”) and a structural unit represented by the following formula (6-2) (hereinafter, may be also referred to as “structural unit (Fb)”). The polymer (F) may have each one, or two or more types of the structural unit (Fa) and the structural unit (Fb).

Structural Unit (Fa))

The structural unit (Fa) is represented by the following formula (6-1). Due to having the structural unit (Fa), the polymer (F) can adjust the percentage content of fluorine atom.

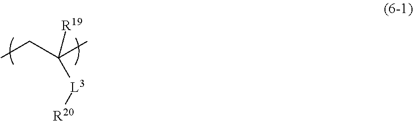

In the above formula (6-1), R¹⁹ represents a hydrogen atom, a fluorine atom, a methyl group or a trifluoromethyl group; L³ represents a single bond, an oxygen atom, a sulfur atom, —CO—O—, —SO₂—O—NH—, —CO—NH— or —O—CO—NH—; and R²⁰ represents a monovalent fluorinated chain hydrocarbon group having 1 to 6 carbon atoms or a monovalent fluorinated alicyclic hydrocarbon group having 4 to 20 carbon atoms.

In light of the degree of copolymerization of a monomer that gives the structural unit (Fa), R¹⁹ represents preferably a hydrogen atom or a methyl group, and more preferably a methyl group.

Examples of the monovalent fluorinated chain hydrocarbon group having 1 to 6 carbon atoms which may be represented by R²⁰ include a trifluoromethyl group, a 2,2,2-trifluoroethyl group, a perfluoroethyl group, a 2,2,3,3,3-pentafluoropropyl group, a 1,1,1,3,3,3-hexafluoropropyl group, a perfluoro n-propyl group, a perfluoro i-propyl group, a perfluoro n-butyl group, a perfluoro i-butyl group, a perfluoro t-butyl group, a 2,2,3,3,4,4,5,5-octafluoropentyl group, a perfluorohexyl group, and the like.

Examples of the monovalent fluorinated alicyclic hydrocarbon group having 4 to 20 carbon atoms which may be represented by R²⁰ include a monofluorocyclopentyl group, a difluorocyclopentyl group, a perfluorocyclopentyl group, a monofluorocyclohexyl group, a difluorocyclopentyl group, a perfluorocyclohexylmethyl group, a fluoronorbornyl group, a fluoroadamantyl group, a fluorobornyl group, a fluoroisobornyl group, a fluorotricyclodecyl group, a fluorotetracyclodecyl group, and the like.

The structural unit (Fa) is preferably a 2,2,2-trifluoroethyl (meth)acrylate.

When the polymer (F) has the structural unit (Fa), the lower limit of the proportion of the structural unit (Fa) with respect to the total structural units constituting the polymer (F) is preferably 5 mol %, more preferably 10 mol %, and still more preferably 20 mol %. The upper limit of the proportion of the structural unit (Fa) is preferably 95 mol %, more preferably 75 mol %, and still more preferably 50 mol %. When the proportion of the structural unit (Fa) falls within the above range, percentage content of fluorine atom can be more adequately adjusted.

Structural Unit (Fb)

The structural unit (Fb) is represented by the following formula (6-2). Due to having the structural unit (Fb), the polymer (F) has increased hydrophobicity, and therefore, the surface of the resist film formed from the radiation-sensitive resin composition (I) can have a further improved dynamic contact angle.

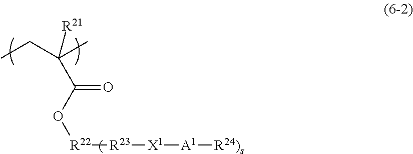

In the above formula (6-2), R²¹ represents a hydrogen atom, a fluorine atom, a methyl group or a trifluoromethyl group; R²² represents a hydrocarbon group having 1 to 20 carbon atoms and having a valency of (s+1), or a structure in which the hydrocarbon group binds to an oxygen atom, a sulfur atom, —NR′ a carbonyl group, —CO—O— or —CO—NH— to the end on the R²³ side of the hydrocarbon group, wherein R′ represents a hydrogen atom or a monovalent organic group; R²³ represents a single bond, a divalent chain hydrocarbon group having 1 to 10 carbon atoms or a divalent alicyclic hydrocarbon group having 4 to 20 carbon atoms; X¹ represents a divalent fluorinated chain hydrocarbon group having 1 to 20 carbon atoms; A¹ represents an oxygen atom, —NR″—, —CO—O—* or —SO₂—O—*, wherein R″ represents a hydrogen atom or monovalent organic group, and * denotes a binding site to R²⁴; R²² represents; R²⁴ represents a hydrogen atom, or a monovalent hydrocarbon group having 1 to 30 carbon atoms which may have an acid-labile group, an alkali-labile group or a substituent; and s is an integer of 1 to 3, wherein in a case where s is 2 or 3, a plurality of R²³s may be identical or different, a plurality of X¹s may be identical or different, a plurality of A¹s may be identical or different, and a plurality of R²⁴s may be identical or different.

Examples of the structural unit (Fb) include the structural units represented by the following formulae (6-2-1) to (6-2-3), and the like.

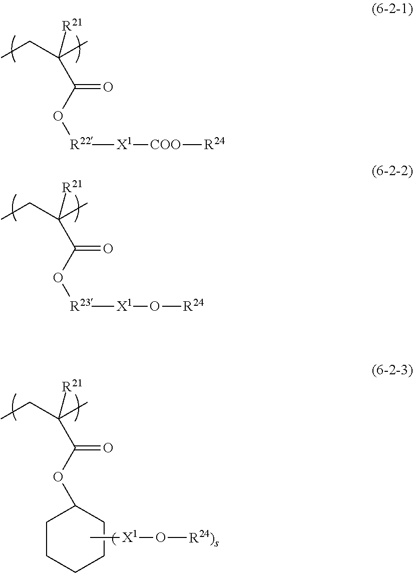

In the above formulae (6-2-1) to (6-2-3), R^{22′} represents a divalent hydrocarbon group having 1 to 20 carbon atoms; R²¹, X¹, R²⁴ and s are as defined in the above formula (6-2), wherein in a case where s is 2 or 3, a plurality of X¹s may be identical or different, and a plurality of R²⁴s may be identical or different.

When the polymer (F) has the structural unit (Fb), the lower limit of the proportion of the structural unit (Fb) with respect to the total structural units constituting the polymer (F) is preferably 5 mol %, more preferably 10 mol %, and still more preferably 15 mol %. The upper limit of the proportion of the structural unit (Fb) is preferably 90 mol %, more preferably 70 mol %, and still more preferably 50 mol %. When the proportion of the structural unit (Fb) falls within the above range, the percentage content of the fluorine atom can be more adequately adjusted.

Structural Unit (Fc))

The polymer (F) may also have, in addition to the structural units (Fa) and (Fb), a structural unit that includes an acid-labile group (hereinafter, may be also referred to as “structural unit (Fc)”), except for those corresponding to the structural unit (Fb). When the polymer (F) has the structural unit (Fc), the resulting resist pattern can have a more favorable shape. The structural unit (Fc) may be exemplified by the structural unit (I) which may be included in the aforementioned polymer (A), and the like.

When the polymer (F) has the structural unit (Fc), the lower limit of the proportion of the structural unit (Fc) with respect to the total structural units constituting the polymer (F) is preferably 5 mol %, more preferably 25 mol %, and still more preferably 60 mol %. The upper limit of the proportion of the structural unit (Fc) is preferably 90 mol %, more preferably 80 mol %, and still more preferably 75 mol %.

Other Structural Unit

Moreover, in addition to the structural units (Fa) to (Fc), the polymer (F) may also have other structural unit such as, for example: a structural unit that includes an alkali-soluble group; a structural unit that includes a lactone structure, a cyclic carbonate structure, a sultone structure or a combination thereof; and a structural unit derived from (meth)acrylate that includes a nonlabile monovalent alicyclic hydrocarbon group. Examples of the alkali-soluble group include a carboxy group, a sulfonamide group, a sulfo group, and the like. Examples of the structural unit that includes a lactone structure, a cyclic carbonate structure, a sultone structure or a combination thereof include the structural unit (II) which may be included in the aforementioned polymer (A), and the like.

The upper limit of the proportion of the other structural unit with respect to the total structural units constituting the polymer (F) is preferably 30 mol %, and more preferably 20 mol %.

When the radiation-sensitive resin composition (I) contains the polymer (F), the lower limit of the content of the polymer (F) with respect to 100 parts by mass of the component (A) is preferably 0.5 parts by mass, more preferably 1 part by mass, and still more preferably 2 parts by mass. The upper limit of the content of the polymer (F) is preferably 20 parts by mass, more preferably 10 parts by mass, and still more preferably 7 parts by mass.

Other Component

The radiation-sensitive resin composition (I) may contain other component. The other component is exemplified by a surfactant, an alicyclic skeleton-containing compound, and the like. The radiation-sensitive resin composition (I) may contain each one, or two or more types of the other component.

### Preparation Method of Radiation-Sensitive Resin Composition (I)

The radiation-sensitive resin composition (I) may be prepared by, for example, mixing the component (A), the component (B) and the sensitizer precursor (C), and the quencher (D), etc., which may be contained as needed, as well as the solvent (E) in a certain ratio. After mixing, the radiation-sensitive resin composition (I) is preferably filtered through a filter having a pore size of about 0.2 μm, for example. The lower limit of the solid content concentration of the radiation-sensitive resin composition (I) is preferably 0.1% by mass, more preferably 0.5% by mass, and still more preferably 1% by mass. The upper limit of the solid content concentration is preferably 50% by mass, more preferably 30% by mass, and still more preferably 10% by mass.

Since the radiation-sensitive resin composition (I) is of a chemically amplified type, the sensitizer absorbs the exposure light (II) to generate the acid and the sensitizer, thereby allowing the resist reaction to proceed. For example, by irradiating with the exposure light (II), an excited state of the sensitizer is formed. Electron transfer from the sensitizer in the excited state permits the component (B) to cause degradation through a dissociable electron addition (DEA) reaction, whereby the acid and the sensitizer unexcited are newly generated. The acid and the sensitizer are generated in the regions where the sensitizer is present as long as the irradiation with the exposure light (II) is continued, until the component (B) almost disappears.

According to the radiation-sensitive resin composition (I), by executing photoflood exposure of the sensitizer that comes to exhibit a narrower concentration distribution due to the quencher that decreases the sensitizer in the exposure step (I), the excited state of the sensitizer is formed. Electron transfer from the sensitizer in the excited state permits degradation of the acid generating agent, whereby the acid and the sensitizer unexcited are newly generated. The acid and the sensitizer are generated in the regions where the sensitizer is present until the acid generating agent almost disappears. Also, in the regions where the amount of remaining acid generating agent is decreased, the acid-generating reaction is retarded to reach saturation. In the regions irradiated with the exposure light (I), the distribution of the concentration of the acid after the neutralization of the acid with the quencher is constant at around the center, whereas steeply arises on the periphery. Thus, the acid is formed such that the distribution of the concentration on the periphery altering with a steep inclination is provided. Accordingly, all the matter in connection with the sensitivity improvement, increase in resolution, reduction of LER, photon shot noise can be concurrently achieved.

In the following, suitable examples of use of the radiation-sensitive resin composition (I) of the present embodiment will be described.

### Specific Example 5

The radiation-sensitive resin composition (I) is provided. The radiation-sensitive resin composition (I) contain the component (A), the component (B) and the sensitizer precursor (C). In the present embodiment, the radiation-sensitive resin composition (I) produces the sensitizer through the irradiation with the exposure light (I), whereas the sensitizer is not produced even when irradiation with the exposure light (II) that accelerates the resist reaction by this sensitizer is executed, without the irradiation with the exposure light (I).

The resist film is formed by using the radiation-sensitive resin composition (I). The resist film is formed on the substrate by, for example, a spin-coating procedure.

The exposure step (1) is carried out. In the exposure step (1), the irradiation with the exposure light (I) is executed patternwise. In the regions irradiated with the exposure light (I), the sensitizer is produced. In addition, the acid is generated together with the sensitizer in this procedure. In the exposure step (1), due to a low patternwise irradiation dose, the resist pattern is not formed on the resist film even if the development step is carried out. It is to be noted that in Specific Example 5, a decrease in the amount of the acid and/or the sensitizer in the resist film may or may not be inhibited by the maintaining step described above.

Concurrently with or following carrying out the exposure step (1), the exposure step (2) is carried out. In the exposure step (2), a floodwise exposure is executed, i.e., one face is irradiated with the exposure light (II). As shown in FIGS. 5A to 5C, the exposure light (II) is appropriately selected such that in the exposure light (I)-unirradiated regions of the resist film, the acid and the sensitizer are not generated, and the sensitizer is activated. By irradiating with the exposure light (II), the acid is generated through a reaction of the sensitizer with the acid generating agent.

Accordingly, in the exposure step (2), even though the one face is irradiated with the exposure light (II), the sensitizer is generated only in the regions irradiated patternwise first, and the sensitizer is activated only in the regions irradiated patternwise first by irradiating the one face (floodwise). Thus, a large amount of the acid is generated only in the regions irradiated patternwise first, and even after the neutralization of the acid with the quencher, the latent image of the acid is formed only in the regions irradiated patternwise first. Thereafter, the heating step and the development step are carried out to form a resist pattern.

### Specific Example 6

The resist film is formed by using the radiation-sensitive resin composition (I). The exposure step (1) is carried out. In the exposure step (1), the irradiation with the exposure light (I) is executed patternwise. In the regions irradiated with the exposure light (I), the acid and the sensitizer are generated. In this step, due to a low patternwise irradiation dose, the resist pattern is not formed on the resist film even if the development step is carried out. Also, in Specific Example 6, a decrease in the amount of the acid and the sensitizer in the resist film may or may not be inhibited by the maintaining step described above.

Concurrently with or following carrying out the exposure step (1), the exposure step (2) is carried out. In the exposure step (2), a floodwise exposure is executed, i.e., one face is irradiated with the exposure light (II). The exposure light (II) is appropriately selected such that in the resist film 12 unirradiated with the exposure light (I), the acid from the component (B), and the sensitizer from the sensitizer precursor (C) are not generated substantially, and only the active substance α/stable substance α1 is activated. By irradiating with the exposure light (II), production of the sensitizer from the sensitizer precursor (C), and/or generation of the acid (or an acid having a different structure from that of the aforementioned acid, or a precursor of the acid) from the component (B) occur. The sensitizer reacts with the active atmosphere or active liquid to be converted again into the active substance α/stable substance α1.

Accordingly, in the exposure step (2), even though the one face is irradiated with the exposure light (II), the acid is generated only in the regions irradiated patternwise first, and the active substance α/stable substance α1 is regenerated only in the regions irradiated patternwise first by irradiating the one face (floodwise). Thus, a large amount of the acid is generated only in the regions irradiated patternwise first, and even after the neutralization of the acid with the quencher, the latent image of the acid is formed only in the regions irradiated patternwise first. Thereafter, the heating step and the development step are carried out to form a resist pattern.

### Specific Example 7

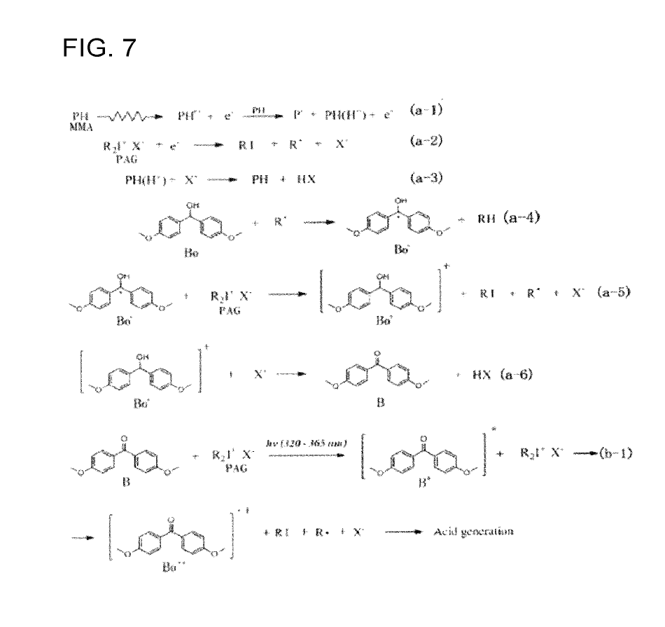

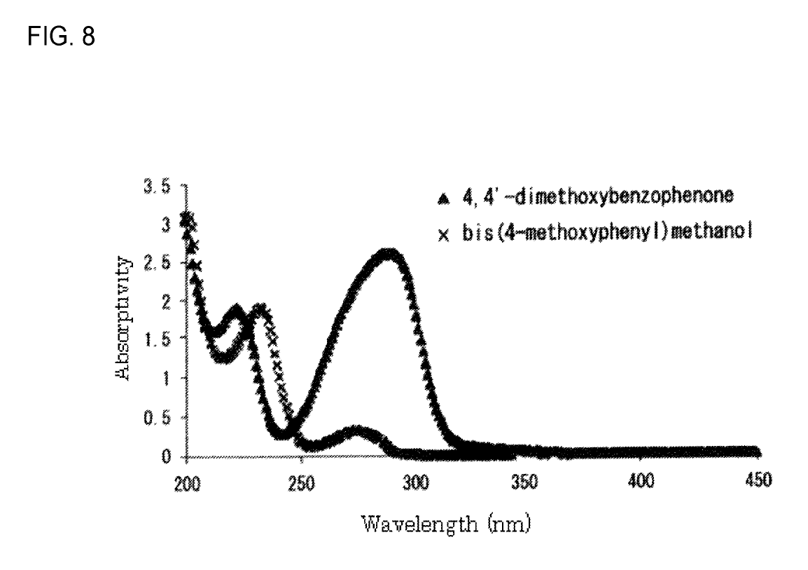

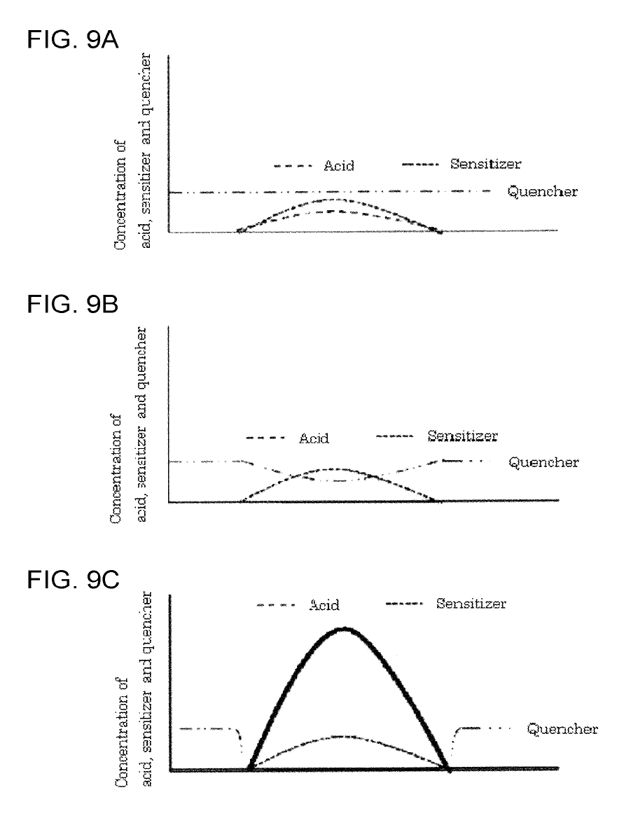

In the following, Specific Example 7 will be described with reference to FIGS. 7 to 9. First, the radiation-sensitive resin composition (I) is prepared. The radiation-sensitive resin composition (I) contains: a copolymer of γ-butyrolactone-α-methacrylate, 2-(1-adamantyl)propane-2-yl methacrylate, 3-hydroxyadamantan-1-yl methacrylate and 1-ethylcyclopentyl methacrylate as a polymer that is the component (A); bis(4-methoxyphenyl)methanol (DOMeBzH) as the sensitizer precursor (C); and an iodonium salt (R₂IX) as the acid generating agent (B). With respect to 100 parts by mass of the component (A), the sensitizer precursor (C) is contained in an amount of 4.6 parts by mass (no less than 3 parts by mass and no greater than 30 parts by mass, preferably, no less than 4 parts by mass and no greater than 10 parts by mass), and the acid generating agent (B) is contained in an amount of 4.6 parts by mass (no less than 3 parts by mass and no greater than 30 parts by mass, preferably no less than 4 parts by mass and no greater than 10 parts by mass).

Next, the radiation-sensitive resin composition (I) is spin-coated on a silicon substrate, followed by subjecting to a prebaking treatment. Conditions of the spin-coating may be changed depending on the solid content concentration and the like of the radiation-sensitive resin composition (I), and in this step, the spin-coating may be performed at 1,500 rpm for 30 sec, with prebaking at 100° C., for 60 sec. Also, the amount of the quencher added may be around tenth ( 1/10) by mass the amount of the acid generating agent (B) added, and for example, the quencher in the total solid content of the radiation-sensitive resin composition (I) may be no less than 0.1% by mass and no greater than 3.0% by mass, and preferably no less than 0.3% by mass and no greater than 1.2% by mass.

FIG. 7 shows a chemical reaction equation employed in the present embodiment. The resist film is irradiated patternwise with an electron beam. The patternwise exposure with the electron beam is executed using, for example, JSM-6500F, 30 keV, EB lithography system (JEOL, beam stream: 12.5 and 28 pA, <1E⁻⁴ Pa) equipped with a beam draw (Tokyo Technology LTD.).

In regard to the reaction mechanism in the resist film when irradiated patternwise with the electron beam, the reaction is believed to proceed according to the formulae (a-1) to (a-5) shown in FIG. 7. As represented by the formula (a-1), the patternwise irradiation with the electron beam allows for ionization in the resist film, thereby producing predominantly a polymeric radical cation (RH⁺•) and an electron (e⁻). The polymeric radical cation (RH⁺•) reacts with a polymer (RH), and is separated into a radical P• and a cation (RH(H⁺)).

As represented by the formula (a-2), the electron (e⁻) reacts with the acid generating agent (B) (R₂I⁺X⁻) to produce a neutral molecule (RI), a radical (R•) and an anion (X⁻).

As represented by the formula (a-3), the cation (RH(H⁺)) reacts with the anion (X⁻) to produce the polymer (RH) and an acid (HX).

Further, as represented by the formula (a-4), when the radical (R•) reacts with DOMeBzH, a radical (DOMeBzH•) is produced. As represented by the formula (a-5), the radical reacts with the acid generating agent (B) (R₂I⁺X⁻) to produce a cation (DOMeBzH⁺) through transfer of the electron. Moreover, as represented by the formula (a-6), transfer of the proton from this cation (DOMeBzH⁺) to the anion results in generation of the sensitizer (DOMeBzO) and the acid (HX).

Next, after the patternwise irradiation with the electron beam, irradiation with flood UV (320 and 365 nm) is executed at room temperature. In regard to the reaction mechanism in the resist film when irradiated with the flood UV, the reaction is believed to proceed according to the formula (b-1) shown in FIG. 7. The irradiation with flood UV results in excitation of the sensitizer (DOMeBzO). By the transfer of the electron from the sensitizer (DOMeBzO) in the excited state to the acid generating agent (B), a radical cation (DOMeBzO•⁺) of the sensitizer, the neutral molecule (RI), the radical (R•) and the anion (X⁻) are produced. In addition, when the irradiation with the flood UV is executed, a reaction similar to that in irradiating with the electron beam patternwise proceeds, and thus the acid is efficiently generated through a chain reaction.

### EXAMPLES

Hereinafter, the present invention is explained in detail by way of Examples, but the present invention is not in any way limited to these Examples. Measuring methods for various types of physical properties are shown below.

### Weight Average Molecular Weight (Mw) and Number Average Molecular Weight (Mn)

The Mw and the Mn of the polymer were determined by gel permeation chromatography (GPC) using GPC columns (“G2000 HXL” x 2, “G3000 HXL” x 1 and “G4000 HXL” x 1) available from Tosoh Corporation under the following conditions.

eluent: tetrahydrofuran (available from Wako Pure Chemical Industries, Ltd.);

flow rate: 1.0 mL/min;

sample concentration: 1.0% by mass;

amount of injected sample: 100 μL;

detector: differential refractometer; and

standard substance: mono-dispersed polystyrene

### Content of Low Molecular Weight Component

The content (% by mass) of a low molecular weight component (component having a molecular weight of no greater than 1,000) in the polymer as the component (A) was determined by high performance liquid chromatography (HPLC) using “Inertsil ODS-25 μm column” (4.6 mmφ×250 mm) available from GL Sciences, Inc., under the following conditions.

eluent: acrylonitrile/0.1% by mass aqueous phosphoric acid solution;

flow rate: 1.0 mL/min;

sample concentration: 1.0% by mass;

amount of injected sample: 100 μL; and

detector: differential refractometer

### ¹³C-NMR Analysis

The analysis was performed by using a nuclear magnetic resonance apparatus (“JNM-EX400” available from JEOL, Ltd.) and DMSO-d₆ as a solvent for measurement.

### Synthesis of Component (A)

Polymers (A-1) to (A-10) as the component (A), and the polymer (F-1) as the component (F) were synthesized using compounds represented by the following formulae (M-1) to (M-9) (hereinafter, may be also referred to as “compounds (M-1) to (M-9)”).

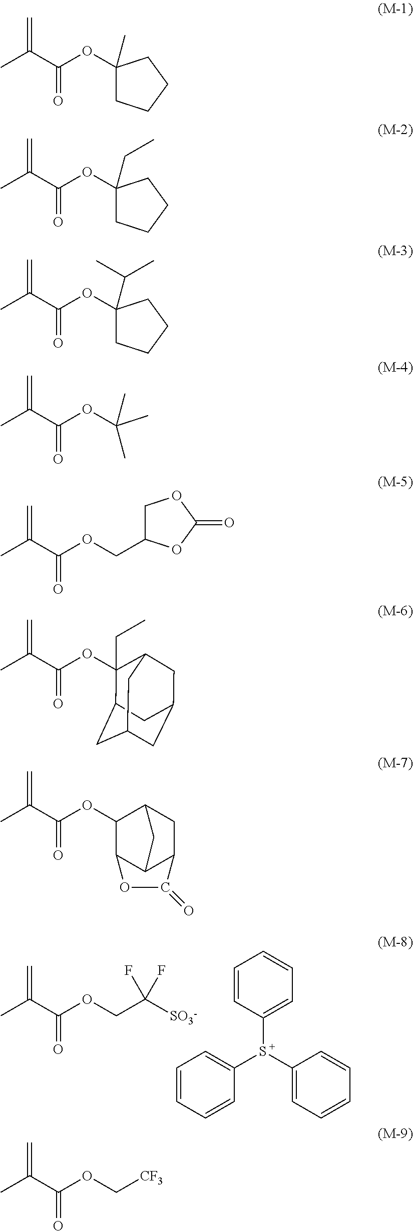

### Synthesis of Polymer (A)

### Synthesis Example 1

A monomer solution was prepared by dissolving 43.08 g (50 mol %) of the compound (M-1) and 56.92 g (50 mol %) of the compound (M-7) in 200 g of 2-butanone, and adding thereto 4.21 g (5 mol % with respect to the total amount of the monomers) of AIBN. Into a 1,000 mL three-neck flask which had been charged with 100 g of 2-butanone was subjected to nitrogen-purging for 30 min. Then, the flask was heated to 80° C. with stirring, and the monomer solution prepared as above was added thereto dropwise over 3 hrs using a dropping funnel. The time of the start of the dropwise addition was regarded as the time of the start of the polymerization reaction, and the polymerization reaction was allowed to proceed for 6 hrs. After the completion of the polymerization reaction, the polymerization reaction mixture was water-cooled to 30° C. or below. The cooled polymerization reaction mixture was charged into 2,000 g of methanol, and the precipitated white powder was filtered off. The collected white powder was washed twice with 400 g of methanol and filtered off, followed by drying at 50° C. for 17 hrs to obtain a polymer (A-1) as a white powder (73 g, 73% yield). The polymer (A-1) had the Mw of 7,730 and the Mw/Mn of 1.51, and the content of the low molecular weight component was 0.05% by mass. In addition, the result of ¹³C-NMR analysis indicated that the proportions of the structural unit derived from (M-1) and the structural unit derived from (M-7) were 47.3 mol % and 52.7 mol %, respectively.

### Synthesis Examples 2 to 10

Polymers (A-2) to (A-10) were synthesized by a similar operation to that for Synthesis Example 1 except that the type and the amount of the monomer used, and the amount (mol % with respect to the total amount of the monomers) of AIBN charged as a radical polymerization initiator were as shown in Table 1 below. Yield (%) of the obtained polymer, proportions (mol %) of the structural units, the Mw, the Mw/Mn and the content (% by mass) of the low molecular weight component are shown together in Table 1.

TABLE 1

| | | Monomer giving | | | Monomer giving | | | Monomer giving other | | | | | | Content |
|---|---|---|---|---|---|---|---|---|---|---|---|---|---|---|
| | | structural unit(I) | | | structural unit (II) | | | structural unit | | | | | | of low |
| | | | | propor- | | | propor- | | | propor- | | | | molecular |
| | | | | tion of | | | tion of | | | tion of | | | | weight |
| | | | | structur- | | | structu- | | | structur- | Amount of | | | component |
| | (A) | | amount | al unit | | amount | ral unit | | amount | al unit | AIBN | | Mw/ | (% by |
| | Polymer | type | (mol %) | (mol %) | type | (mol %) | (mol %) | type | (mol %) | (mol %) | (mol %) | Mw | Mn | mass) |
| Synthesis | A-1 | M-1 | 50 | 47.3 | M-7 | 50 | 52.7 | — | — | — | 5.0 | 7,730 | 1.51 | 0.05 |
| Example 1 | | | | | | | | | | | | | | |
| Synthesis | A-2 | M-1 | 50 | 50.1 | M-7 | 50 | 49.9 | — | — | — | 2.0 | 13,020 | 1.56 | 0.04 |
| Example 2 | | | | | | | | | | | | | | |
| Synthesis | A-3 | M-1 | 50 | 50.3 | M-7 | 50 | 49.7 | — | — | — | 1.0 | 20,890 | 1.61 | 0.03 |
| Example 3 | | | | | | | | | | | | | | |
| Synthesis | A-4 | M-2 | 50 | 49.4 | M-7 | 50 | 50.6 | — | — | — | 1.5 | 16,580 | 1.59 | 0.05 |
| Example 4 | | | | | | | | | | | | | | |
| Synthesis | A-5 | M-3 | 50 | 48.1 | M-7 | 50 | 51.9 | — | — | — | 3.0 | 9,860 | 1.48 | 0.04 |
| Example 5 | | | | | | | | | | | | | | |
| Synthesis | A-6 | M-4 | 50 | 46.9 | M-7 | 50 | 53.1 | — | — | — | 2.0 | 13,460 | 1.53 | 0.05 |
| Example 6 | | | | | | | | | | | | | | |
| Synthesis | A-7 | M-1 | 40 | 38.1 | M-5 | 10 | 9.0 | — | — | — | 3.5 | 8,790 | 1.49 | 0.05 |
| Example 7 | | | | | M-7 | 50 | 52.9 | | | | | | | |
| Synthesis | A-8 | M-1 | 35 | 33.0 | M-7 | 50 | 54.1 | — | — | — | 5.0 | 7,020 | 1.50 | 0.03 |
| Example 8 | | M-6 | 15 | 12.9 | | | | | | | | | | |
| Synthesis | A-9 | M-1 | 45 | 42.1 | M-7 | 45 | 50.9 | M-8 | 10 | 7.0 | 5.0 | 7,240 | 1.54 | 0.05 |
| Example 9 | | | | | | | | | | | | | | |
| Synthesis | A-10 | M-1 | 50 | 46.2 | M-7 | 50 | 53.8 | — | — | — | 10.0 | 4,700 | 1.41 | 0.07 |
| Example 10 | | | | | | | | | | | | | | |

### Synthesis of Polymer (F)

### Synthesis Example 11

A monomer solution was prepared by dissolving 71.67 g (70 mol %) of the compound (M-2) and 28.33 g (30 mol %) of the compound (M-9) in 100 g of 2-butanone, and adding thereto 10.35 g of dimethyl 2,2′-azobisisobutyrate as a radical polymerization initiator. Into a 1,000 mL three-neck flask which had been charged with 100 g of 2-butanone was subjected to nitrogen-purging for 30 min. Then, the flask was heated to 80° C. with stirring, and the monomer solution prepared as above was added thereto dropwise over 3 hrs using a dropping funnel. The time of the start of the dropwise addition was regarded as the time of the start of the polymerization reaction, and the polymerization reaction was allowed to proceed for 6 hrs. After the completion of the polymerization reaction, the polymerization reaction mixture was water-cooled to 30° C. or below. The resultant polymerization reaction mixture was transferred to a 4 L separatory funnel, then homogeneously diluted with 300 g of n-hexane, and 1,200 g of methanol was charged thereinto followed by mixing. Then, 60 g of distilled water was charged, and the mixture was further stirred and left to stand for 30 min. Next, after the lower layer was recovered, solvent substitution was conducted to obtain a propylene glycol monomethyl ether acetate solution of a polymer (F-1) (60% yield). The polymer (F-1) had the Mw of 7,200 and the Mw/Mn of 2.00, and the content of the low molecular weight component was 0.07% by mass. In addition, the result of ¹³C-NMR analysis indicated that the proportions of the structural unit derived from (M-2) and the structural unit derived from (M-9) were 71.1 mol % and 28.9 mol %, respectively.

### Preparation of Radiation-Sensitive Resin Composition

Components which were used in the preparation of the radiation-sensitive resin composition are shown below.

### (B) Component

The structural formulae are shown below.

B-1: diphenyliodonium nonafluoro-n-butanesulfonate

B-2: 4-cyclohexylsulfonylphenyldiphenylsulfonium 4-[2-(norbomanelacton-2-yloxycarbonyl)cyclohexan-1-ylcarbonyloxy]-1,1,2-trifluorobutane-1-sulfonate

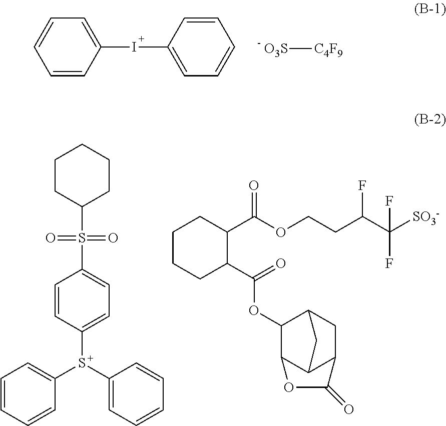

### (C) Sensitizer Precursor

C-1: bis(4-methoxyphenyl)methanol

The sensitizer precursor (C-1) is to be converted to a sensitizer, 4,4′-dimethoxybenzophenone (hereinafter, may be also referred to as “sensitizer (C-1′)”) by an action of an acid.

It is to be noted that with respect to each of the sensitizer precursor (C-1) and the sensitizer (C-1′), a 0.0001% by mass cyclohexane solution thereof was prepared, and the absorbance of each solution was measured using cyclohexane as a reference solvent and a spectrophotometer (“V-670” available from JASCO Corporation). The absorbance of the reference solvent at the wavelength of 320 nm was subtracted from the absorbance of the solution to be measured at the wavelength of 320 nm, whereby the absorbance attributed to each of the sensitizer precursor (C-1) and the sensitizer (C-1′) was determined. Consequently, the absorbance of the sensitizer (C-1′) was ascertained to be at least 5 times greater than the absorbance of the sensitizer precursor (C-1). It is to be noted that the transmittance of the cyclohexane solvent used in the measurement of the absorbance was confirmed to be no less than 95% at the wavelength of 320 nm.

### (D) Quencher

The structural formulae are shown below.

D-1: 4-hydroxy-N-t-amyloxycarbonylpiperidine

D-2: triphenylsulfonium salicylate

D-3: triphenylsulfonium 10-camphorsulfonate

D-4: triphenylsulfonium N-n-butyltrifluoromethylsulfonamide

D-5: 4-cyclohexylsulfonylphenyldiphenylsulfonium 1,2-di(cyclohexyloxycarbonyl)ethane-1-sulfonate

D-6: 4-cyclohexylsulfonylphenyldiphenylsulfonium 1,2-di(norbomanelacton-2-yloxycarbonyl)ethane-1-sulfonate

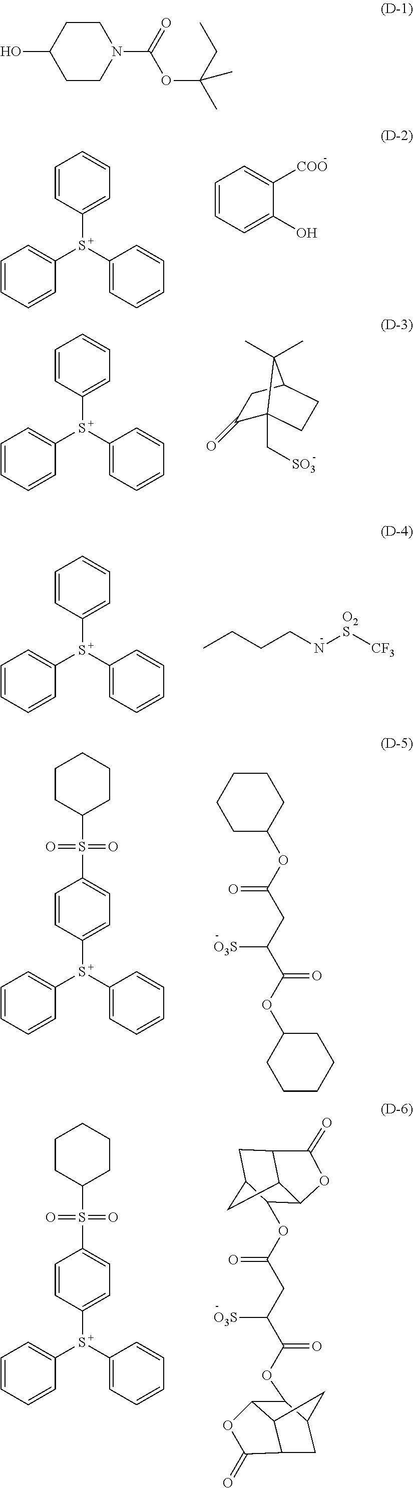

### (E) Solvent

E-1: propylene glycol monomethyl ether acetate

E-2: cyclohexanone

E-3: γ-butyrolactone

### Example 1

A chemically amplified radiation-sensitive resin composition (J-1) was prepared by: mixing 100 parts by mass of the polymer (A-1) as the component (A), 11 parts by mass of (B-1) as the component (B), 5 parts by mass of (C-1) as the sensitizer precursor (C), 4.5 parts by mass of (D-2) as the quencher (D), 3,240 parts by mass of (E-1), 1,400 parts by mass of (E-2) and 30 parts by mass of (E-3) as the solvent (E), and 3 parts by mass of (F-1) as the polymer (F); and filtering the resulting mixed solution through a filter having a pore size of 0.20 μm.

### Examples 2 to 16 and Comparative Examples 1 to 16

Chemically amplified radiation-sensitive resin compositions (J-2) to (J-16) and (CJ-1) to (CJ-16) were prepared in a similar manner to Example 1 except that each component of the type and the content shown in Table 2 below was used.

TABLE 2

| | Chemically | | | | | | | | | | | | |
|---|---|---|---|---|---|---|---|---|---|---|---|---|---|
| | amplified | | | (B) Acid | | (C) Sensitizer | | | | | | | |
| | radiation- | (A) Polymer | | generating agent | | precursor | | (D) Quencher | | (E) Solvent | | (F) Polymer | |
| | sensitive resin | | parts by | | parts by | | parts by | | parts by | | parts by | | parts by |
| | composition | type | mass | type | mass | type | mass | type | mass | type | mass | type | mass |
| Example 1 | J-1 | A-1 | 100 | B-1 | 11 | C-1 | 5 | D-2 | 4.5 | E-1/E-2/E-3 | 3,240/1,400/30 | F-1 | 3 |
| Comparative | CJ-1 | A-1 | 100 | B-1 | 11 | — | — | D-2 | 4.5 | E-1/E-2/E-3 | 3,240/1,400/30 | F-1 | 3 |
| Example 1 | | | | | | | | | | | | | |
| Example 2 | J-2 | A-1 | 100 | B-2 | 20 | C-1 | 5 | D-1 | 1 | E-1/E-2/E-3 | 3,240/1,400/30 | — | 0 |
| Comparative | CJ-2 | A-1 | 100 | B-2 | 20 | — | — | D-1 | 1 | E-1/E-2/E-3 | 3,240/1,400/30 | — | 0 |
| Example 2 | | | | | | | | | | | | | |
| Example 3 | J-3 | A-2 | 100 | B-1 | 30 | C-1 | 2.5 | D-3 | 5.5 | E-1/E-2/E-3 | 3,240/1,400/30 | F-1 | 3 |
| Comparative | CJ-3 | A-2 | 100 | B-1 | 30 | — | — | D-3 | 5.5 | E-1/E-2/E-3 | 3,240/1,400/30 | F-1 | 3 |
| Example 3 | | | | | | | | | | | | | |
| Example 4 | J-4 | A-2 | 100 | B-2 | 35 | C-1 | 2.5 | D-2 | 4.5 | E-1/E-2/E-3 | 3,240/1,400/30 | F-1 | 3 |
| Comparative | CJ-4 | A-2 | 100 | B-2 | 35 | — | — | D-2 | 4.5 | E-1/E-2/E-3 | 3,240/1,400/30 | F-1 | 3 |
| Example 4 | | | | | | | | | | | | | |
| Example 5 | J-5 | A-3 | 100 | B-1 | 40 | C-1 | 10 | D-1 | 1 | E-1/E-2/E-3 | 3,240/1,400/30 | F-1 | 3 |
| Comparative | CJ-5 | A-3 | 100 | B-1 | 40 | — | — | D-1 | 1 | E-1/E-2/E-3 | 3,240/1,400/30 | F-1 | 3 |
| Example 5 | | | | | | | | | | | | | |
| Example 6 | J-6 | A-4 | 100 | B-1 | 50 | C-1 | 5 | D-2 | 4.5 | E-1/E-2/E-3 | 3,240/1,400/30 | F-1 | 3 |
| Comparative | CJ-6 | A-4 | 100 | B-1 | 50 | — | — | D-2 | 4.5 | E-1/E-2/E-3 | 3,240/1,400/30 | F-1 | 3 |
| Example 6 | | | | | | | | | | | | | |
| Example 7 | J-7 | A-5 | 100 | B-2 | 8.5 | C-1 | 4.5 | D-2 | 4.5 | E-1/E-2/E-3 | 3,240/1,400/30 | F-1 | 3 |
| Comparative | CJ-7 | A-5 | 100 | B-2 | 8.5 | — | — | D-2 | 4.5 | E-1/E-2/E-3 | 3,240/1,400/30 | F-1 | 3 |
| Example 7 | | | | | | | | | | | | | |
| Example 8 | J-8 | A-6 | 100 | B-1 | 15 | C-1 | 4.5 | D-3 | 4.5 | E-1/E-2/E-3 | 3,240/1,400/30 | F-1 | 3 |
| Comparative | CJ-8 | A-6 | 100 | B-1 | 15 | — | — | D-3 | 4.5 | E-1/E-2/E-3 | 3,240/1,400/30 | F-1 | 3 |
| Example 8 | | | | | | | | | | | | | |
| Example 9 | J-9 | A-7 | 100 | B-1 | 17 | C-1 | 7 | D-1 | 1 | E-1/E-2/E-3 | 3,240/1,400/30 | F-1 | 3 |
| Comparative | CJ-9 | A-7 | 100 | B-1 | 17 | — | — | D-1 | 1 | E-1/E-2/E-3 | 3,240/1,400/30 | F-1 | 3 |
| Example 9 | | | | | | | | | | | | | |
| Example 10 | J-10 | A-8 | 100 | B-2 | 8.5 | C-1 | 7 | D-2 | 4.5 | E-1/E-2/E-3 | 3,240/1,400/30 | F-1 | 3 |
| Comparative | CJ-10 | A-8 | 100 | B-2 | 8.5 | — | — | D-2 | 4.5 | E-1/E-2/E-3 | 3,240/1,400/30 | F-1 | 3 |
| Example 10 | | | | | | | | | | | | | |
| Example 11 | J-11 | A-1 | 100 | B-1 | 25 | C-1 | 5 | D-4 | 5 | E-1/E-2/E-3 | 3,240/1,400/30 | F-1 | 3 |
| Comparative | CJ-11 | A-1 | 100 | B-1 | 25 | — | — | D-4 | 5 | E-1/E-2/E-3 | 3,240/1,400/30 | F-1 | 3 |
| Example 11 | | | | | | | | | | | | | |
| Example 12 | J-12 | A-1 | 100 | B-1 | 11 | C-1 | 5 | D-5 | 8.5 | E-1/E-2/E-3 | 3,240/1,400/30 | F-1 | 3 |
| Comparative | CJ-12 | A-1 | 100 | B-1 | 11 | — | — | D-5 | 8.5 | E-1/E-2/E-3 | 3,240/1,400/30 | F-1 | 3 |
| Example 12 | | | | | | | | | | | | | |
| Example 13 | J-13 | A-1 | 100 | B-1 | 20 | C-1 | 10 | D-6 | 9.5 | E-1/E-2/E-3 | 3,240/1,400/30 | F-1 | 3 |
| Comparative | CJ-13 | A-1 | 100 | B-1 | 20 | — | — | D-6 | 9.5 | E-1/E-2/E-3 | 3,240/1,400/30 | F-1 | 3 |
| Example 13 | | | | | | | | | | | | | |
| Example 14 | J-14 | A-5 | 100 | B-2 | 25 | C-1 | 5 | D-4 | 5 | E-1/E-2/E-3 | 3,240/1,400/30 | F-1 | 3 |
| Comparative | CJ-14 | A-5 | 100 | B-2 | 25 | — | — | D-4 | 5 | E-1/E-2/E-3 | 3,240/1,400/30 | F-1 | 3 |
| Example 14 | | | | | | | | | | | | | |
| Example 15 | J-15 | A-9 | 100 | B-1 | 10 | C-1 | 5 | D-3 | 5.5 | E-1/E-2/E-3 | 3,240/1,400/30 | F-1 | 3 |
| Comparative | CJ-15 | A-9 | 100 | B-1 | 10 | — | — | D-3 | 5.5 | E-1/E-2/E-3 | 3,240/1,400/30 | F-1 | 3 |
| Example 15 | | | | | | | | | | | | | |
| Example 16 | J-16 | A-10 | 100 | B-1 | 18 | C-1 | 5 | D-2 | 4.5 | E-1/E-2/E-3 | 3,240/1,400/30 | F-1 | 3 |
| Comparative | CJ-16 | A-10 | 100 | B-1 | 18 | — | — | D-2 | 4.5 | E-1/E-2/E-3 | 3,240/1,400/30 | F-1 | 3 |
| Example 16 | | | | | | | | | | | | | |

### Formation of Resist Pattern

### Example 1

The chemically amplified radiation-sensitive resin composition (J-1) prepared in Example 1 was spin-coated onto a silicon wafer in “CLEAN TRACK ACT-8” available from Tokyo Electron Limited, and subjected to PB at 100° C. for 60 sec to form a resist film having an average film thickness of 50 nm. Subsequently, the resist film was irradiated with an electron beam using a simplified electron beam writer (“HL800D” available from Hitachi, Ltd., power: 50 KeV, current density: 5.0 ampere/cm²) to permit patterning. After the irradiation with the electron beam, the following operation (a) or (b) was performed.

(a) Immediately after the irradiation with the electron beam, PEB was carried out at 110° C. for 60 sec in the CLEAN TRACK ACT-8. Then, a development was carried out according to a puddle procedure at 23° C. for 1 min using butyl acetate. Thereafter, the substrate was dried, whereby a negative resist pattern was formed.

(b) The entire face was exposed to an ultraviolet ray for 10 min using a black light lamp manufactured by Toshiba Corporation (320 nm) with a light source of 1 mW/h in an ambient air. Immediately after the exposure, PEB was carried out at 110° C. for 60 sec in the CLEAN TRACK ACT-8. Then, a development was carried out according to the puddle procedure at 23° C. for 1 min using butyl acetate in the CLEAN TRACK ACT-8. Thereafter, the substrate was dried, whereby a negative resist pattern was formed.

### Examples 2 to 15 and Comparative Examples 1 to 16

Each resist pattern was formed by a similar operation to that for Example 1 except that the radiation-sensitive resin composition and the developer solution shown in Table 3 were used.

The negative resist patterns thus formed were each evaluated for the sensitivity, the nanoedge roughness and the film loss quantity. The results of the evaluations are shown in Table 3.

### Comparative Example 1′

A positive resist pattern was formed by a similar operation to that for Example 1 except that the radiation-sensitive resin composition (J-1) was used and that a 2.38% by mass aqueous tetramethylammonium hydroxide solution was used as the developer solution. The resist pattern of Comparative Example 1′ was evaluated for the sensitivity and the nanoedge roughness. The results of the evaluations are shown together in Table 3. Note that the pattern of Comparative Example 1′ was not evaluated for the film loss quantity since a positive development was carried out.

### Sensitivity (μC/cm²)

An exposure dose at which a line and space pattern (1L 1S) configured with a line part having a line width of 150 nm and a space part formed by neighboring line parts with an interval of 150 nm was formed to give a line width of 1:1 was defined as “optimal exposure dose”, and the “optimal exposure dose” was defined as “sensitivity” (μC/cm²). The sensitivity was determined to be: “AA (extremely favorable)” in the case of less than 30 μC/cm²; “A (favorable)” in the case of no less than 30 μC/cm² and no greater than 50 μC/cm²; and “B (unfavorable)” in the case of greater than 50 μC/cm².

### Nanoedge Roughness (nm)

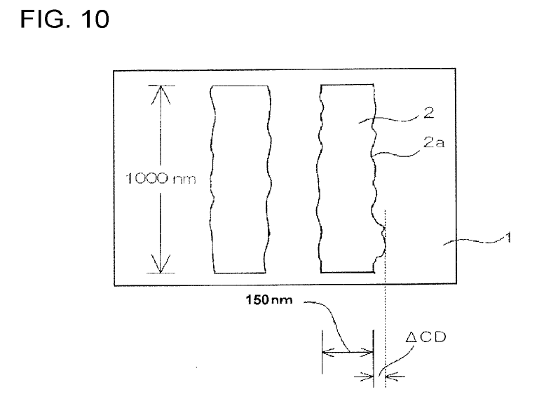

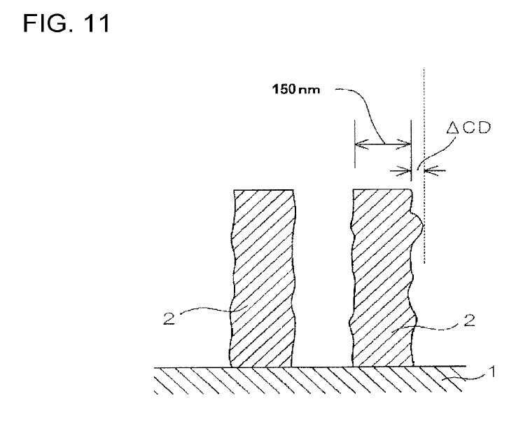

The line patterns of the line and space pattern (1L 1S) were observed using a high-resolution FEB critical dimension measurement device (S-9220, available from Hitachi, Ltd.). Arbitrary twenty points on the substrate were observed, and with respect to the observed shape, a difference “ΔCD” between an intended line width of 150 nm and a line width in an area in which irregularities generated along the side lateral surface 2a of the line part (resist pattern) 2 of the resist film formed on the silicon wafer (substrate) 1 was most significant was measured as shown in FIGS. 10 and 11. The average value of the ΔCD values was defined as “nanoedge roughness” (nm). The nanoedge roughness was determined to be: “AA (extremely favorable)” in the case of no greater than 15.0 nm; “A (favorable)” in the case of greater than 15.0 nm and no greater than 16.5 nm; and “B (unfavorable)” in the case of greater than 16.5 nm. It is to be noted that the irregularities shown in FIGS. 10 and 11 are exaggerated.

### Film Loss Quantity

The chemically amplified radiation-sensitive resin composition (J-1) prepared in Example 1 was spin-coated onto a silicon wafer in “CLEAN TRACK ACT-8” available from Tokyo Electron Limited, and subjected to PB at 100° C. for 60 sec to form a resist film having an average thickness of 50 nm. Next, the resist film was irradiated with an electron beam using a simplified electron beam writer (“HL800D” available from Hitachi, Ltd., power: 50 KeV, current density: 5.0 ampere/cm²) such that a 2 cm×2 cm center region of the wafer was exposed at the optimum exposure dose in which the line and space pattern having a line width of 150 nm and an interval of 150 nm was formed as described above. After the exposure, PEB was carried out at 110° C. for 60 sec. Thereafter, a development was carried out with a developer solution shown in Table 3 below at 23° C. for 30 sec, followed by drying. After completing a series of process, the thickness of the remaining coating film was measured. A value obtained by subtracting the film thickness of the remaining coating film from the initial film thickness was defined as the film loss quantity (unit: nm). It is to be noted that for the measurement of the film thickness, a spectroscopic film thickness measurement system (“Lambda Ace” available from Dainippon Screen Mfg. Co., Ltd.) was used. Values of the film loss quantity thus obtained are shown together in Table 3. The film loss quantity measured was evaluated to be: “A (favorable)” in the case of less than 20 nm; and “B (unfavorable)” in the case of no less than 20 nm.

TABLE 3

| | Chemically | | | | | | | | | | | | | |
|---|---|---|---|---|---|---|---|---|---|---|---|---|---|---|
| | amplified | | Process (a) (not irradiated with black light) | | | | | | Process (b) (irradiated with black light) | | | | | |
| | radiation- | | sensitivity | | nanoedge | | film loss | | sensitivity | | nanoedge | | film loss | |
| | sensitive | | value | | roughness | | quantity | | value | | roughness | | quantity | |
| | resin | | (μC/ | evalu- | value | evalu- | value | evalu- | (μC/ | evalu- | value | evalu- | value | evalu- |
| | composition | Developer solution | cm²⁾ | ation | (nm) | ation | (nm) | ation | cm²⁾ | ation | (nm) | ation | (nm) | ation |
| Example 1 | J-1 | butyl acetate | 60 | B | 14.3 | AA | 5 | A | 42 | A | 14.9 | AA | 6 | A |
| Comparative | CJ-1 | butyl acetate | 61 | B | 14.4 | AA | 4 | A | 59 | B | 14.5 | AA | 4 | A |
| Example 1 | | | | | | | | | | | | | | |
| Comparative | J-1 | tetramethyl- | 70 | B | 16.8 | B | — | — | 59 | B | 16.9 | B | — | — |
| Example 1′ | | ammonium | | | | | | | | | | | | |
| | | hydroxide (2.38 | | | | | | | | | | | | |
| | | mass %) | | | | | | | | | | | | |
| Example 2 | J-2 | 2-propanol | 51 | B | 13.2 | AA | 9 | A | 28 | AA | 13.5 | AA | 11 | A |
| Comparative | CJ-2 | 2-propanol | 53 | B | 13.3 | AA | 8 | A | 52 | B | 13.2 | AA | 10 | A |
| Example 2 | | | | | | | | | | | | | | |
| Example 3 | J-3 | 3-methylbutyl | 58 | B | 14.0 | AA | 5 | A | 25 | AA | 14.1 | AA | 6 | A |
| | | acetate | | | | | | | | | | | | |
| Comparative | CJ-3 | 3-methylbutyl | 58 | B | 14.3 | AA | 6 | A | 58 | B | 14.2 | AA | 5 | A |
| Example 3 | | acetate | | | | | | | | | | | | |
| Example 4 | J-4 | cyclohexanone | 51 | B | 14.9 | AA | 7 | A | 23 | AA | 14.8 | AA | 8 | A |
| Comparative | CJ-4 | cyclohexanone | 52 | B | 14.8 | AA | 8 | A | 51 | B | 14.7 | AA | 9 | A |
| Example 4 | | | | | | | | | | | | | | |
| Example 5 | J-5 | methylamyl ketone | 53 | B | 14.2 | AA | 5 | A | 22 | AA | 14.5 | AA | 6 | A |
| Comparative | CJ-5 | methylamyl ketone | 54 | B | 14.3 | AA | 4 | A | 52 | B | 14.2 | AA | 6 | A |
| Example 5 | | | | | | | | | | | | | | |
| Example 6 | J-6 | γ-butyrolactone | 51 | B | 15.6 | A | 4 | A | 18 | AA | 15.8 | A | 3 | A |
| Comparative | CJ-6 | γ-butyrolactone | 51 | B | 15.7 | A | 3 | A | 51 | B | 15.7 | A | 3 | A |
| Example 6 | | | | | | | | | | | | | | |
| Example 7 | J-7 | dibutyl ether | 65 | B | 13.2 | AA | 12 | A | 41 | A | 13.5 | AA | 12 | A |
| Comparative | CJ-7 | dibutyl ether | 67 | B | 12.9 | AA | 13 | A | 65 | B | 13.0 | AA | 11 | A |
| Example 7 | | | | | | | | | | | | | | |
| Example 8 | J-8 | N,N- | 58 | B | 14.3 | AA | 9 | A | 33 | A | 14.5 | AA | 9 | A |
| | | dimethylacetamide | | | | | | | | | | | | |
| Comparative | CJ-8 | N,N- | 57 | B | 14.2 | AA | 8 | A | 55 | B | 14.5 | AA | 10 | A |
| Example 8 | | dimethylacetamide | | | | | | | | | | | | |
| Example 9 | J-9 | butyl acetate | 55 | B | 12.8 | AA | 8 | A | 34 | A | 13.0 | AA | 9 | A |
| Comparative | CJ-9 | butyl acetate | 54 | B | 13.0 | AA | 7 | A | 52 | B | 13.3 | AA | 9 | A |
| Example 9 | | | | | | | | | | | | | | |
| Example 10 | J-10 | ethyl lactate | 72 | B | 12.6 | AA | 17 | A | 45 | A | 13.0 | AA | 16 | A |
| Comparative | CJ-10 | ethyl lactate | 72 | B | 12.7 | AA | 18 | A | 70 | B | 13.0 | AA | 17 | A |
| Example 10 | | | | | | | | | | | | | | |
| Example 11 | J-11 | propylene glycol | 56 | B | 13.6 | AA | 7 | A | 32 | A | 13.9 | AA | 7 | A |
| | | monomethyl ether | | | | | | | | | | | | |
| Comparative | CJ-11 | propylene glycol | 55 | B | 13.3 | AA | 8 | A | 52 | B | 13.0 | AA | 7 | A |
| Example 11 | | monomethyl ether | | | | | | | | | | | | |
| Example 12 | J-12 | ethanol | 65 | B | 13.2 | AA | 10 | A | 39 | A | 13.6 | AA | 11 | A |
| Comparative | CJ-12 | ethanol | 66 | B | 13.3 | AA | 11 | A | 64 | B | 13.2 | AA | 12 | A |
| Example 12 | | | | | | | | | | | | | | |
| Example 13 | J-13 | methyl amyl ketone/ | 57 | B | 14.2 | AA | 7 | A | 34 | A | 14.6 | AA | 8 | A |
| | | trioctylamine | | | | | | | | | | | | |
| | | (mass ratio: 99/1) | | | | | | | | | | | | |
| Comparative | CJ-13 | methyl amyl ketone/ | 56 | B | 14.4 | AA | 9 | A | 55 | B | 14.4 | AA | 8 | A |
| Example 13 | | trioctylamine | | | | | | | | | | | | |
| | | (mass ratio: 99/1) | | | | | | | | | | | | |
| Example 14 | J-14 | anisole | 54 | B | 14.6 | AA | 6 | A | 31 | A | 14.9 | AA | 6 | A |
| Comparative | CJ-14 | anisole | 54 | B | 14.7 | AA | 5 | A | 53 | B | 14.5 | AA | 7 | A |
| Example 14 | | | | | | | | | | | | | | |
| Example 15 | J-15 | butyl acetate | 79 | B | 12.0 | AA | 17 | A | 46 | A | 12.5 | AA | 16 | A |
| Comparative | CJ-15 | butyl acetate | 78 | B | 11.9 | AA | 16 | A | 77 | B | 12.2 | AA | 15 | A |
| Example 15 | | | | | | | | | | | | | | |
| Example 16 | J-16 | butyl acetate | 54 | B | 13.2 | AA | 23 | B | 29 | AA | 13.6 | AA | 22 | B |
| Comparative | CJ-16 | butyl acetate | 55 | B | 13.5 | AA | 24 | B | 54 | B | 13.4 | AA | 21 | B |
| Example 16 | | | | | | | | | | | | | | |

From the results shown in Table 3, it is revealed that a resist pattern having less nanoedge roughness and a high resolution can be formed with high sensitivity, according to the radiation-sensitive resin compositions of Examples. In addition, it is also revealed that when the Mw of the polymer (A) in the radiation-sensitive resin composition falls within the certain range, the film loss quantity can be decreased.

The resist pattern-forming method and the chemically amplified radiation-sensitive resin composition of the embodiments of the present invention are suitably used for exposure steps by which a resist pattern is formed on a substrate. According to the resist pattern-forming method and the chemically amplified radiation-sensitive resin composition of the embodiments of the present invention, the sensitivity of a resist can be improved.

Obviously, numerous modifications and variations of the present invention are possible in light of the above teachings. It is therefore to be understood that within the scope of the appended claims, the invention may be practiced otherwise than as specifically described herein.

What is claimed is:

1. A resist pattern-forming method comprising:
applying a chemically amplified radiation-sensitive resin composition on a substrate to form a resist film, the chemically amplified radiation-sensitive resin composition comprising:
a first component solubility in a developer solution of which is capable of being altered by an action of an acid;
a second component that is capable of generating an acid by an action of a first exposure light comprising a radioactive ray having a first wavelength; and
a sensitizer precursor to be converted into a sensitizer by an action of the first exposure light;
conducting a first exposure of the resist film to the first exposure light;
conducting a second exposure of the resist film exposed to the first exposure light, to a second exposure light comprising a radioactive ray having a second wavelength longer than the first wavelength; and
developing with a developer solution comprising an organic solvent as a principal component, the resist film exposed to the second exposure light,
wherein a value (I^{PP})/(I^{P}) is no greater than 0.2, wherein (I^{PP}) is an absorbance of the sensitizer precursor at the second wavelength, and (I^{P}) is an absorbance of the sensitizer at the second wavelength.

2. The resist pattern-Twining method according to claim 1, wherein the first exposure light is substantially devoid of a radioactive ray having the second wavelength.

3. The resist pattern-forming method according to claim 1, wherein
the first exposure is a floodwise exposure of the resist film, and
the second exposure is a patternwise exposure of the resist film exposed to the first exposure light.

4. The resist pattern-forming method according to claim 1, wherein
the first exposure is a patternwise exposure of the resist film, and
the second exposure is a floodwise exposure of the resist film exposed to the first exposure light.

5. The resist pattern-forming method according to claim 1, wherein the first component is a first polymer comprising a group that is capable of generating a polar group through dissociation of an acid-labile group by an action of the acid.

6. The resist pattern-forming method according to claim 1, wherein the second component and the sensitizer precursor are each different from the first component.

7. The resist pattern-forming method according to claim 6, wherein a content of the second component with respect to a total solid content of the chemically amplified radiation-sensitive resin composition is no less than 10% by mass and no greater than 30% by mass.

8. The resist pattern-forming method according to claim 5, wherein the first polymer comprises at least one of the second component and the sensitizer precursor.

9. The resist pattern-forming method according to claim 5, wherein the developer solution used in the developing further comprises a first compound that gives an ionic bond, a hydrogen bond, a covalent bond, a coordinate bond, a dipole-dipole interaction or a combination thereof with a polar group generated in the first polymer.

10. The resist pattern-forming method according to claim 9, wherein the first compound is a nitrogen-containing compound, an onium salt, an onium salt-comprising polymer, a basic polymer, a phosphorus compound or a combination thereof.

11. The resist pattern-forming method according claim 1, wherein the first exposure light is an extreme ultraviolet ray or an electron beam.

12. The resist pattern-forming method according to claim 1, further comprising before forming the resist film,
forming an organic underlayer film directly or indirectly on a face of the substrate on which the resist film is to be formed.

13. The resist pattern-forming method according to claim 12, further comprising after forming the organic underlayer film and before forming the resist film,
forming a silicon-containing film directly or indirectly on a face of the organic underlayer film on which the resist film is to be formed.

14. A chemically amplified radiation-sensitive resin composition, comprising:
a first component solubility in a developer solution of which is capable of being altered by an action of an acid;
a second component that is capable of generating an acid by an action of a first exposure light including a radioactive ray having a first wavelength; and
a sensitizer precursor to be converted into a sensitizer by an action of the first exposure light.
